(19) United States
(12) Patent Application Publication
(10) Pub. No.: US 2024/0176243 A1
(43) Pub. Date: May 30, 2024

(54) RESIST UNDERLAYER FILM-FORMING COMPOSITION

(71) Applicant: NISSAN CHEMICAL CORPORATION, Tokyo (JP)

(72) Inventors: Hiroto OGATA, Toyama-shi (JP); Mamoru TAMURA, Toyama-shi (JP)

(73) Assignee: NISSAN CHEMICAL CORPORATION, Tokyo (JP)

(21) Appl. No.: 18/280,879

(22) PCT Filed: Mar. 15, 2022
(86) PCT No.: PCT/JP2022/011452

§ 371 Date: Sep. 7, 2023

(30) Foreign Application Priority Data
Mar. 16, 2021 (JP) 2021-042226
Mar. 16, 2021 (JP) 2021-042227
Mar. 16, 2021 (JP) 2021-042229

(51) Int. Cl. G03F 7/039; G03F 7/004; G03F 7/16

(52) U.S. Cl. CPC G03F 7/0392; G03F 7/0048; G03F 7/168

(57) ABSTRACT

A resist underlayer film formation composition including a solvent and a polymer or a compound including a structure represented by formula (100): (in formula (100), Ar represents an optionally substituted C6-40 aromatic ring group, L0 represents a single bond, an ester bond, an ether bond, an optionally substituted C1-10 alkylene group, or an optionally substituted C2-10 alkenylene group, T0 represents a single bond, an ester bond, an ether bond, an optionally substituted C1-10 alkylene group, or an optionally substituted C2-10 alkenylene group, provided that L0 and T0 are different, the n-number of R0 independently represent a hydroxy group, a halogen atom, a nitro group, a cyano group, an amino group, or a monovalent organic group, n represents an integer of 0-5, and * represents a binding moiety with a polymer or residue of the compound.

### TECHNICAL FIELD

The present invention relates to a composition for use in a lithography process in manufacturing a semiconductor, in particular, in the state-of-the-art (ArF, EUV, EB, or the like) lithography process. In addition, the present invention relates to a method for manufacturing a substrate with a resist pattern to which the resist underlayer film is applied and a method for manufacturing a semiconductor device.

### BACKGROUND ART

Conventionally, in the manufacture of a semiconductor device, fine processing by lithography using a resist composition has been performed. The fine processing is a processing method for forming a thin film of a photoresist composition on a semiconductor substrate such as a silicon wafer, irradiating the thin film with active rays such as ultraviolet rays through a mask pattern in which a pattern of a device is formed, developing the thin film, and etching the substrate using the obtained photoresist pattern as a protective film, thereby forming fine unevenness corresponding to the pattern on a surface of the substrate. In recent years, a degree of integration of a semiconductor device has been increased, and in addition to an i-line (wavelength: 365 nm), a KrF excimer laser (wavelength: 248 nm), and an ArF excimer laser (wavelength: 193 nm) that have been used in the related art, active rays used for practical application of an extreme ultraviolet ray (EUV) (wavelength: 13.5 nm) or an electron beam (EB) have been studied for the state-of-the-art fine processing. Accordingly, there is a serious problem of resist pattern formation defects due to the influence of the semiconductor substrate and the like. Therefore, in order to solve this problem, a method of providing a resist underlayer film between the resist and the semiconductor substrate has been widely studied. Patent Literature 1 discloses a resist underlayer film-forming composition for EUV lithography containing a condensation polymer. Patent Literature 2 discloses a resist underlayer film-forming composition containing a polymer having a specific unit structure in a main chain. Patent Literature 3 discloses a semiconductor lithography film-forming composition containing a nitrile compound.

### CITATION LIST

### Patent Literature

Patent Literature 1: WO 2013/018802 A
Patent Literature 2: JP 2015-145944 A
Patent Literature 3: WO 2019/059202 A

### SUMMARY OF INVENTION

### Technical Problem

The properties required for the resist underlayer film include, for example, that the film does not cause intermixing with a resist film formed on an upper layer (that is, the film is insoluble in a resist solvent), and that the film has a higher dry etching rate than that of the resist film.

In the case of lithography with EUV exposure, a resist pattern is formed with a line width of 32 nm or less, and a resist underlayer film for EUV exposure is formed to be thinner than before. When such a thin film is formed, pinholes, agglomeration, and the like are likely to occur due to the influence of the surface of the substrate, the polymer to be used, and the like, and it is difficult to form a uniform film without defects.

On the other hand, when a resist pattern is formed, in a development process such as a negative development process in which an unexposed portion of a resist film is removed using a solvent that can dissolve the resist film, usually an organic solvent, and an exposed portion of the resist film is left as a resist pattern, or such as a positive development process in which an exposed portion of the resist film is removed and an unexposed portion of the resist film is left as a resist pattern, improvement of adhesion of the resist pattern is a major problem.

In addition, at the time of forming a resist pattern, it is required to suppress deterioration of line width roughness ((LWR), fluctuation in line width (roughness)) to form a resist pattern having a preferred rectangular shape, and to improve resist sensitivity.

An object of the present invention is to provide a composition for forming a resist underlayer film and a resist pattern forming method using the resist underlayer film-forming composition which have solved the above problems and can form a desired resist pattern.

### Solution to Problem

The present invention encompasses the followings.
[1]
   A resist underlayer film-forming composition comprising a solvent and a polymer or compound having a structure represented by the following Formula (100):

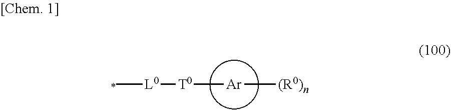

(in Formula (100),
Ar represents an optionally substituted aromatic ring group having 6 to 40 carbon atoms,
L⁰ represents a single bond, an ester bond, an ether bond, an optionally substituted alkylene group having 1 to 10 carbon atoms, or an optionally substituted alkenylene group having 2 to 10 carbon atoms,
T⁰ represents a single bond, an ester bond, an ether bond, an optionally substituted alkylene group having 1 to 10 carbon atoms, or an optionally substituted alkenylene group having 2 to 10 carbon atoms,
provided that L⁰ and T⁰ are different from each other,
n quantity of R⁰ each independently represent a hydroxy group, a halogen atom, a nitro group, a cyano group, an amino group, or a monovalent organic group,
n represents an integer of 0 to 5, and
* represents a binding site to a residue of the polymer or compound).
[2]
   The resist underlayer film-forming composition according to [1], which comprises a solvent and a compound having a partial structure represented by Formula (100),
   wherein in Formula (100),
   Ar represents an optionally substituted aromatic ring having 6 to 40 carbon atoms,
   L⁰ represents a single bond, an ester bond, an ether bond, an alkylene group having 1 to 10 carbon atoms, or an alkenylene group having 2 to 10 carbon atoms,
   T⁰ represents a single bond,
   n quantity of R⁰ each independently represent a hydroxy group, a halogen atom, a nitro group, a cyano group, an amino group, or a monovalent organic group, and
   n represents an integer of 1 to 3.
[3]
   The resist underlayer film-forming composition according to [2], wherein the compound is a reaction product of an epoxy group-containing compound and a compound represented by the following Formula (101):

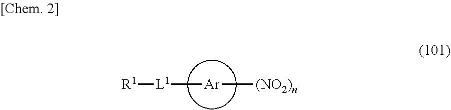

(in Formula (101), R¹ represents a group having reactivity with an epoxy group, and
Ar, L¹, and n have the same meaning as Ar, L⁰, and n in [2], respectively).
[4]
   A resist underlayer film-forming composition comprising a solvent and a polymer,
   wherein the polymer has at a terminal thereof a structure represented by the following Formula (103):

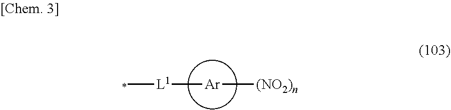

(in Formula (103), Ar represents an optionally substituted aromatic ring having 6 to 40 carbon atoms; L¹ represents a single bond, an ester bond, an ether bond, an alkylene group having 1 to 10 carbon atoms, or an alkenylene group having 2 to 10 carbon atoms; and n represents an integer of 1 to 3).
[5]
   A resist underlayer film-forming composition comprising a solvent and a polymer, which is a reaction product of a compound containing two or more epoxy groups with a compound represented by the following Formula (102):

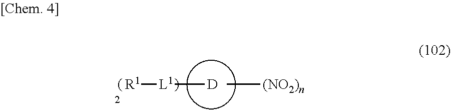

(in Formula (102), R represents a group having reactivity with an epoxy group; D represents an aromatic ring having 6 to 40 carbon atoms or a heterocyclic ring;
and L¹ and n have the same meaning as L⁰ and n in [2], respectively).
[6]
   The resist underlayer film-forming composition according to [5], wherein the polymer has at a terminal thereof a structure represented by Formula (103).
[7]
   A resist underlayer film-forming composition comprising a solvent and a polymer represented by the following Formula (P1):

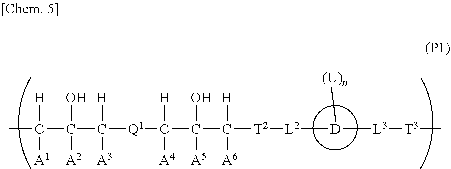

(in Formula (P1), A¹, A², A³, A⁴, A⁵, and A⁶ each independently represent a hydrogen atom, a methyl group, or an ethyl group; Q¹ represents a divalent organic group; T² and T³ each independently represent a single bond, an ester bond, or an ether bond; L² and L³ each independently represent a single bond, an optionally substituted alkylene group having 1 to 10 carbon atoms, or an optionally substituted alkenylene group having 2 to 10 carbon atoms; U represents a nitro group; D represents an aromatic ring having 6 to 40 carbon atoms or a heterocyclic ring; and n represents an integer of 0 to 3).
[8]
   The resist underlayer film-forming composition according to [3], [5], or [7], wherein the epoxy group-containing compound, the compound containing two or more epoxy groups, or Q¹ has a heterocyclic structure.
[9]
   The resist underlayer film-forming composition according to any one of [2] to [8], wherein at least one of L¹ to L³ is an alkenylene group having 2 to 10 carbon atoms.
[10]
   A resist underlayer film-forming composition comprising a solvent and a polymer or compound having at a terminal thereof a structure represented by the following Formula (200):

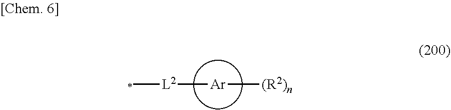

(in Formula (200), Ar represents an optionally substituted aromatic ring having 6 to 40 carbon atoms; L² represents an optionally substituted alkenylene group having 2 to 10 carbon atoms; n quantity of R² each independently represent a group selected from the group consisting of a hydroxy group, a halogen atom, a carboxy group, a nitro group, a cyano group, a methylenedioxy group, an acetoxy group, a methylthio group, an amino group, an optionally substituted alkyl group having 1 to 10 carbon atoms, and an optionally substituted alkoxy group having 1 to 10 carbon atoms; n represents an integer of 0 to 5; and * represents a binding site to a residue of the polymer or compound).
[11]
   The resist underlayer film-forming composition according to [10], wherein the polymer is a reaction product of a compound (A) containing two or more epoxy groups and a compound (B) containing two or more groups having reactivity with the epoxy group, and
   the compounds (A) and (B) have a heterocyclic structure or an aromatic ring structure having 6 to 40 carbon atoms.
[12]
   The resist underlayer film-forming composition according to [10] or [11], wherein the polymer has a unit structure represented by the following Formula (P2):

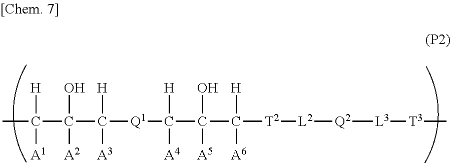

(in Formula (P2), A¹, A², A³, A⁴, A⁵, and A⁶ each independently represent a hydrogen atom, a methyl group, or an ethyl group; Q¹ and Q² each independently represent a divalent organic group having a heterocyclic structure or an aromatic ring structure having 6 to 40 carbon atoms; T² and T³ each independently represent a single bond, an ester bond, or an ether bond; and L² and L³ each independently represent a single bond, an optionally substituted alkylene group having 1 to 10 carbon atoms, or an optionally substituted alkenylene group having 2 to 10 carbon atoms).
[13]
   A resist underlayer film-forming composition comprising a solvent and a polymer having at a terminal thereof a structure at represented by the following Formula (300):

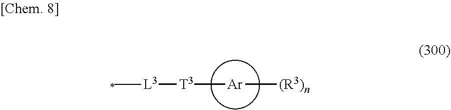

(in Formula (300), Ar represents an optionally substituted aryl group having 6 to 40 carbon atoms; L³ represents a single bond, an ester bond, or an ether bond; T³ represents a single bond, an optionally substituted alkylene group having 1 to 10 carbon atoms, or an optionally substituted alkenylene group having 2 to 10 carbon atoms; n quantity of R³ each independently represent a monovalent organic group; n represents an integer of 0 to 5; and * represents a binding site to a residue of the polymer; and at least one cyano group is present in Formula (300)).
[14]
   The resist underlayer film-forming composition according to [13], wherein the polymer is represented by the following Formula (P3):

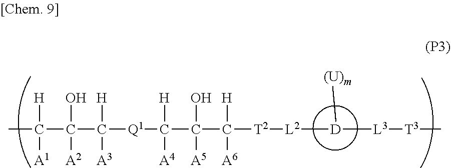

(in Formula (P3), A¹, A², A³, A⁴, A⁵, and A⁶ each independently represent a hydrogen atom, a methyl group, or an ethyl group; Q¹ represents a divalent organic group; T² and T³ each independently represent a single bond, an ester bond, or an ether bond; L² and L³ each independently represent a single bond, an optionally substituted alkylene group having 1 to 10 carbon atoms, or an optionally substituted alkenylene group having 2 to 10 carbon atoms; D represents an arylene group having 6 to 40 carbon atoms or a heterocylic ring; U represents a group selected from the group consisting of a halogen atom, a carboxy group, a nitro group, a cyano group, a methylenedioxy group, an acetoxy group, a methylthio group, an amino group, an optionally substituted alkyl group having 1 to 10 carbon atoms, an optionally substituted alkenyl group having 2 to 10 carbon atoms, and an optionally substituted alkoxy group having 1 to 10 carbon atoms; and m represents an integer of 0 to 5).
[15]
   The resist underlayer film-forming composition according to any one of [1] to [14], further comprising an acid generator.
[16]
   The resist underlayer film-forming composition according to any one of [1] to [15], further comprising a crosslinking agent.
[17]
   A resist underlayer film, which is a baked product of a coating film of the resist underlayer film-forming composition according to any one of [1] to [16].
[18]
   A method for manufacturing a patterned substrate, comprising:
   applying the resist underlayer film-forming composition according to any one of [1] to [16] onto a semiconductor substrate and baking the resist underlayer film-forming composition to form a resist underlayer film;
   applying a resist onto the resist underlayer film and baking the resist to form a resist film;
   exposing the semiconductor substrate coated with the resist underlayer film and the resist; and
   developing the exposed resist film and performing patterning.
[19]
   A method for manufacturing a semiconductor device, comprising:
   forming a resist underlayer film of the resist underlayer film-forming composition according to any one of [1] to [16] on a semiconductor substrate;
   forming a resist film on the resist underlayer film;
   forming a resist pattern by irradiating the resist film with a light or electron beam and then developing the resist film;
   forming a patterned resist underlayer film by etching the resist underlayer film through the formed resist pattern; and
   processing the semiconductor substrate by the patterned resist underlayer film.

### Advantageous Effects of Invention

Since the resist underlayer film-forming composition of the present invention has excellent coatability to a semiconductor substrate to be processed and has excellent adhesion of an interface between a resist and a resist underlayer film at the time of resist pattern formation, it is possible to suppress deterioration of line width roughness ((LWR), fluctuation in line width (roughness)) at the time of resist pattern formation without causing peeling of the resist pattern, such that a resist pattern size (minimum CD size) can be minimized, and the resist pattern can be formed into an excellent rectangular resist pattern. In particular, a remarkable effect is exhibited when EUV (wavelength: 13.5 nm) or EB (electron beam) is used.

### DESCRIPTION OF EMBODIMENTS

<Resist Underlayer Film-forming Composition>

A resist underlayer film-forming composition of the present invention contains a solvent and a polymer or compound having a structure represented by the following Formula (100):

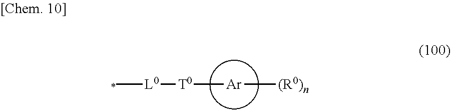

Ar represents an optionally substituted aromatic ring group having 6 to 40 carbon atoms,
L⁰ represents a single bond, an ester bond, an ether bond, an optionally substituted alkylene group having 1 to 10 carbon atoms, or an optionally substituted alkenylene group having 2 to 10 carbon atoms,
T⁰ represents a single bond, an ester bond, an ether bond, an optionally substituted alkylene group having 1 to 10 carbon atoms, or an optionally substituted alkenylene group having 2 to 10 carbon atoms,
provided that L⁰ and T⁰ are different from each other,
n quantity of R⁰ each independently represent a hydroxy group, a halogen atom, a nitro group, a cyano group, an amino group, or a monovalent organic group,
n represents an integer of 0 to 5, and
* represents a binding site with a residue of the polymer or compound).

Examples of the aromatic ring having 6 to 40 carbon atoms include an aromatic ring derived from benzene, naphthalene, anthracene, acenaphthene, fluorene, triphenylene, phenalene, phenanthrene, indene, indane, indacene, pyrene, chrysene, perylene, naphthacene, pentacene, coronene, heptacene, benzo[a]anthracene, dibenzophenanthrene, and dibenzo[a,j]anthracene. Of these, it is preferably selected from benzene, naphthalene, and anthracene.

Examples of the aryl group having 6 to 40 carbon atoms include a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an a-naphthyl group, a β-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Examples of the arylene group having 6 to 40 carbon atoms include a phenylene group, an o-methylphenylene group, an m-methylphenylene group, a p-methylphenylene group, an o-chlorophenylene group, an m-chlorophenylene group, a p-chlorophenylene group, an o-chlorophenylene group, a p-fluorophenylene group, an o-methoxyphenylene group, a p-methoxyphenylene group, a p-nitrophenylene group, a p-cyanophenylene group, an a-naphthylene group, a β-naphthylene group, an o-biphenylylene group, an m-biphenylylene group, a p-biphenylylene group, a 1-anthrylene group, a 2-anthrylene group, a 9-anthrylene group, a 1-phenanthrylene group, a 2-phenanthrylene group, a 3-phenanthrylene group, a 4-phenanthrylene group, and a 9-phenanthrylene group.

Examples of the alkylene group having 1 to 10 carbon atoms include a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, and an n-decanylene group.

Examples of the alkenylene group having 2 to 10 carbon atoms include groups having at least one double bond resulting from removing hydrogen atoms from adjacent carbon atoms, respectively, out of the alkylene groups having 2 to 10 carbon atoms. Of the alkenylene groups having 2 to 10 carbon atoms, a vinylene group is preferable.

Examples of the halogen atom include a fluorine atom, a chlorine atom, a bromine atom, and an iodine atom.

The expression “optionally substituted” means that some or all of the hydrogen atoms present in the aromatic ring or aryl group having 6 to 40 carbon atoms, the alkylene group having 1 to 10 carbon atoms, or the alkenylene group having 2 to 10 carbon atoms may be substituted with, for example, a hydroxy group, a halogen atom, a carboxyl group, a nitro group, a cyano group, a methylenedioxy group, an acetoxy group, a methylthio group, an amino group, an alkyl group having 1 to 10 carbon atoms, or an alkoxy group having 1 to 10 carbon atoms.

Examples of the alkyl group having 1 to 10 carbon atoms include a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, and a decyl group.

Examples of the alkenyl group having 2 to 10 carbon atoms include groups having at least one double bond resulting from removing hydrogen atoms from adjacent carbon atoms, respectively, out of the alkyl groups having 2 to 10 carbon atoms.

Examples of the alkoxy group having 1 to 10 carbon atoms include a methoxy group, an ethoxy group, an n-propoxy group, an i-propoxy group, an n-butoxy group, an i-butoxy group, an s-butoxy group, a t-butoxy group, an n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, a 1-ethyl-2-methyl-n-propoxy group, an n-heptyloxy group, an n-octyloxy group, an n-nonyloxy group, and an n-decanyloxy group.

<Resist Underlayer Film-forming Composition A (Containing Compound)>

The resist underlayer film-forming composition of the present invention includes
a resist underlayer film-forming composition A containing
a solvent and a compound having a partial structure represented by Formula (100),
wherein in Formula (100),
Ar represents an optionally substituted aromatic ring having 6 to 40 carbon atoms,
L⁰ represents a single bond, an ester bond, an ether bond, an alkylene group having 1 to 10 carbon atoms, or an alkenylene group having 2 to 10 carbon atoms,
T⁰ represents a single bond,
n quantity of R⁰ each independently represent a hydroxy group, a halogen atom, a nitro group, a cyano group, an amino group, or a monovalent organic group, and
n represents an integer of 1 to 3.

The compound may be a reaction product of an epoxy group-containing compound and a compound represented by the following Formula (101):

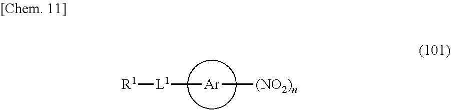

(in Formula (101), R represents a group having reactivity with an epoxy group; Ar, L¹, and n have the same meaning as Ar, L⁰, and n in Formula (100); preferably, Ar represents an optionally substituted aromatic ring have 6 to 40 carbon atoms; L¹ represents a single bond, an ester bond, an ether bond, an alkylene group having 1 to 10 carbon atoms, or an alkenylene group having 2 to 10 carbon atoms; and n represents an integer of 1 to 3).

Examples of the group (R¹) having reactivity with an epoxy group include a hydroxy group, an acyl group, an acetyl group, a formyl group, a benzoyl group, a carboxy group, a carbonyl group, an amino group, an imino group, a cyano group, an azo group, an azide group, a thiol group, a sulfo group, and an allyl group, and of these, a hydroxy group or a carboxy group is preferable from the viewpoint of reactivity with an epoxy group.

Examples of the epoxy group-containing compound include the following.

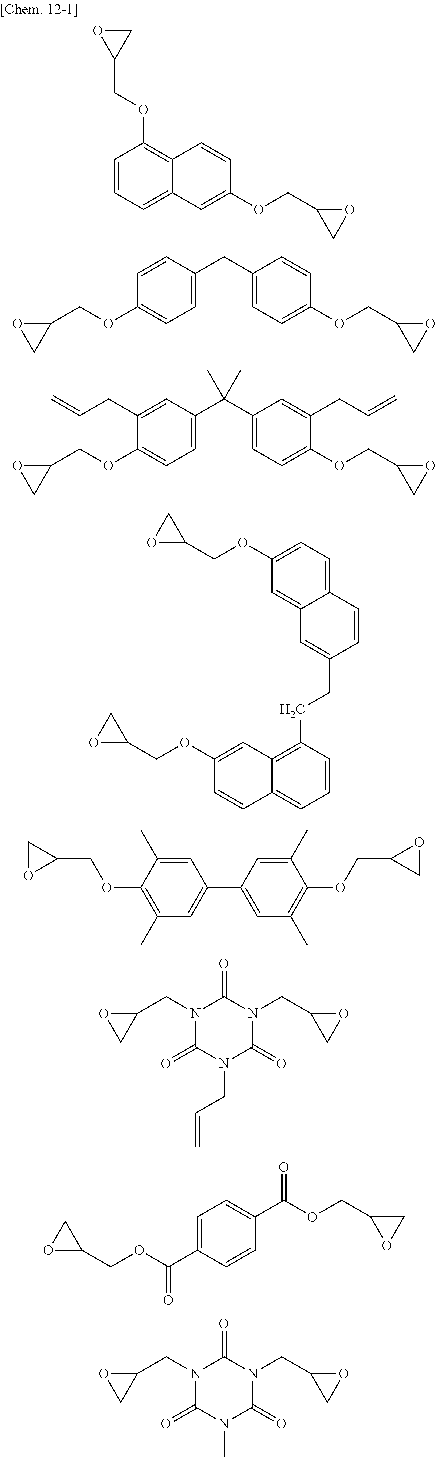

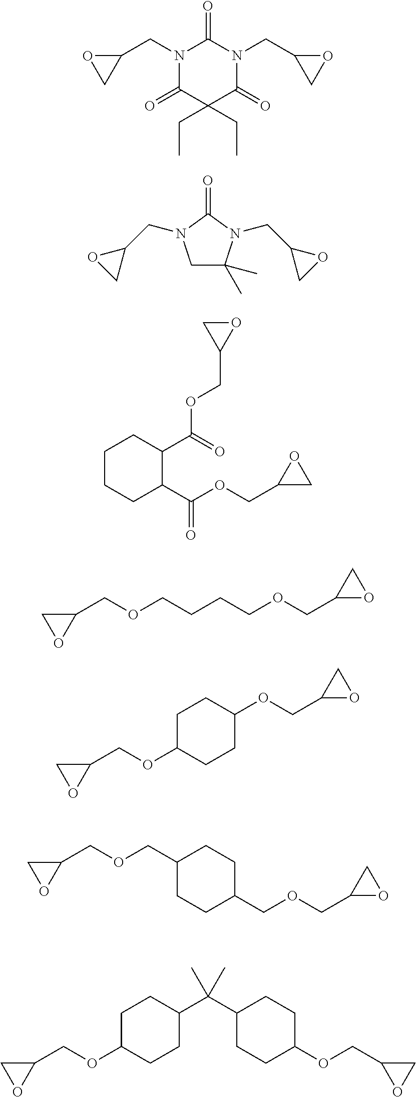

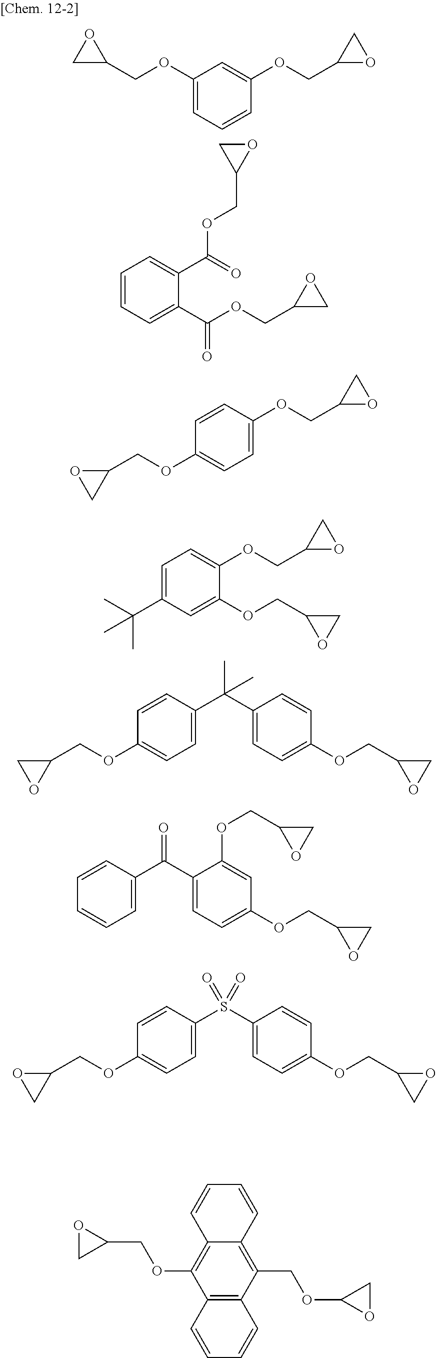

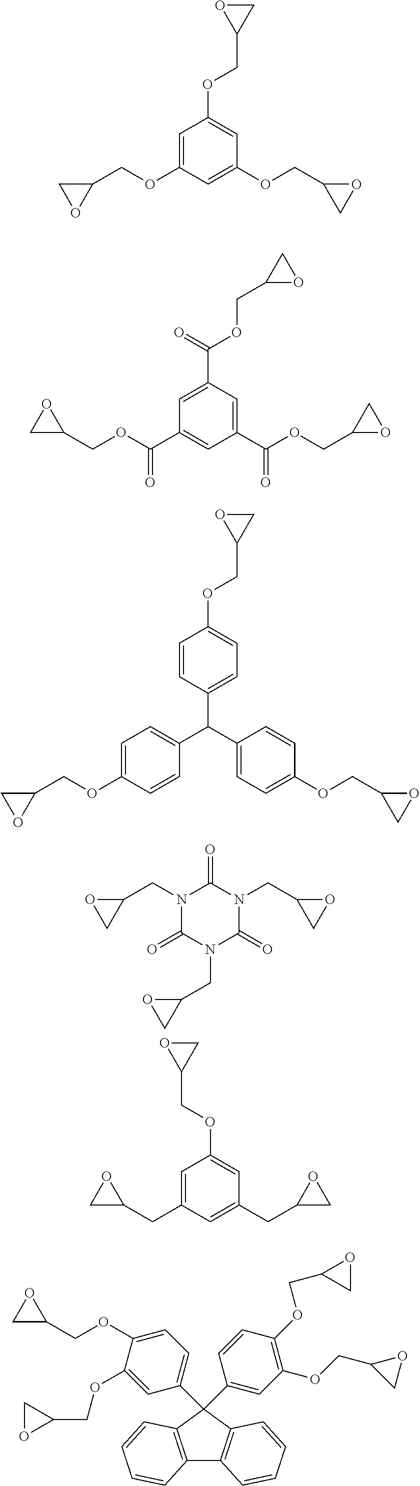

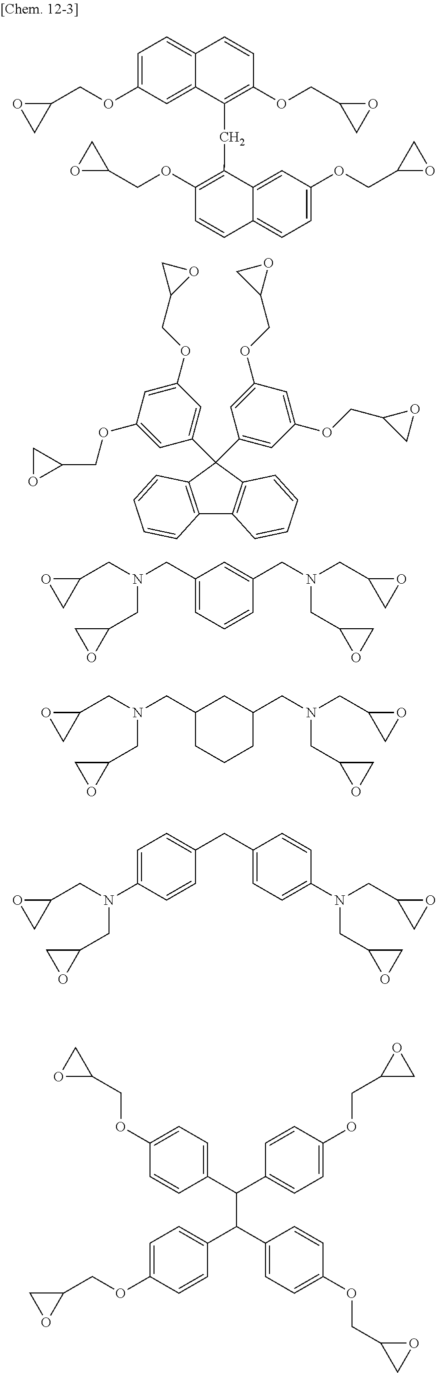

Examples of the compound represented by Formula (101) include the following.

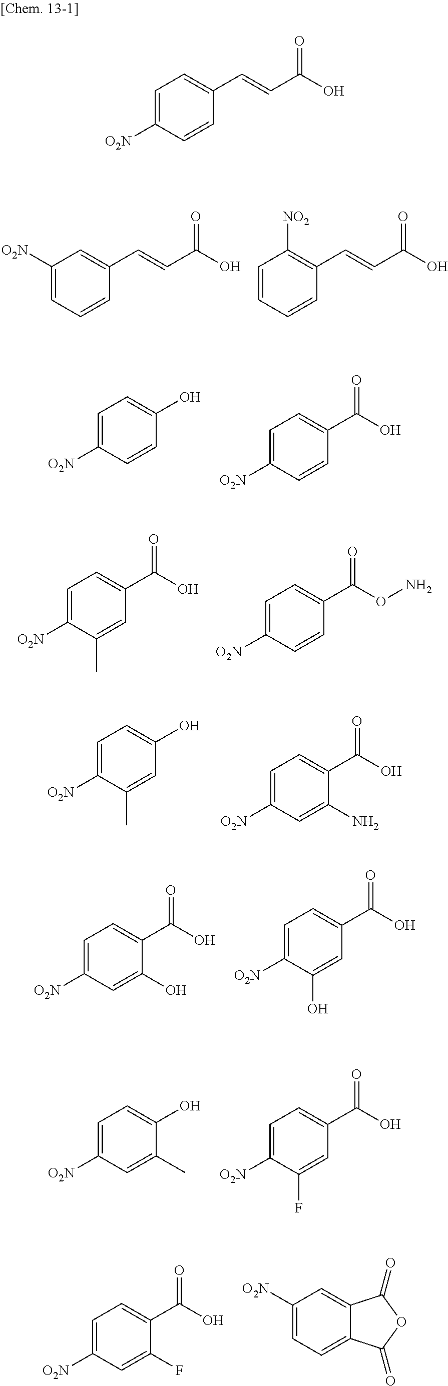

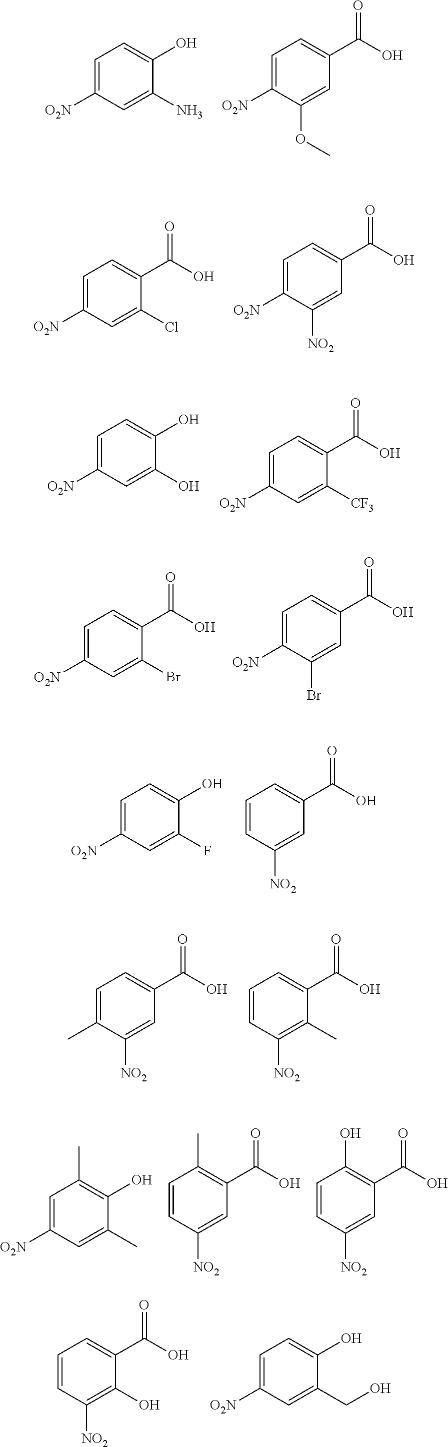

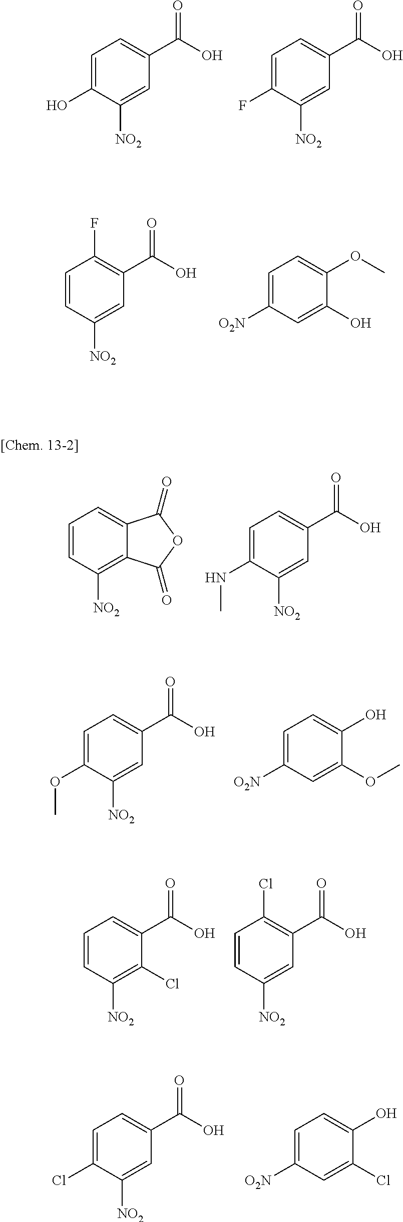

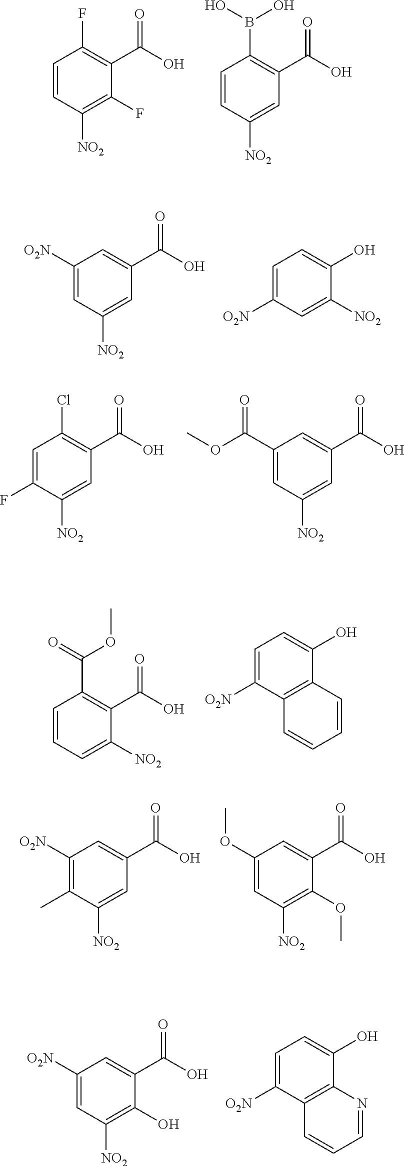

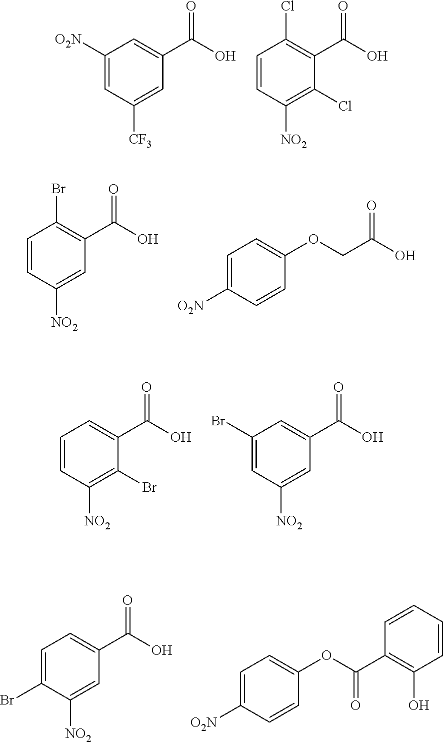

A lower limit of a weight average molecular weight of the compound measured by gel permeation chromatography as described in Examples is, for example, 200 or 300, for example, and an upper limit of the weight average molecular weight of the compound is 1,999, 1,500, or 1,200, for example.

<Resist Underlayer Film-forming Composition A (Containing Polymer)>

The resist underlayer film-forming composition of the present invention may contain a solvent and a polymer, which may have a structure represented by Formula (100) at a terminal thereof.

(Polymer)

The polymer (copolymer or resin) contained in the resist underlayer film-forming composition of the present invention is not limited as long as the advantageous effects of the present invention are exhibited, and may be, for example, a polymer having the following structure described in WO 2009/008446 A. The polymer has a repeating unit structure represented by the following Formula (1):

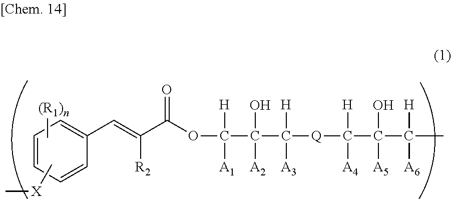

(in the formula, R₁ represents a methoxy group, an alkyl group having 1 to 13 carbon atoms, or a halogen atom; n represents an integer of 0 to 4; R₂ represents a hydrogen atom, a cyano group, a phenyl group, an alkyl group having 1 to 13 carbon atoms, or a halogen atom; X represents an ether bond or an ester bond; A₁, A₂, A₃, A₄, A₅, and A₆ are each independently represent a hydrogen atom, a methyl group, or an ethyl group; and Q represents a divalent organic group between two carbon atoms).

Further, the polymer may be a polymer described in WO 2011/074494 A, and having a repeating unit structure represented by the following Formula (1):

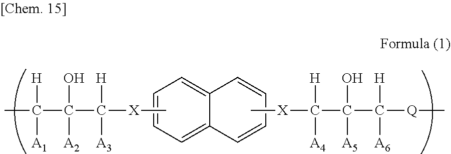

[in the formula, X represents an ester bond or an ether bond; each of A₁, A₂, A₃, A₄, A₅, and A₆ represents a hydrogen atom, a methyl group, or an ethyl group; and Q represents Formula (2) or Formula (3):

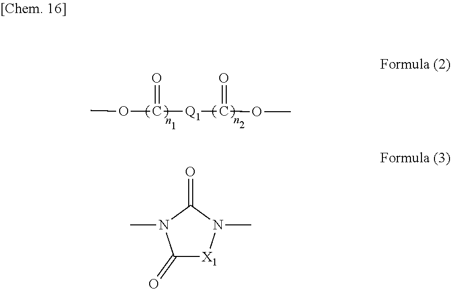

(in the formula, Q₁ represents an alkylene group having 1 to 10 carbon atoms, a phenylene group, a naphthylene group, or an anthrylene group, in which each of the phenylene group, the naphthylene group, and the anthrylene group may be substituted with a group selected from the group consisting of an alkyl group having 1 to 6 carbon atoms, a halogen atom, an alkoxy group having 1 to 6 carbon atoms, a nitro group, a cyano group, a hydroxyl group, and an alkylthio group having 1 to 6 carbon atoms; each of n1 and n2 represents the number of 0 or 1; and X₁ represents Formula (4), (5), or (6):

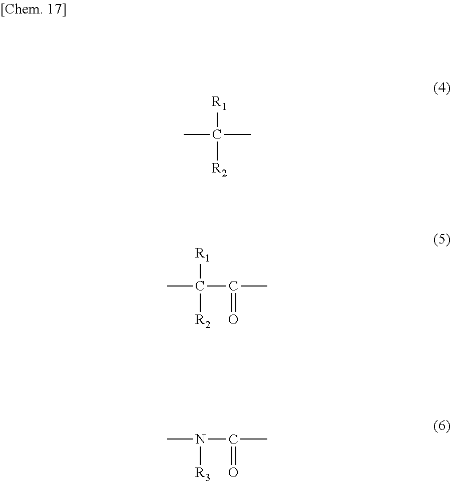

(in the formula, each of R₁ and R₂ represents a hydrogen atom, an alkyl group having 1 to 6 carbon atoms, an alkenyl group having 2 to 6 carbon atoms, a benzyl group, or a phenyl group, in which the benzyl group and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxyl group, and an alkylthio group having 1 to 6 carbon atoms; R₁ and R₂ may be bonded to each other to form a ring having 3 to 6 carbon atoms; and R₃ represents an alkyl group having 1 to 6 carbon atoms, an alkenyl group having 2 to 6 carbon atoms, a benzyl group, or a phenyl group, in which the benzyl group and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxyl group, and an alkylthio group having 1 to 6 carbon atoms))].

Further, the polymer may be a polymer having the following structure described in WO 2013/018802 A.

The polymer has a repeating unit structure represented by Formula (1a):

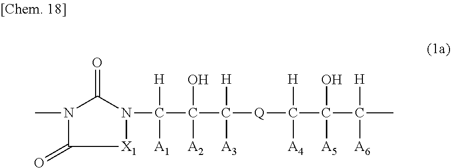

[in the formula, each of A₁, A₂, A₃, A₄, A₅, and A₆ represents a hydrogen atom, a methyl group, or an ethyl group; X₁ is represented by Formula (2), (3), (4), or (0):

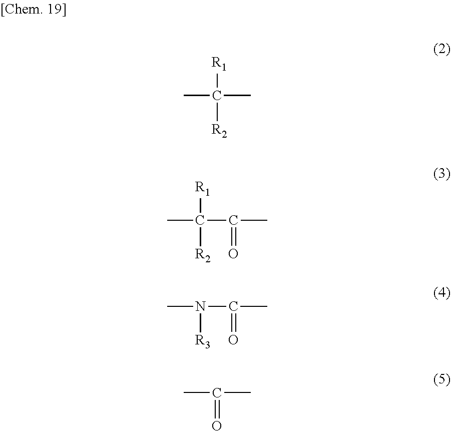

(in Formulas (2), (3), (4), and (0), each of R₁ and R₂ represents a hydrogen atom, a halogen atom, an alkyl group having 1 to 6 carbon atoms, an alkenyl group having 3 to 6 carbon atoms, a benzyl group, or a phenyl group, in which the alkyl group having 1 to 6 carbon atoms, the alkenyl group having 3 to 6 carbon atoms, the benzyl group, and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, a carboxyl group, and an alkylthio group having 1 to 6 carbon atoms; R₁ and R₂ may be bonded to each other to form a ring having 3 to 6 carbon atoms; R₃ represents a halogen atom, an alkyl group having 1 to 6 carbon atoms, an alkenyl group having 3 to 6 carbon atoms, a benzyl group, or a phenyl group, in which the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms); and Q is represented by Formula (5) or Formula (6):

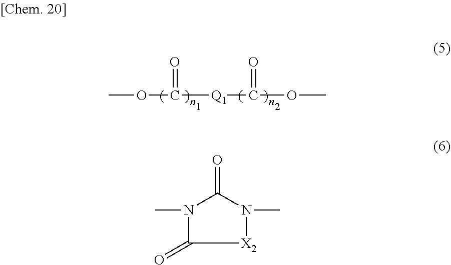

(in the formula, Q₁ represents an alkylene group having 1 to 10 carbon atoms, a phenylene group, a naphthylene group, or an anthrylene group, in which each of the alkylene group, the phenylene group, the naphthylene group, and the anthrylene group may be substituted with a group selected from the group consisting of an alkyl group having 1 to 6 carbon atoms, a carbonyloxyalkyl group having 2 to 7 carbon atoms, a halogen atom, an alkoxy group having 1 to 6 carbon atoms, a phenyl group, a nitro group, a cyano group, a hydroxy group, an alkylthio group having 1 to 6 carbon atoms, a group having a disulfide group, a carboxyl group, and a combination thereof; each of n₁ and n₂ represents the number of 0 or 1; and X₂ represents Formula (2), Formula (3), or Formula (0)].

In addition, the polymer of the present invention may be a resin having a repeating structural unit containing at least one —C(═O)—O— group in a main chain and a repeating structural unit containing at least one hydroxy group in a side chain, or having a repeating structural unit containing at least one —C(═O)—O— group in a main chain and at least one hydroxy group in a side chain, as described in WO 2020/026834 A.

Further, the resin may be a copolymer having a repeating structural unit represented by the following (1-1) and a repeating structural unit represented by the following Formula (1-2).

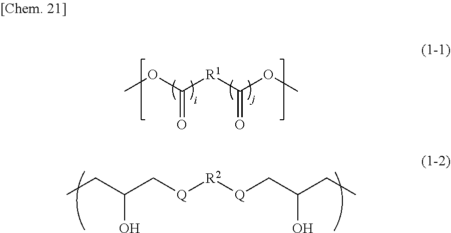

(Formulas (1-1) and (1-2), R¹ and R² each independently represent a divalent organic group containing a linear, branched, or cyclic functional group having 2 to 20 carbon atoms, the organic group may contain at least one sulfur atom, nitrogen atom, or oxygen atom; i and j each independently represent 0 or 1; two Q's each represent a single bond, an —O— group or a —C(═O)—O— group, provided that when both i and j are 0, at least one Q out of the two Q's represents a —C(═O)—O— group.)

For example, as the resin, it is possible to use a copolymer of at least one compound represented by the following Formula (A):

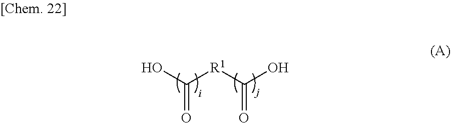

(in Formula (A), R¹, i, and j represent the same meaning as defined above), and
at least one diepoxy compound represented by the following Formula (B):

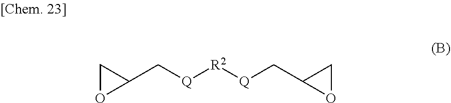

(in Formula (B), R² and Q represent the same meaning as defined above).

That is, a copolymer having a repeating structural unit represented by Formula (1-1) and a repeating structural unit represented by Formula (1-2) is obtained by dissolving at least one compound represented by Formula (A) and at least one diepoxy compound represented by Formula (B) in an organic solvent so as to have an appropriate molar ratio, and polymerizing these compounds, if necessary, in the presence of a catalyst.

The compound represented by Formula (A) is not particularly limited, and examples thereof include compounds represented by the following formulas.

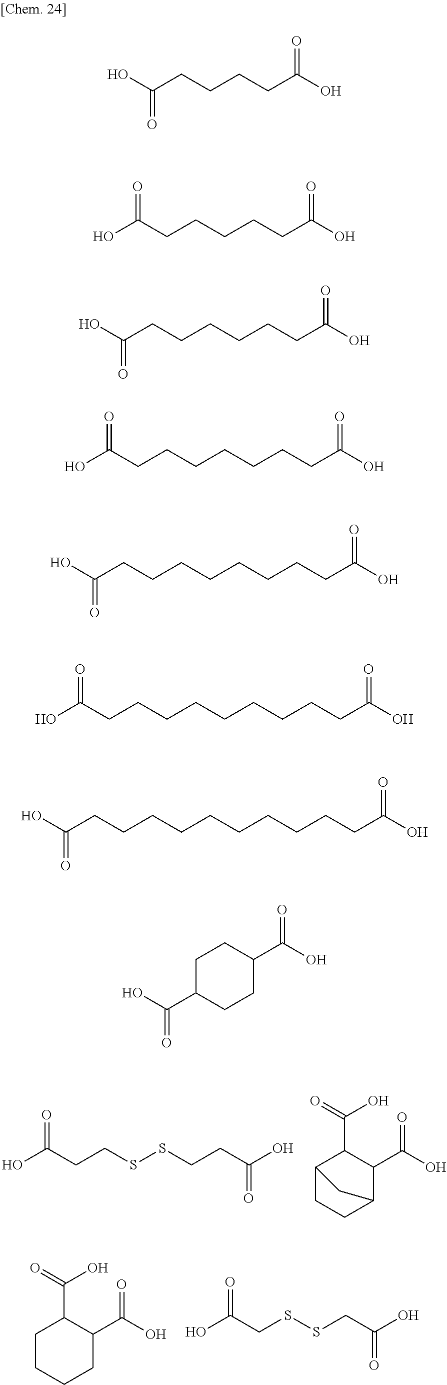

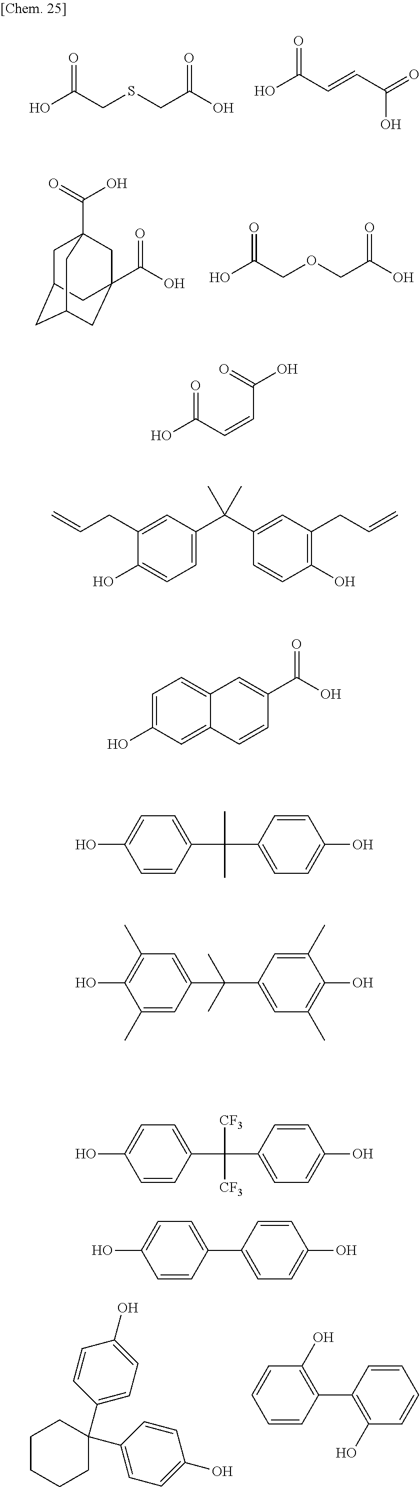

The diepoxy compound represented by Formula (B) is not particularly limited, and examples thereof include the following diepoxy compounds.

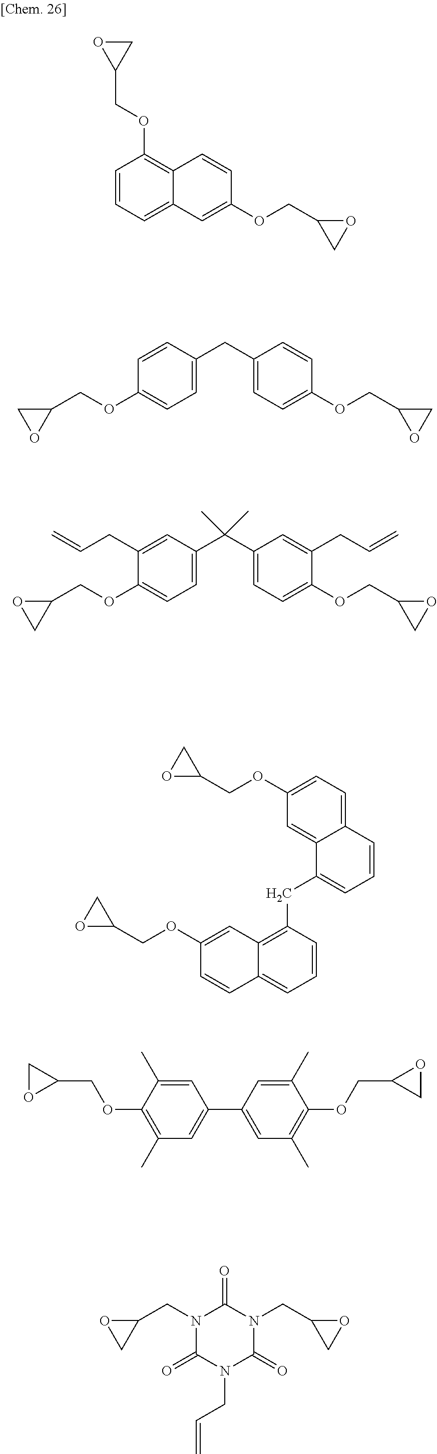 [SMILES: c1cc(OCC2CO2)c2ccc(OCC3CO3)cc2c1 ; c1cc(OCC2CO2)ccc1Cc1ccc(OCC2CO2)cc1 ; C=CCc1cc(C(C)(C)c2ccc(OCC3CO3)c(CC=C)c2)ccc1OCC1CO1 ; c1cc(Cc2cccc3ccc(OCC4CO4)cc23)c2cc(OCC3CO3)ccc2c1 ; Cc1cc(-c2cc(C)c(OCC3CO3)c(C)c2)cc(C)c1OCC1CO1 ; C=CCn1c(=O)n(CC2CO2)c(=O)n(CC2CO2)c1=O]

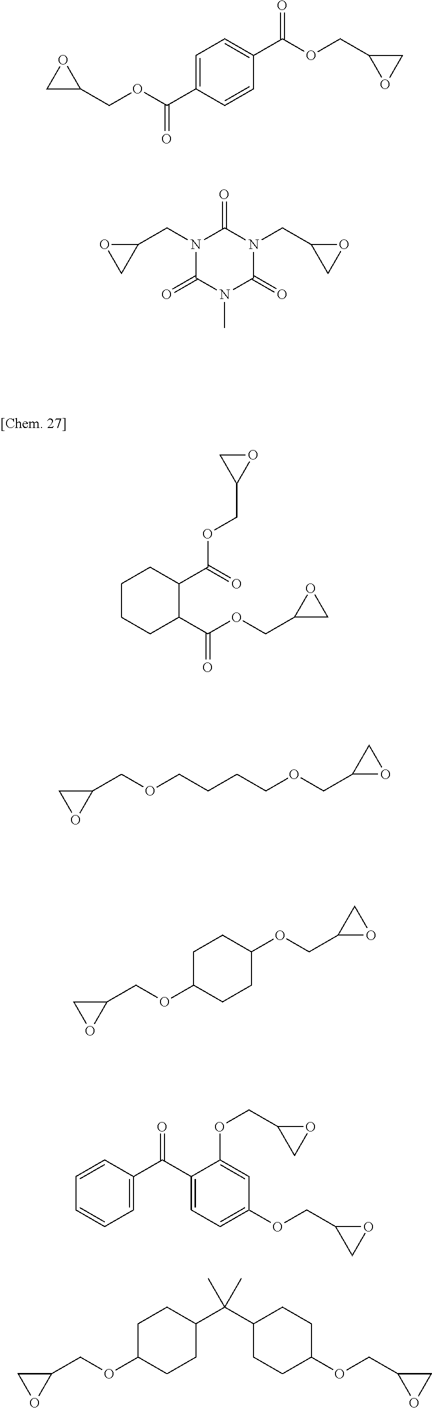

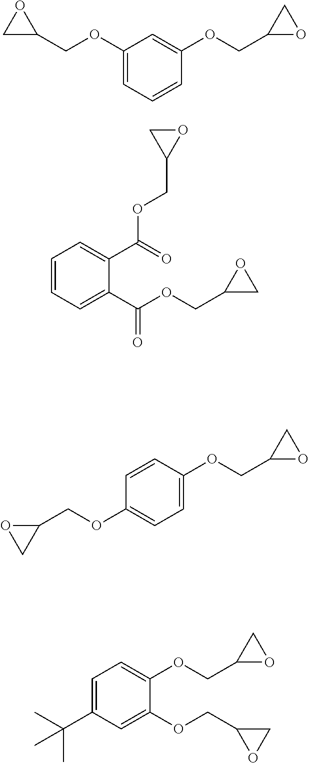

Examples of the copolymer having a repeating structural unit represented by Formula (1-1) and a repeating structural unit represented by the following Formula (1-2) include copolymers having repeating structural units represented by the following Formulas (1a) to (1n).

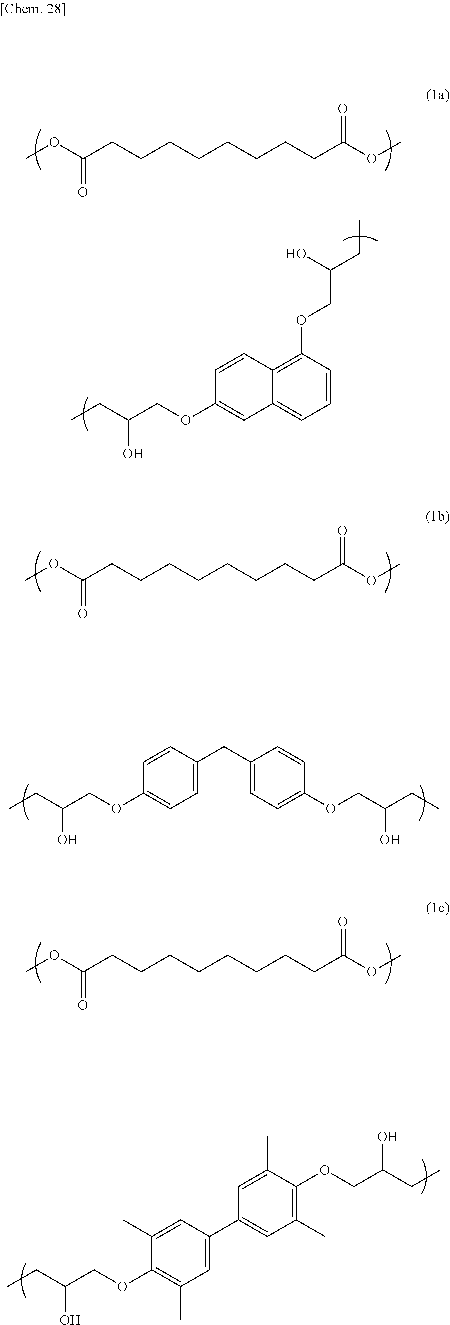

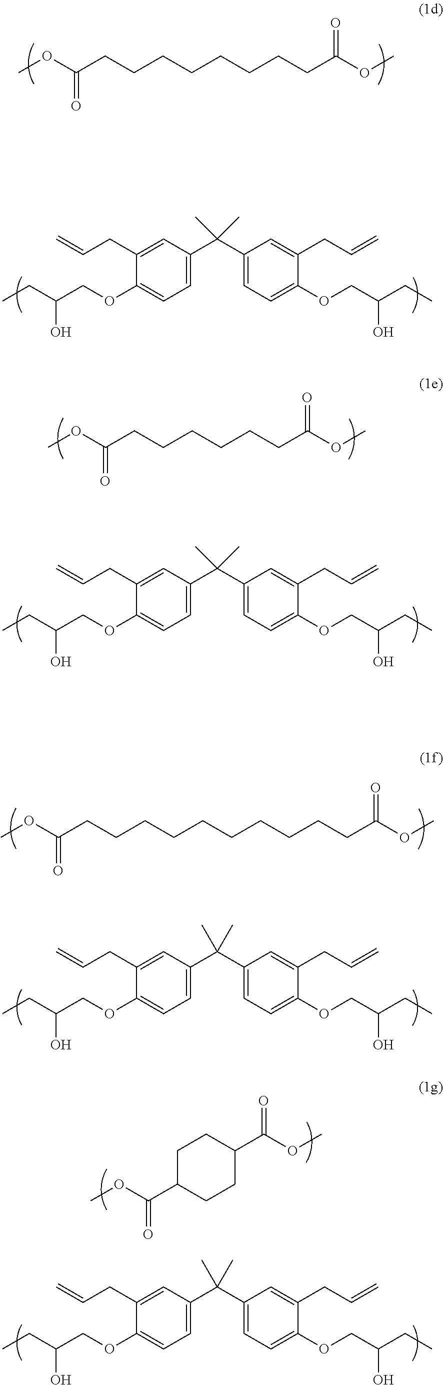

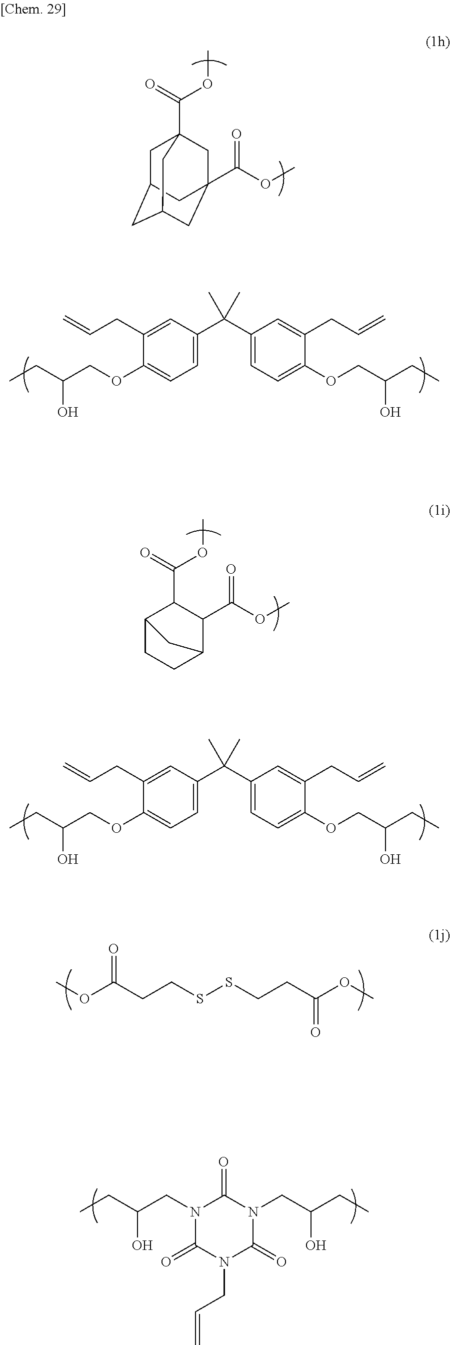

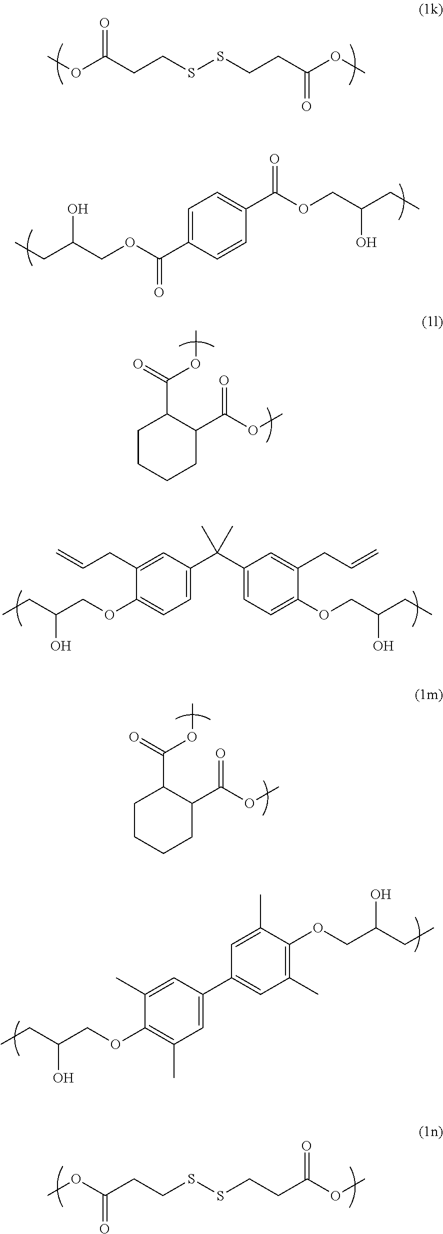

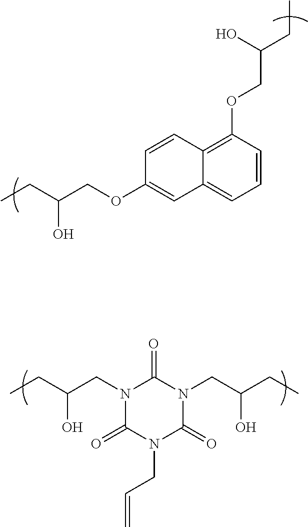

The entire disclosures of WO 2009/008446 A, WO 2011/074494 A, WO 2013/018802 A, and WO 2020/026834 A are incorporated herein by reference.

The polymer may be a polymer obtained by a reaction of a compound containing two or more epoxy groups with a compound represented by the following Formula (102):

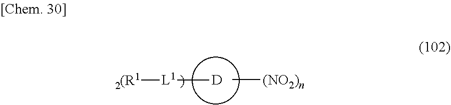

(in Formula (102), R¹ represents a group having reactivity with an epoxy group; D represents an arylene group having 6 to 40 carbon atoms or a heterocyclic ring; L¹ and n have the same meaning as L⁰ and n in Formula (100), and preferably L¹ represents an optionally substituted alkenylene group having 2 to 10 carbon atoms; n quantity of R¹ each independently represent a group selected from the group consisting of a hydroxy group, a halogen atom, a carboxy group, a nitro group, a cyano group, a methylenedioxy group, an acetoxy group, a methylthio group, an amino group, an optionally substituted alkyl group having 1 to 10 carbon atoms, and an optionally substituted alkoxy group having 1 to 10 carbon atoms; and n represents an integer of 0 to 5).

The compound containing two or more epoxy groups is as described above.

Examples of the heterocyclic ring include furan, thiophene, pyrrole, imidazole, pyran, pyridine, pyrimidine, pyrazine, pyrrolidine, piperidine, piperazine, morpholine, indole, purine, quinoline, isoquinoline, quinuclidine, chromene, thianthrene, phenothiazine, phenoxazine, xanthene, acridine, phenazine, carbazole, triazinone, triazinedione, and triazinetrione. Of these, triazinone, triazinedione, and triazinetrione are preferable.

The polymer may have a structure represented by Formula (100) at a terminal thereof.

The polymer may be a polymer represented by the following Formula (P):

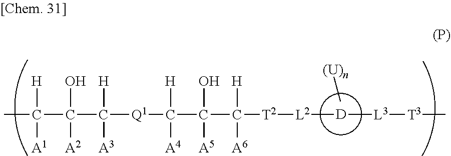

(in Formula (P), A¹, A², A³, A⁴, A⁵, and A⁶ each independently represent a hydrogen atom, a methyl group, or an ethyl group; Q¹ represents a divalent organic group; T² and T³ each independently represent a single bond, an ester bond, or an ether bond; L² and L³ each independently represent a single bond, an optionally substituted alkylene group having 1 to 10 carbon atoms, or an optionally substituted alkenylene group having 2 to 10 carbon atoms; U represents a hydrogen atom or a nitro group; D represents an aromatic ring having 6 to 40 carbon atoms or a heterocyclic ring; and n represents an integer of 1 to 3). The meaning and specific examples of each term are as described above.

The epoxy group-containing compound, the compound containing two or more epoxy groups, or Q¹ may have a heterocyclic structure. Specific examples of the heterocyclic structure are as follows.

At least one of L¹ to L³ may be an alkenylene group having 2 to 10 carbon atoms.

Of the alkenylene groups having 2 to 10 carbon atoms, a vinylene group is preferable.

A lower limit of a weight average molecular weight of the polymer measured by gel permeation chromatography as described in Examples is, for example, 1,000 or 2,000, for example, and an upper limit of the weight average molecular weight of the polymer is 30,000, 20,000, or 10,000, for example.

<Resist Underlayer Film-Forming Composition B>

The resist underlayer film-forming composition includes a resist underlayer film-forming composition B containing a solvent and a polymer or compound having at a terminal thereof a structure represented by the following Formula (200):

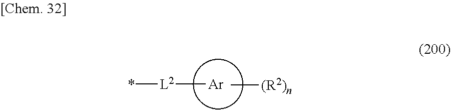

(in Formula (200), Ar represents an optionally substituted aromatic ring having 6 to 40 carbon atoms; L² represents an optionally substituted alkenylene group having 2 to 10 carbon atoms; n quantity of R² each independently represent a group selected from the group consisting of a hydroxy group, a halogen atom, a carboxy group, a nitro group, a cyano group, a methylenedioxy group, an acetoxy group, a methylthio group, an amino group, an optionally substituted alkyl group having 1 to 10 carbon atoms, and an optionally substituted alkoxy group having 1 to 10 carbon atoms; n represents an integer of 0 to 5; and * represents a binding site to a residue of the polymer or compound).

It is preferable that R² is at most three groups selected from the groups described above.

The aromatic ring having 6 to 40 carbon atoms, the alkylene group having 1 to 10 carbon atoms, the alkenylene group having 2 to 10 carbon atoms, the alkyl group having 1 to 10 carbon atoms, and the alkoxy group having 1 to 10 carbon atoms are as described above.

The structure of Formula (200) is preferably a structure derived from cinnamic acid.

The polymer may be a reaction product of a compound (A) containing two or more epoxy groups and a compound (B) containing two or more groups having reactivity with the epoxy group.

Specific examples of the compound (A) containing two or more epoxy groups and the compound (B) containing a group having reactivity with the epoxy group are as described above.

Specific examples of the compound (B) containing two or more groups having reactivity with the epoxy group include the compounds shown below.

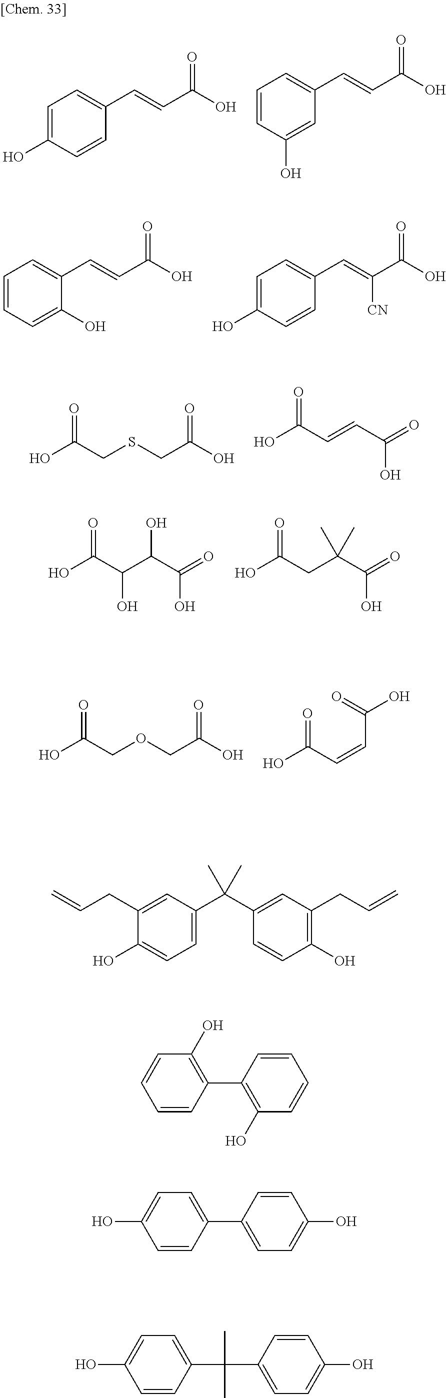

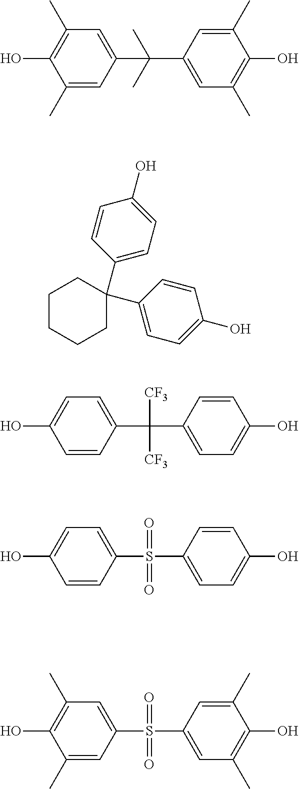 [SMILES: Cc1cc(C(C)(C)c2cc(C)c(O)c(C)c2)cc(C)c1O ; Oc1ccc(C2(c3ccc(O)cc3)CCCCC2)cc1 ; Oc1ccc(C(c2ccc(O)cc2)(C(F)(F)F)C(F)(F)F)cc1 ; O=S(=O)(c1ccc(O)cc1)c1ccc(O)cc1 ; Cc1cc(S(=O)(=O)c2cc(C)c(O)c(C)c2)cc(C)c1O]

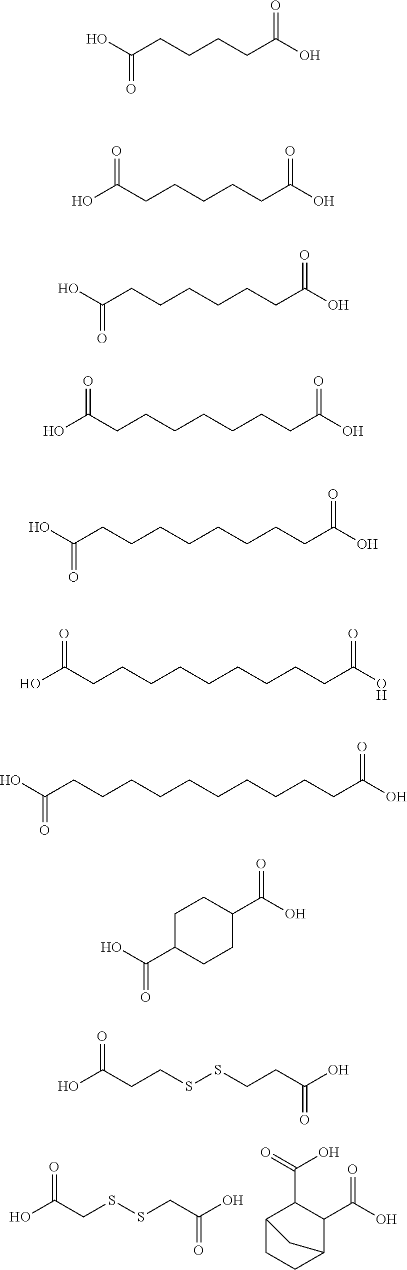

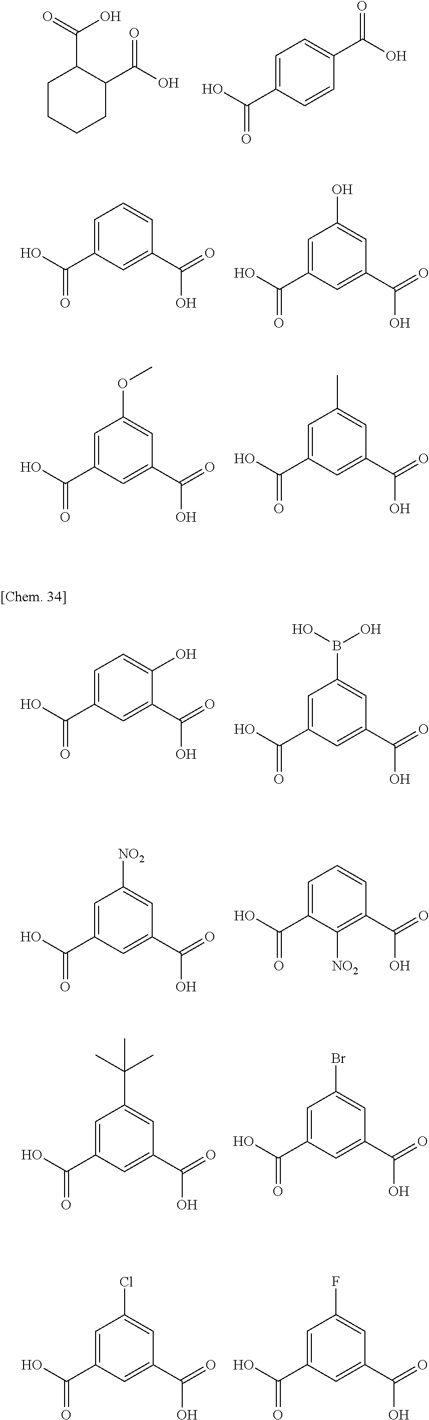

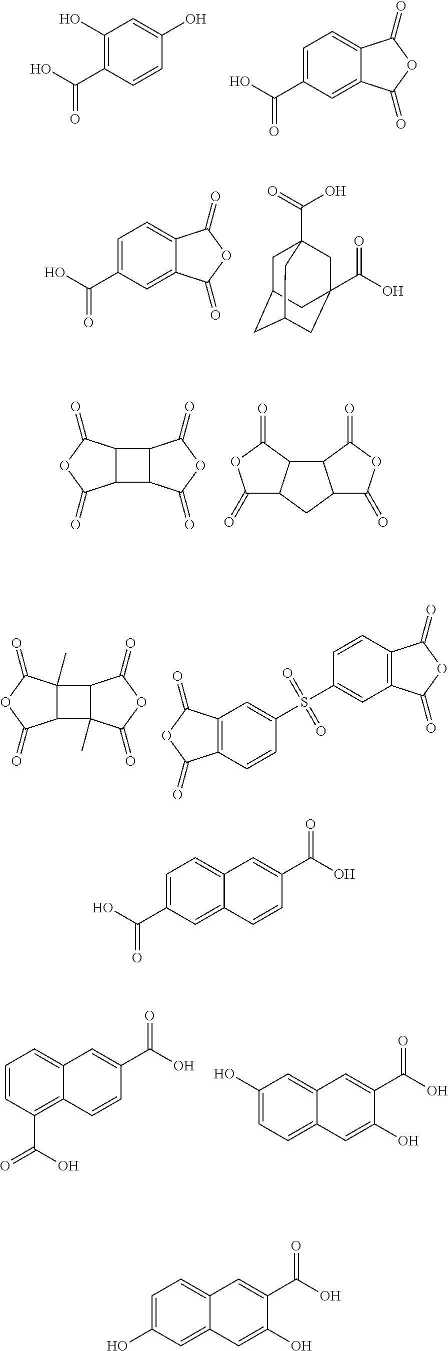

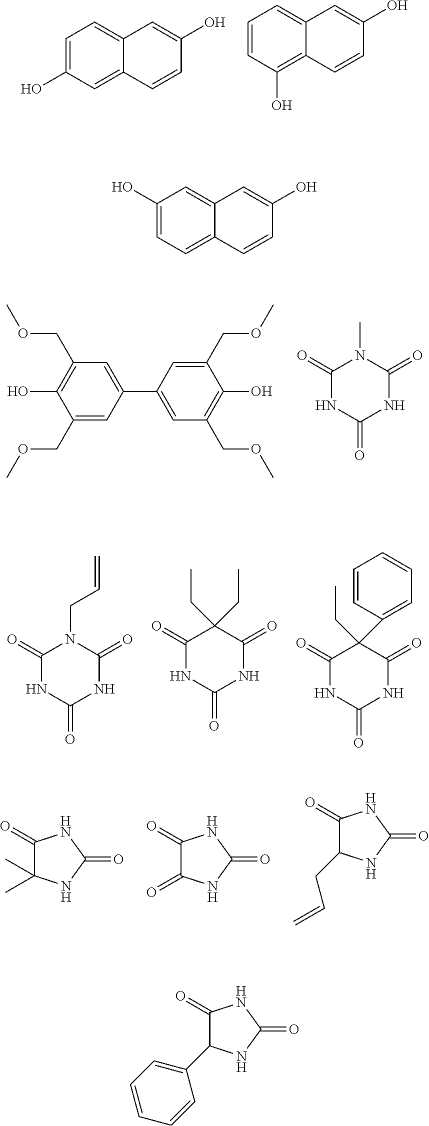

The compounds (A) and (B) may have a heterocyclic structure or an aromatic ring structure having 6 to 40 carbon atoms.

The heterocyclic structure is as described above.

In addition, the heterocyclic structure may have a structure derived from barbituric acid.

The aromatic ring structure having 6 to 40 carbon atoms is as described above.

The polymer may have a unit structure represented by the following Formula (P):

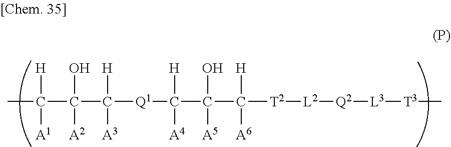

(in Formula (P), A¹, A², A³, A⁴, A⁵, and A⁶ each independently represent a hydrogen atom, a methyl group, or an ethyl group; Q¹ and Q² each independently represent a divalent organic group having a heterocyclic structure or an aromatic ring structure having 6 to 40 carbon atoms; T² and T³ each independently represent a single bond, an ester bond, or an ether bond; and L² and L³ each independently represent a single bond, an optionally substituted alkylene group having 1 to 10 carbon atoms, or an optionally substituted alkenylene group having 2 to 10 carbon atoms). Each term is as defined above.

<Compound>

The compound of the present application is not limited as long as it is a compound exhibiting the advantageous effects of the present application, and has the structure of Formula (200) at a terminal thereof.

Specific examples of a precursor of the compound for inducing the residue of the compound include the precursor of the compounds exemplified for the compound (A) containing two or more epoxy groups.

The residue of the compound may have a heterocyclic structure or an aromatic ring structure having 6 to 40 carbon atoms.

The heterocyclic structure may be triazinetrione.

<Resist Underlayer Film-forming Composition C>

The resist underlayer film-forming composition of the present invention includes a resist underlayer film-forming composition C containing a solvent and a polymer having at a terminal thereof a structure represented by the following Formula (300):

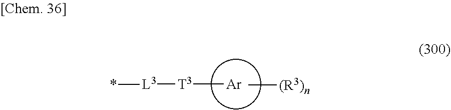

(in Formula (300), Ar represents an optionally substituted aryl group having 6 to 40 carbon atoms; L³ represents a single bond, an ester bond, or an ether bond; T³ represents a single bond, an optionally substituted alkylene group having 1 to 10 carbon atoms, or an optionally substituted alkenylene group having 2 to 10 carbon atoms; n quantity of R³ each independently represent a monovalent organic group; n represents an integer of 0 to 5; * represents a binding site to a residue of the polymer; and at least one cyano group is present in Formula (300)).

The expression “at least one cyano group is present in Formula (300)” means that at least one of Ar, L³, T³, and R³ carries a cyano group.

The alkylene group having 1 to 10 carbon atoms, the alkenylene group having 2 to 10 carbon atoms, and the alkoxy group having 1 to 10 carbon atoms are as described above.

R³ represents a monovalent organic group, and is not particularly limited as long as the advantageous effects of the present invention are not impaired, and examples thereof include a cyano group or a group represented by the following formula.

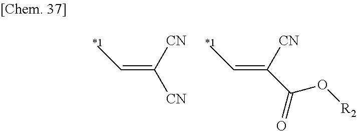

(In the formula, *1 represents a binding site to the aryl group having 6 to 40 carbon atoms. R₂ represents an alkyl group having 1 to 10 carbon atoms, an alkoxy group having 1 to 10 carbon atoms, an alkenyl group having 2 to 10 carbon atoms, a benzyl group, or a phenyl group, and the phenyl group may be substituted with a group selected from the group consisting of an alkyl group having 1 to 10 carbon atoms, a halogen atom, an alkoxy group having 1 to 10 carbon atoms, a nitro group, a cyano group, a hydroxy group, and an alkylthio group having 1 to 10 carbon atoms.)

<Polymer>

The polymer may be a reaction product of a compound (A) containing two or more epoxy groups with a compound (B) represented by the following Formula (301):

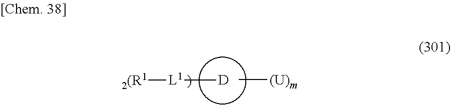

(In Formula (301), R² represents a group having reactivity with an epoxy group; U represents a group selected from the group consisting of a halogen atom, a carboxy group, a nitro group, a cyano group, a methylenedioxy group, an acetoxy group, a methylthio group, an amino group, an optionally substituted alkyl group having 1 to 10 carbon atoms, an optionally substituted alkenyl group having 2 to 10 carbon atoms, an optionally substituted alkoxy group having 1 to 10 carbon atoms, and a combination thereof; m represents an integer of 0 to 5; D represents an arylene group having 6 to 40 carbon atoms or a heterocyclic ring; and L¹ has the same meaning as that in [1]).

The compound (A) containing two or more epoxy groups is as exemplified above as the epoxy group-containing compound.

The group having reactivity with the epoxy group is as described above.

Specific examples of the optionally substituted alkyl group having 1 to 10 carbon atoms, the optionally substituted alkenyl group having 2 to 10 carbon atoms, and the optionally substituted alkoxy group having 1 to 10 carbon atoms are as described above.

The arylene group having 6 to 40 carbon atoms and the heterocyclic ring are as described above.

Specific examples of the compound containing two or more groups having reactivity with the epoxy group may be compounds shown below.

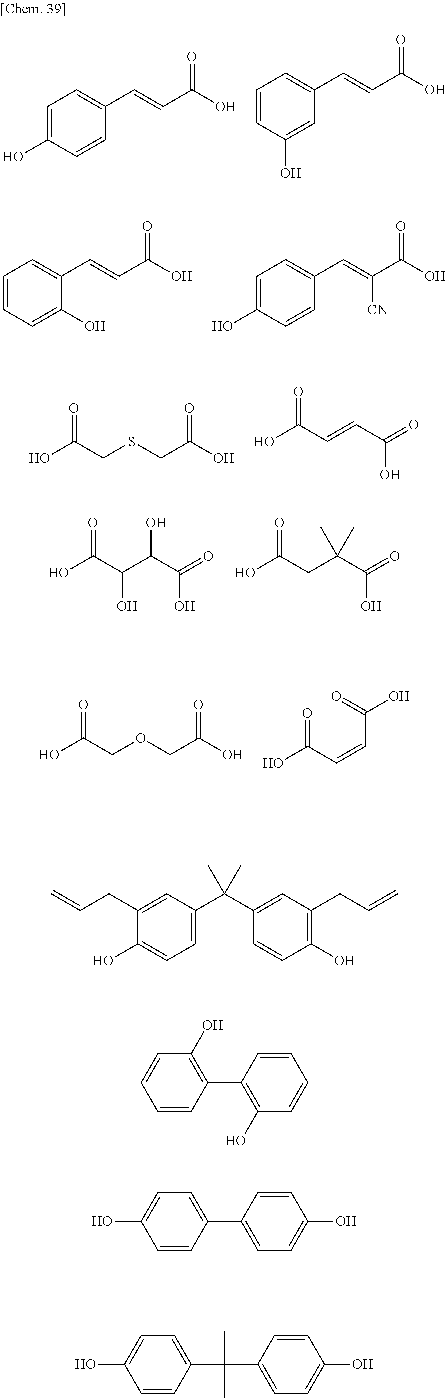

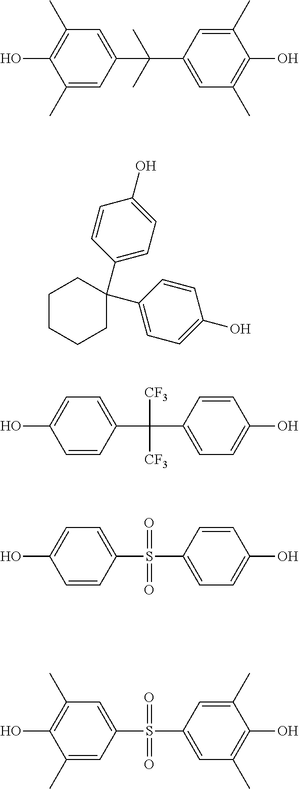 [SMILES: Cc1cc(C(C)(C)c2cc(C)c(O)c(C)c2)cc(C)c1O ; Oc1ccc(C2(c3ccc(O)cc3)CCCCC2)cc1 ; Oc1ccc(C(c2ccc(O)cc2)(C(F)(F)F)C(F)(F)F)cc1 ; O=S(=O)(c1ccc(O)cc1)c1ccc(O)cc1 ; Cc1cc(S(=O)(=O)c2cc(C)c(O)c(C)c2)cc(C)c1O]

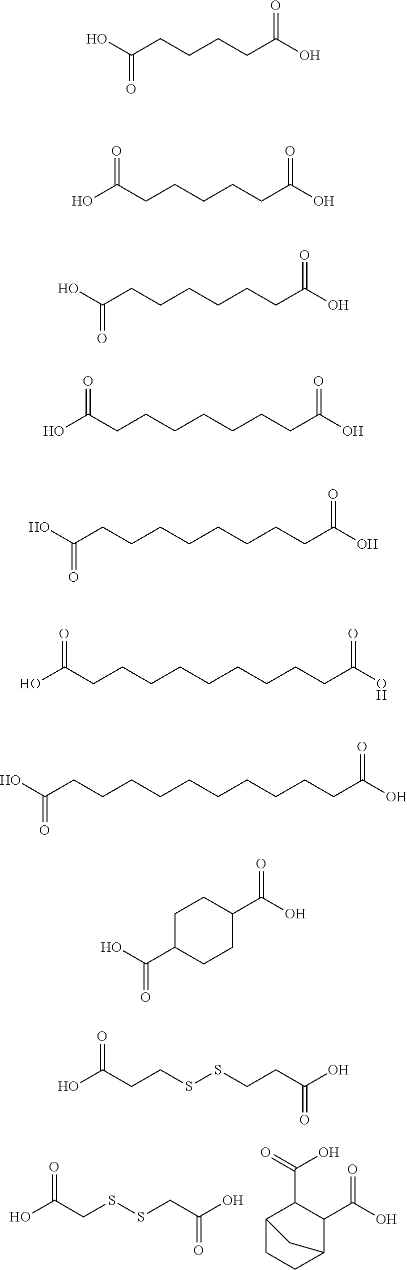

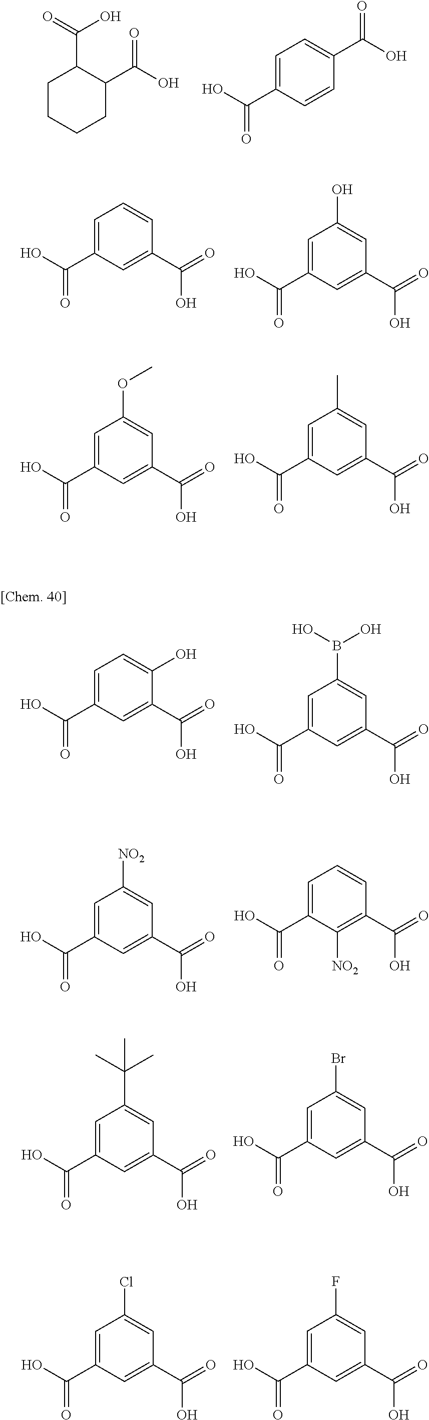

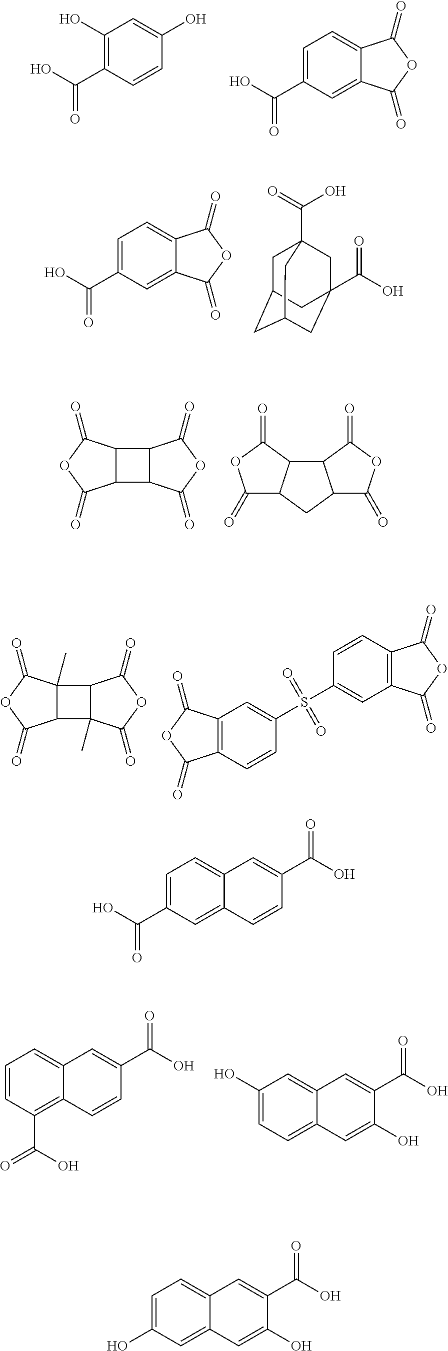

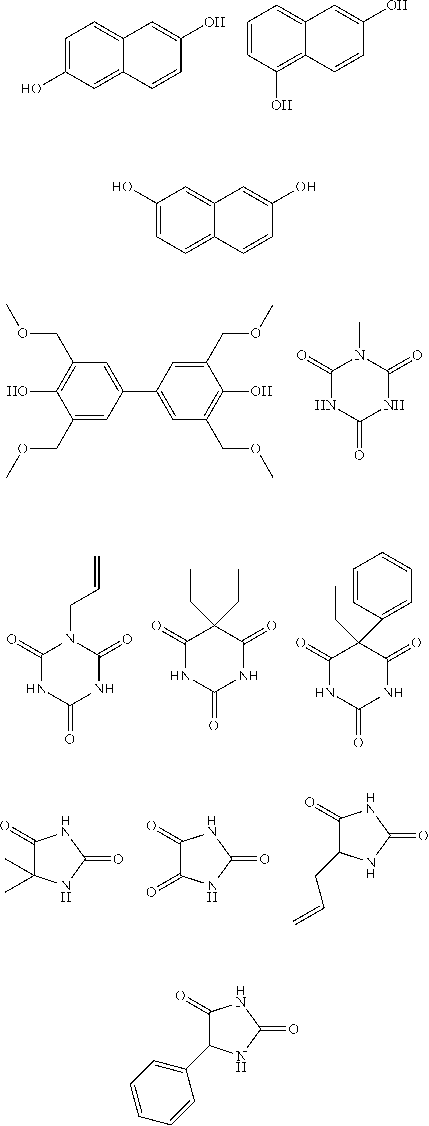

The polymer may be represented by the following Formula (P):

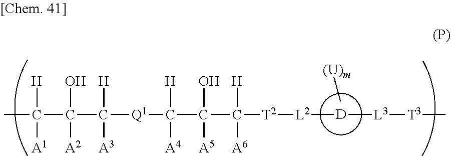

(in Formula (P). A¹, A², A³, A⁴, A⁵, and A⁶ each independently represent a hydrogen atom, a methyl group, or an ethyl group; Q¹ represents a divalent organic group; T² and T³ each independently represent a single bond, an ester bond, or an ether bond; L² and L³ each independently represent a single bond, an optionally substituted alkylene group having 1 to 10 carbon atoms, or an optionally substituted alkenylene group having 2 to 10 carbon atoms; D represents an arylene group having 6 to 40 carbon atoms or a heterocyclic ring; and U and m have the same meaning as those in [2]).

Q¹ may be derived from a compound (A) containing two or more epoxy groups. Alternatively, Q¹ may be an optionally substituted heterocyclic structure or an optionally substituted arylene group having 6 to 40 carbon atoms. Each term is as described above.

<Solvent>

The solvent to be used in the resist underlayer film-forming composition of the present invention is not particularly limited as long as it is a solvent that can uniformly dissolve a solid-containing component such as the polymer at room temperature, and an organic solvent generally used in a chemical solution for a semiconductor lithography process is preferable. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propropylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, y-butyrolactone, N-methylpyrrolidone, N,N-dimethylformamide, and N,N-dimethylacetamide. These solvents may be used alone or in combination of two or more thereof.

Of these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

<Acid Generator>

As the acid generator contained as an optional component in the resist underlayer film-forming composition of the present invention, both a thermal acid generator and a photoacid generator can be used, but it is preferable to use a thermal acid generator. Examples of the thermal acid generator include sulfonic acid compounds such as p-toluenesulfonic acid, trifluoromethanesulfonic acid, pyridinium p-toluenesulfonate (pyridinium p-toluenesulfonic acid), pyridinium phenolsulfonic acid, pyridinium p-hydroxybenzenesulfonic acid (p-phenolsulfonic acid pyridinium salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid, and carboxylic acid compounds.

Examples of the photoacid generator include an onium salt compound, a sulfonimide compound, and a disulfonyl diazomethane compound.

Examples of the onium salt compound include iodonium salt compounds such as diphenyliodoniumhexafluorophosphate, diphenyliodoniumtrifluoromethanesulfonate, diphenyliodoniumnonafluoro n-butane sulfonate, diphenyliodoniumperfluoro n-octane sulfonate, diphenyliodoniumcamphorsulfonate, bis(4-tert-butylphenyl)iodoniumcamphorsulfonate, and bis(4-tert-butylphenyl)iodoniumtrifluoromethanesulfonate; and sulfonium salt compounds such as triphenylsulfoniumhexafluoroantimonate, triphenylsulfoniumnonafluoro n-butane sulfonate, triphenylsulfoniumcamphorsulfonate, and triphenylsulfoniumtrifluoromethanesulfonate.

Examples of the sulfonimide compound include N-(trifluoromethanesulfonyloxy)succinimide, N-(nonafluoro n-butanesulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generators may be used each alone or in combination of two or more thereof.

In a case where an acid generator is used, a content ratio of the acid generator is, for example, within the range of 0.1% by mass to 50% by mass, and preferably, 1% by mass to 30% by mass, relative to the following crosslinking agent.

<Crosslinking Agent>

Examples of a crosslinking agent contained as an optional component in the resist underlayer film-forming composition of the present invention include hexamethoxymethylmelamine, tetramethoxymethyl benzoguanamine, 1,3,4,6-tetrakis(methoxymethyl)glycoluril (tetramethoxymethyl glycoluril) (POWDERLINK [registered trademark] 1174), 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

In addition, the crosslinking agent of the present application may be a nitrogen-containing compound having 2 to 6 substituents represented by the following Formula (1d) bonded to a nitrogen atom per molecule, which is described in WO 2017/187969 A.

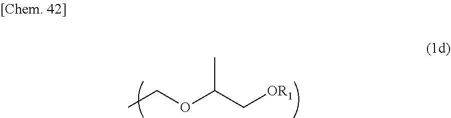

(In Formula (1d), R₁ represents a methyl group or an ethyl group.)

The nitrogen-containing compound having 2 to 6 substituents represented by Formula (1d) per molecule may be a glycoluril derivative represented by the following Formula (1E).

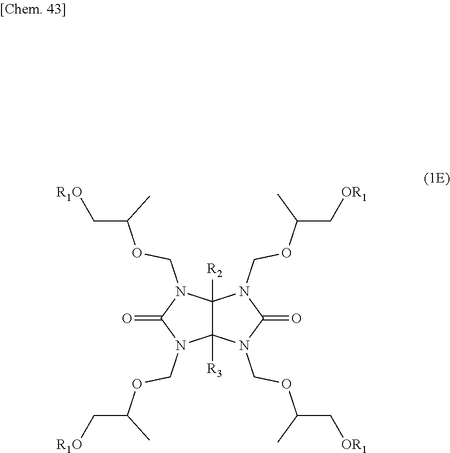

(In Formula (1E), four R₁'s each independently represent a methyl group or an ethyl group; and R₂ and R₃ each independently represent a hydrogen atom, an alkyl group having 1 to 4 carbon atoms, or a phenyl group.)

Examples of the glycoluril derivative represented by Formula (1E) include compounds represented by the following Formula (1E-1) to Formula (1E-6).

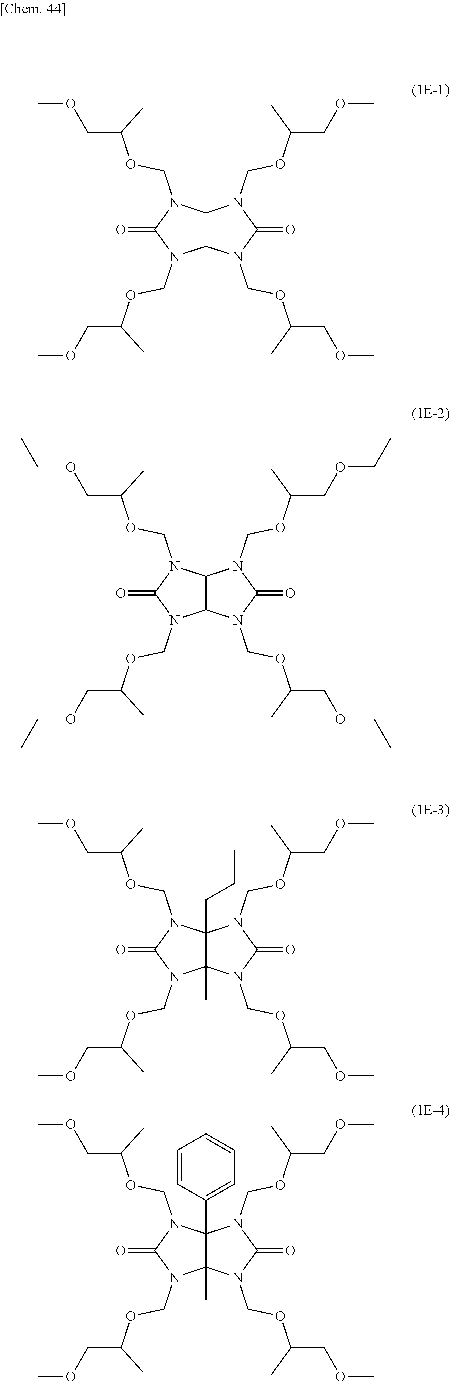

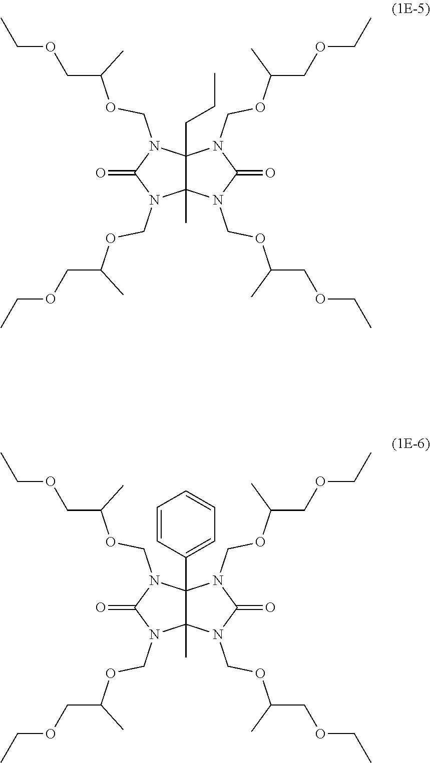

The nitrogen-containing compound having 2 to 6 substituents represented by Formula (1d) per molecule is obtained by reacting a nitrogen-containing compound having 2 to 6 substituents bonded to a nitrogen atom and represented by the following Formula (2d) per molecule with at least one compound represented by the following Formula (3d).

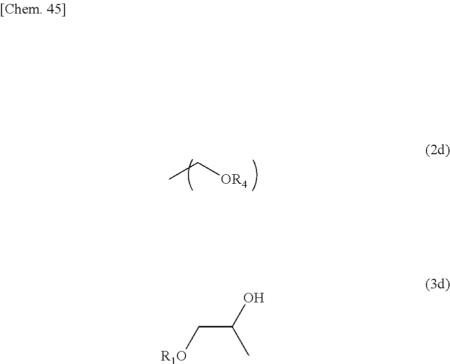

(In Formula (2d) and Formula (3d), R₁ represents a methyl group or an ethyl group; and R₄ represents an alkyl group having 1 to 4 carbon atoms.)

The glycoluril derivative represented by Formula (1E) is obtained by reacting a glycoluril derivative represented by the following Formula (2E) with at least one compound represented by Formula (3d).

The nitrogen-containing compound having 2 to 6 substituents represented by Formula (2d) per molecule is, for example, a glycoluril derivative represented by the following Formula (2E).

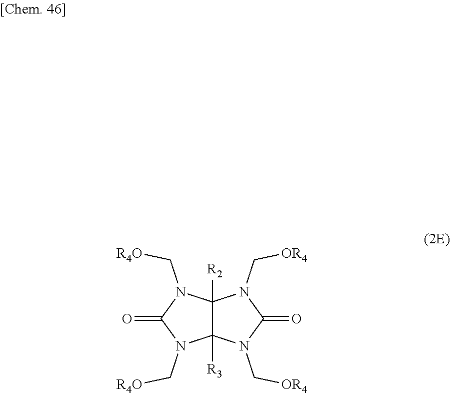

(In Formula (2E), R₂ and R₃ each independently represent a hydrogen atom, an alkyl group having 1 to 4 carbon atoms, or a phenyl group; and R⁴'s each independently represent an alkyl group having 1 to 4 carbon atoms.)

Examples of the glycoluril derivative represented by Formula (2E) include compounds represented by the following Formula (2E-1) through Formula (2E-4). Further, examples of the compound represented by Formula (3d) include compounds represented by the following Formula (3d-1) and Formula (3d-2).

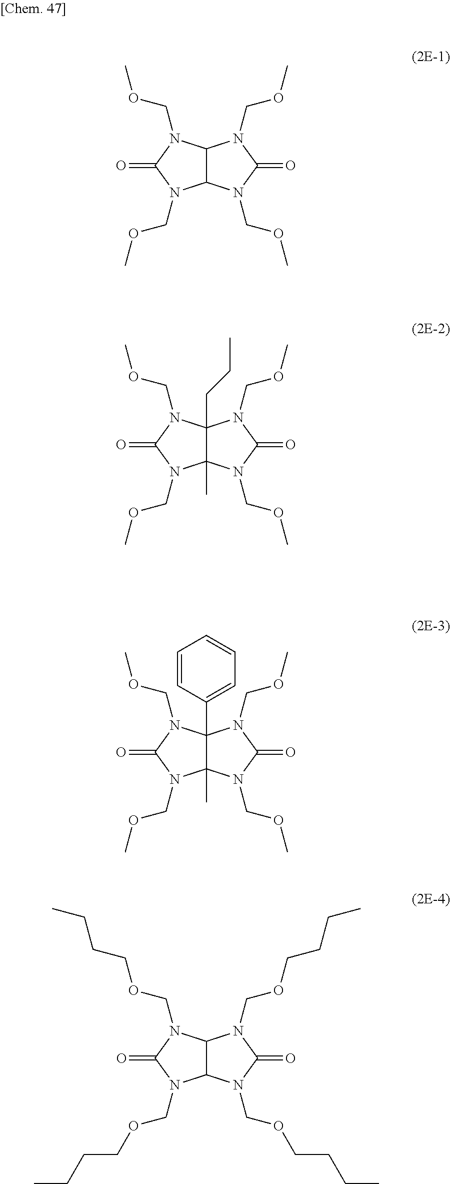 [SMILES: COCN1C(=O)N(COC)C2C1N(COC)C(=O)N2COC ; CCCC12N(COC)C(=O)N(COC)C1(C)N(COC)C(=O)N2COC ; COCN1C(=O)N(COC)C2(c3ccccc3)N(COC)C(=O)N(COC)C12C ; CCCCOCN1C(=O)N(COCCCC)C2C1N(COCCCC)C(=O)N2COCCCC]

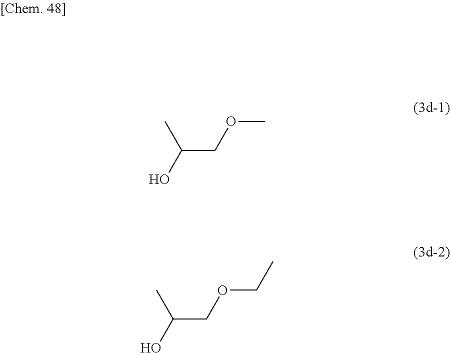

For the contents related to the nitrogen-containing compound having 2 to 6 substituents bonded to a nitrogen atom and represented by the following Formula (1d) per molecule, the entire disclosure of WO 2017/187969 A is incorporated in the present application by reference.

In addition, the crosslinking agent may be a crosslinkable compound represented by the following Formula (G-1) or Formula (G-2) described in WO 2014/208542 A.

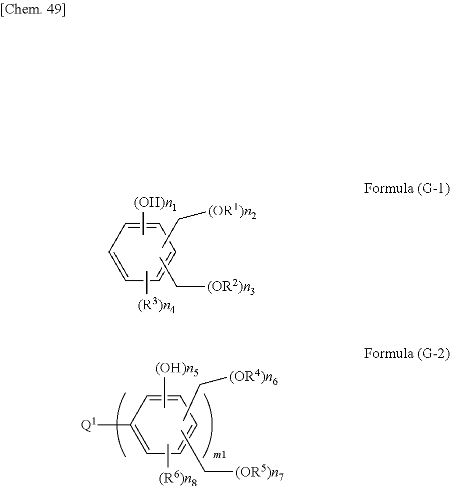

(In the formula, Q¹ represents a single bond or an m1-valent organic group; R and R⁴ each represent an alkyl group having 2 to 10 carbon atoms or an alkyl group having 2 to 10 carbon atoms with an alkoxy group having 1 to 10 carbon atoms; R² and R⁵ each represent a hydrogen atom or a methyl group; and R³ and R⁶ each represent an alkyl group having 1 to 10 carbon atoms or an aryl group having 6 to 40 carbon atoms.
n1 represents an integer that meets 1≤n1≤3; n2 represents an integer that meets 2≤n2≤5; n3 represents an integer that meets 0≤n3≤3; and n4 represents an integer that meets 0≤n4≤3 or an integer that meets 3≤(n1+n2+n3+n4)≤6.
n5 represents an integer that meets 1≤n5≤3: n6 represents an integer that meets 1≤n6≤4; n7 represents an integer that meets 0≤n7≤3; and n8 represents an integer that meets 0≤n8≤3 or an integer that meets 2≤(n5+n6+n7+n8)≤5.
m1 represents an integer of 2 to 10.)

The crosslinkable compound represented by Formula (G-1) or Formula (G-2) may be obtained by a reaction of a compound represented by the following Formula (G-3) or Formula (G-4) with a hydroxyl group-containing ether compound or an alcohol having 2 to 10 carbon atoms.

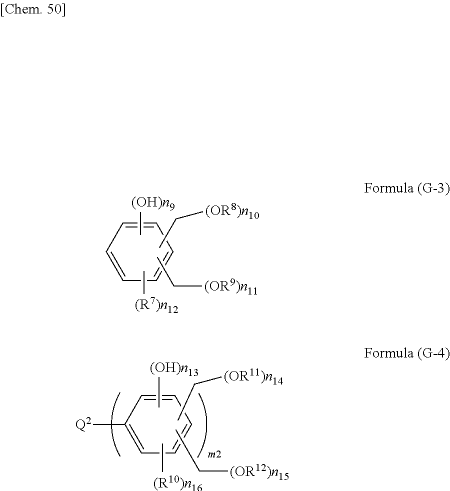

(In the formula, Q² represents a single bond or an m2-valent organic group; R⁸, R⁹, R¹¹, and R¹² each represent a hydrogen atom or a methyl group; and R⁷ and R¹⁰ each represent an alkyl group having 1 to 10 carbon atoms or an aryl group having 6 to 40 carbon atoms.
n9 represents an integer that meets 1≤n9≤3; n10 represents an integer that meets 2≤n10≤5; n11 represents an integer that meets 0≤n11≤3; and n12 represents an integer that meets 0≤n12≤3 or an integer that meets 3≤(n9+n10+n11+n12)≤6.
n13 represents an integer that meets 1≤n13≤3; n14 represents an integer that meets 1≤n14≤4; n15 represents an integer that meets 0≤n15≤3; and n16 represents an integer that meets 0≤n16≤3 or an integer that meets 2≤(n13+n14+n15+n16)≤5.
m2 represents an integer of 2 to 10.)

The compounds represented by Formula (G-1) and Formula (G-2) may be exemplified below.

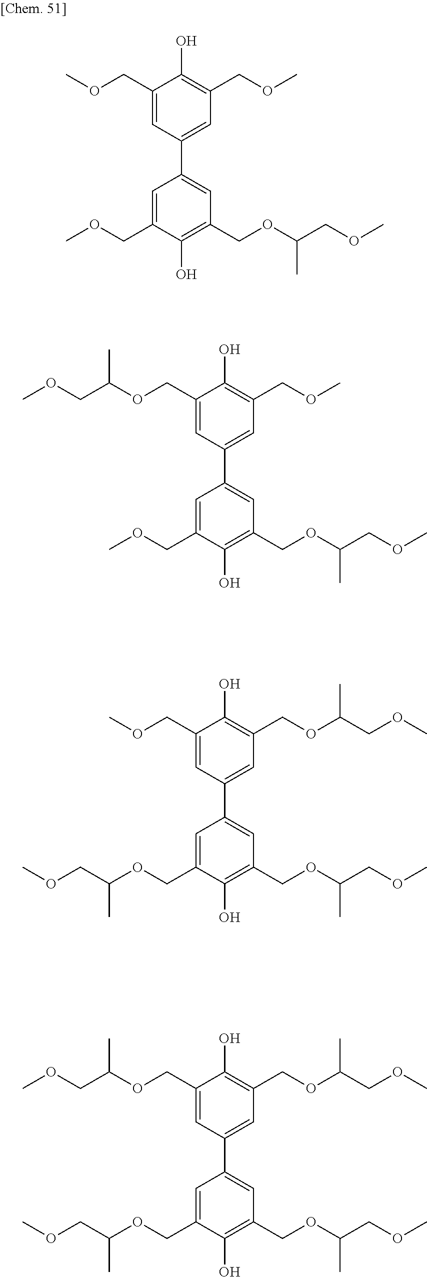

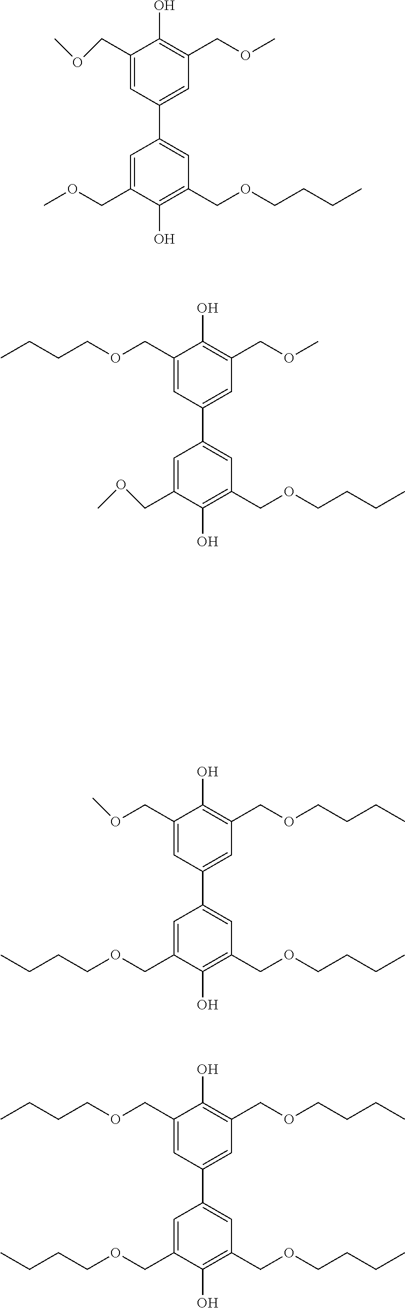

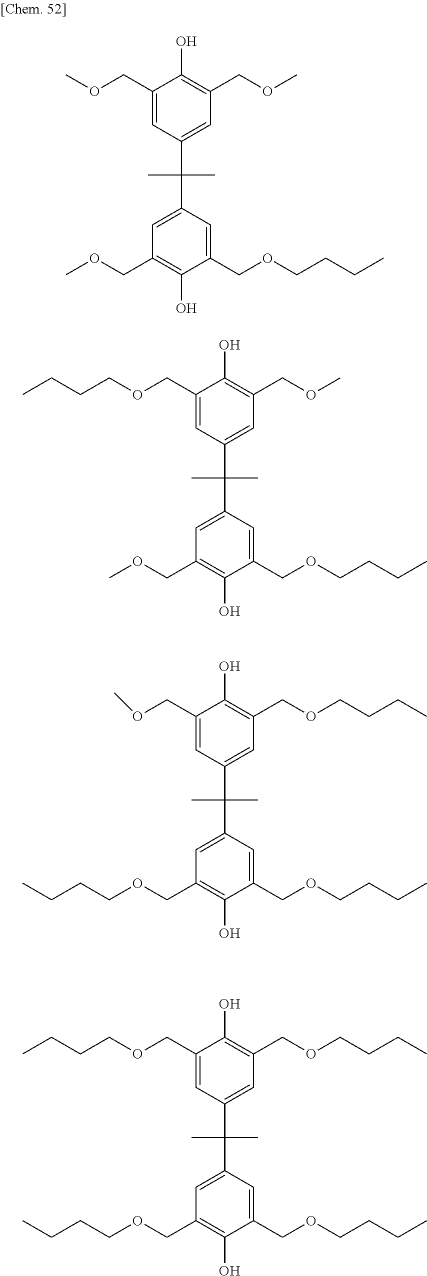

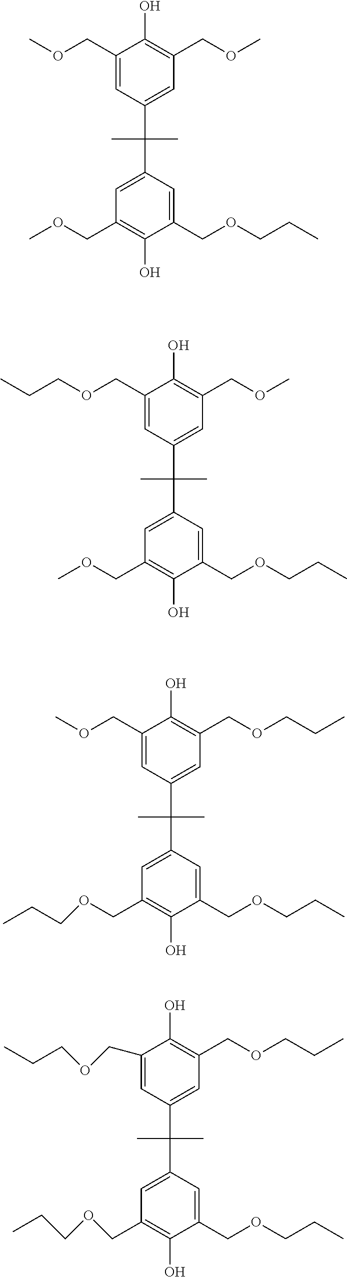

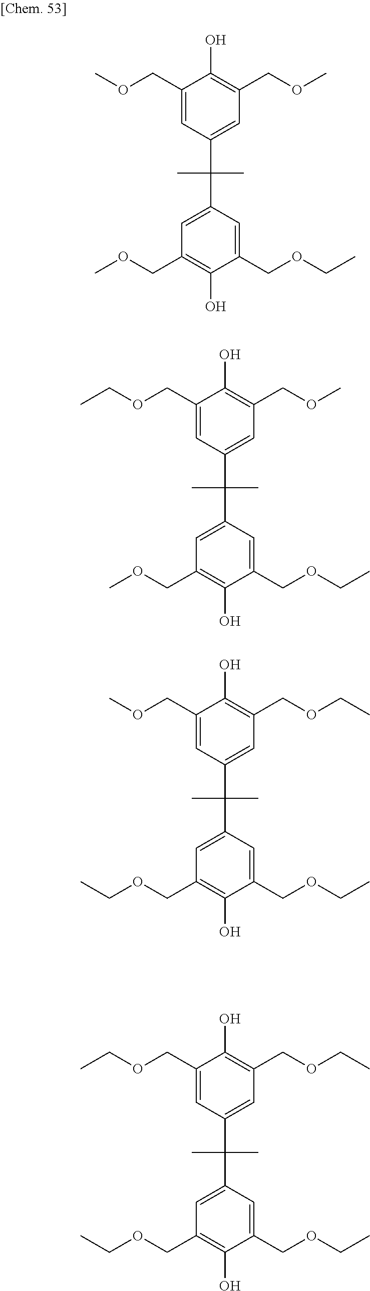

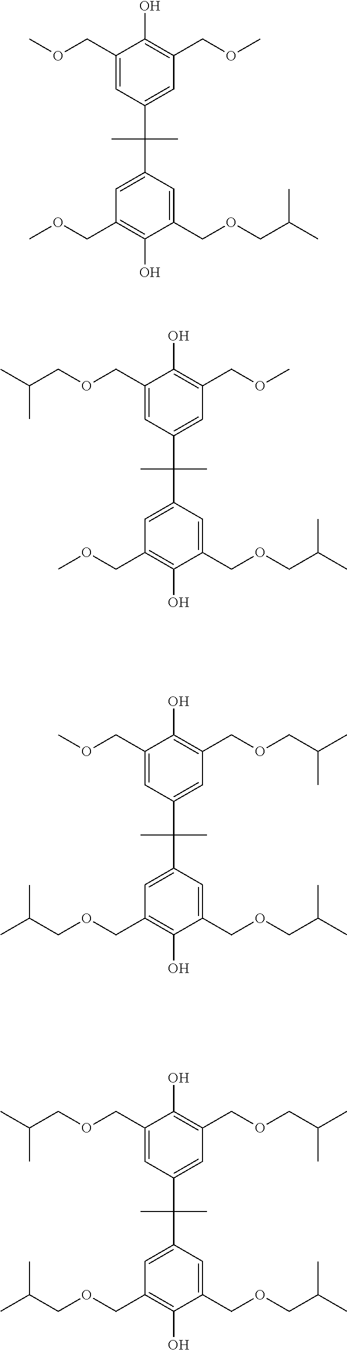

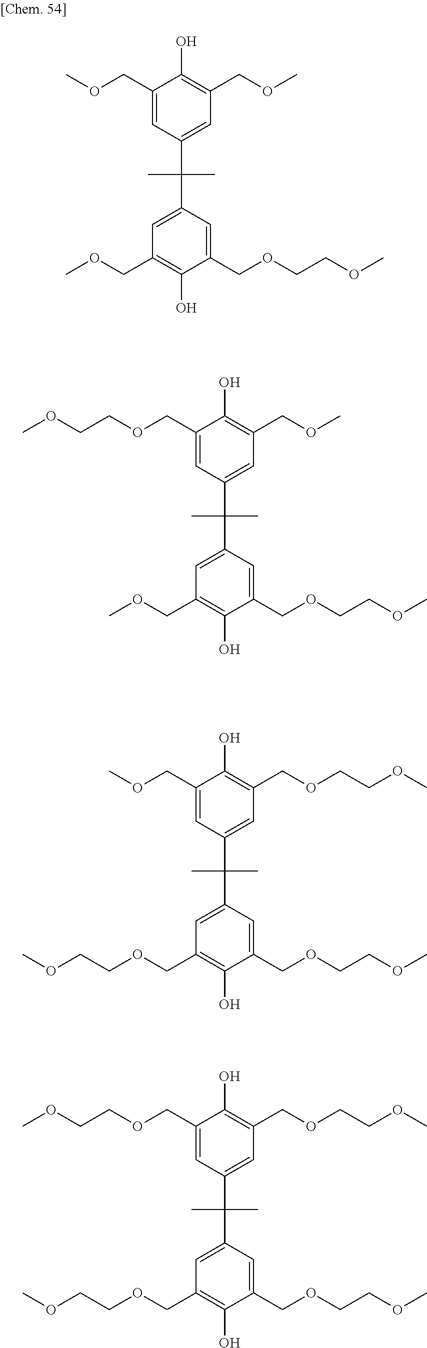

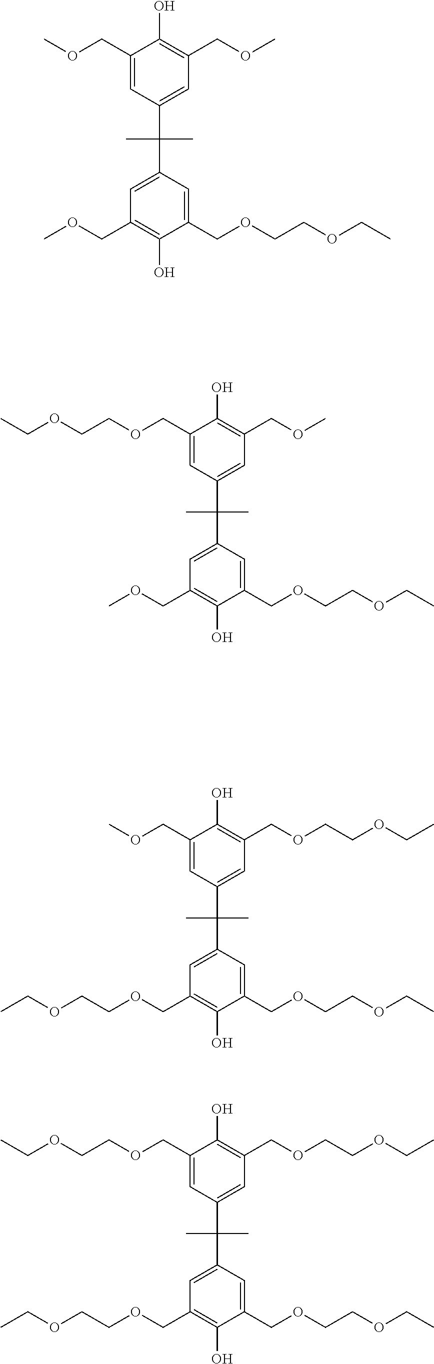

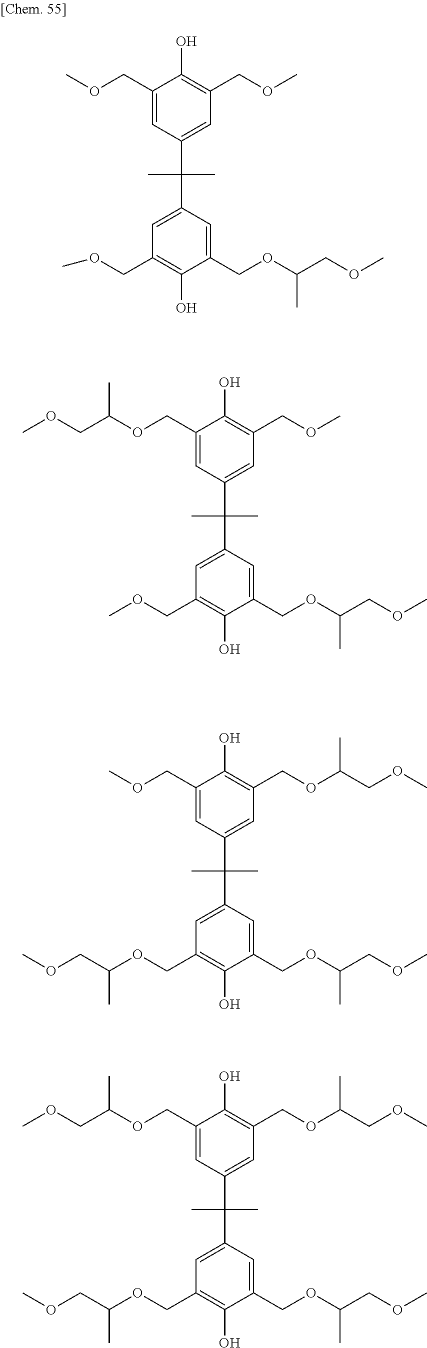

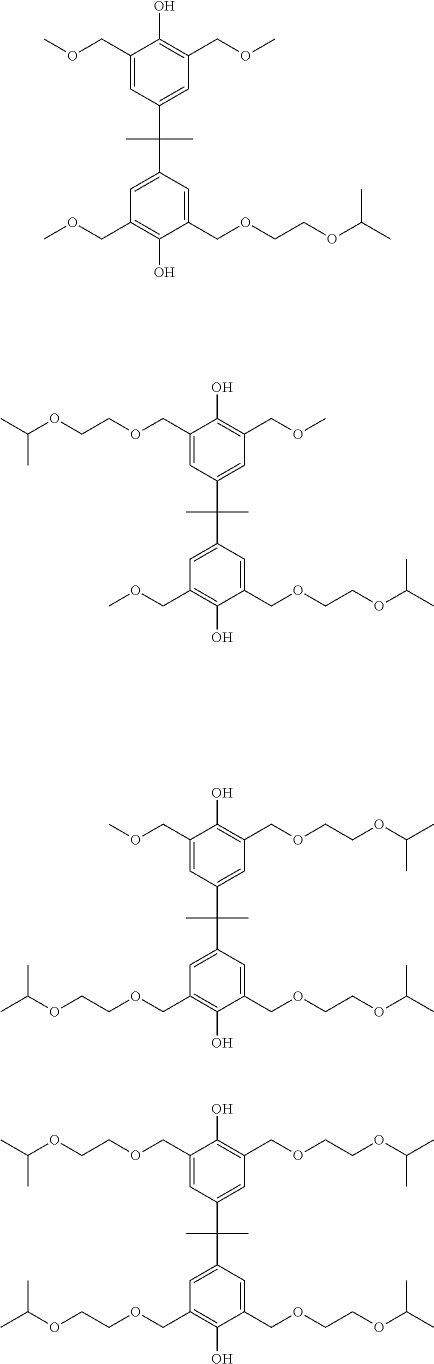

The compounds represented by Formula (G-3) and Formula (G-4) may be exemplified below.

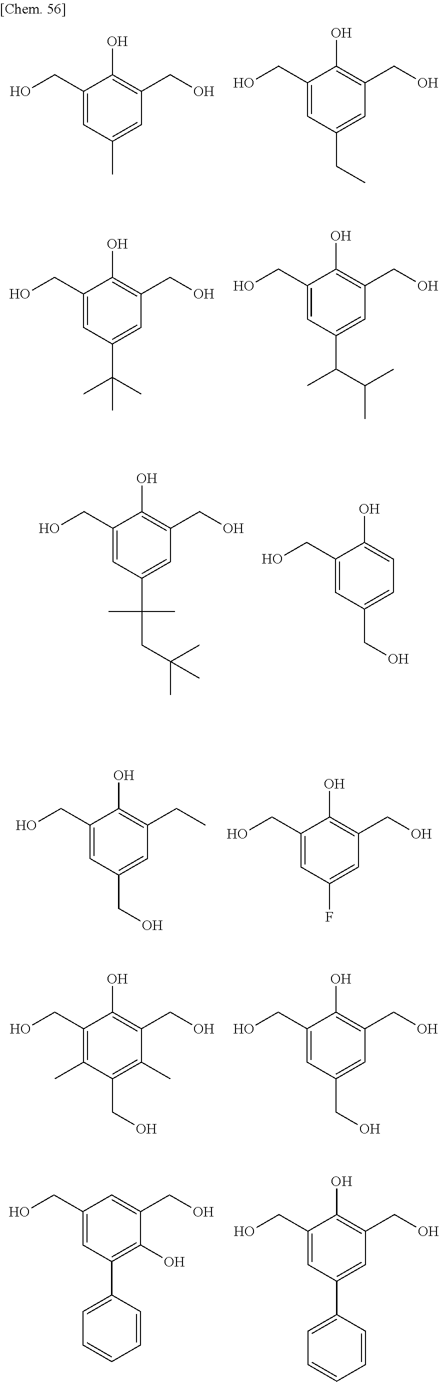

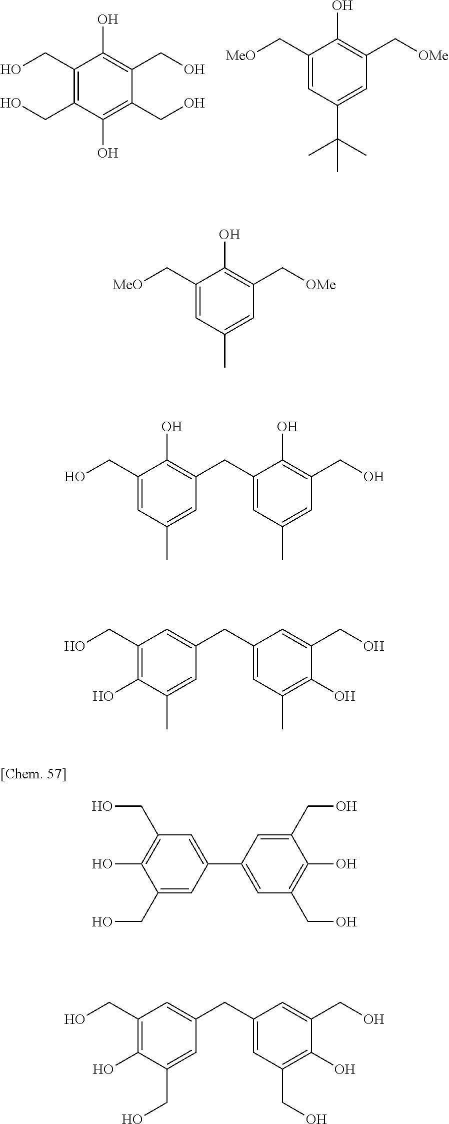

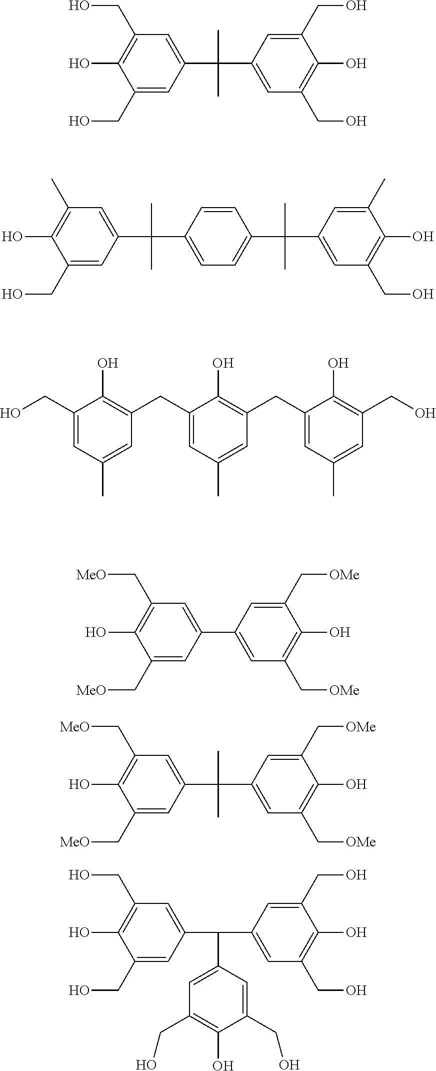

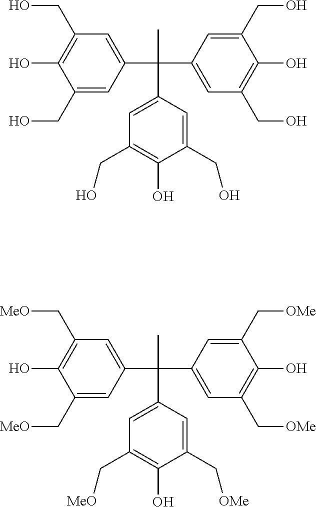

In the formulas, Me represents a methyl group.

The entire disclosure of WO 2014/208542 A is incorporated in the present application by reference.

In a case where a crosslinking agent is used, a content ratio of the crosslinking agent is, for example, within the range of 1% by mass to 50% by mass, and preferably, 5% by mass to 30% by mass, relative to the reaction product.

<Other Components>

In the resist underlayer film-forming composition of the present invention, there is no occurrence of pinholes, striations, or the like; and in order to further improve the applicability for surface unevenness, a surfactant may be further added. Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkylallyl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as EFTOP EF301, EF303, and EF352 (manufactured by Tochem Products Co. Ltd., trade name), Megafac F171, F173, and R-30 (manufactured by Dainippon Ink Co., Ltd., trade name), Fluorad FC430 and FC431 (manufactured by Sumitomo 3M Limited, trade name), and AsahiGuard AG710 and Surflon S-382, SC101, SC102, SC103, SC104, SC105, and SC106 (manufactured by AGC Inc.), and Organosiloxane polymer KP341 (manufactured by Shin-Etsu Chemical Co., Ltd.). A blending amount of these surfactants is usually 2.0% by mass or less, and preferably 1.0% by mass or less, relative to the total solid content of the resist underlayer film-forming composition of the present invention. These surfactants may be added each alone or in combination of two or more thereof.

The solid content contained in the resist underlayer film-forming composition of the present invention, that is, the component excluding the solvent is, for example, 0.01% by mass to 10% by mass.

<Resist Underlayer Film>

The resist underlayer film according to the present invention may be manufactured by applying the resist underlayer film-forming composition described above onto a semiconductor substrate and performing baking.

Examples of the semiconductor substrate on which the resist underlayer film-forming composition of the present invention is applied include a silicon wafer, a germanium wafer, and a semiconductor wafer formed of a compound such as gallium arsenide, indium phosphide, gallium nitride, indium nitride, or aluminum nitride.

In a case where a semiconductor substrate having a surface on which an inorganic film is formed is used, the inorganic film is formed by, for example, an atomic layer deposition (ALD) method, a chemical vapor deposition (CVD) method, a reactive sputtering method, an ion-plating method, a vacuum deposition method, or a spin coating method (spin on glass: SOG). Examples of the inorganic film include a polysilicon film, a silicon oxide film, a silicon nitride film, a Boro-Phospho Silicate Glass (BPSG) film, a titanium nitride film, a titanium nitride oxide film, a tungsten film, a gallium nitride film, and a gallium arsenide film.

The resist underlayer film-forming composition of the present invention is applied onto the semiconductor substrate by an appropriate application method such as a spinner or a coater. Thereafter, baking is performed using a heating means such as a hot plate to form a resist underlayer film. The conditions for baking are appropriately selected from a baking temperature of 100° C. to 400° C. and a baking time of 0.3 minutes to 60 minutes. Preferably, the baking temperature is 120° C. to 350° C. and the baking time is 0.5 minutes to 30 minutes, and more preferably, the baking temperature is 150° C. to 300° C. and the baking time is 0.8 minutes to 10 minutes.

A film thickness of a resist underlayer film to be formed is, for example, within the range of 0.001 μm (1 nm) to 10 m, 0.002 μm (2 nm) to 1 m, 0.005 μm (5 nm) to 0.5 μm (500 nm), 0.001 μm (1 nm) to 0.05 μm (50 nm), 0.002 μm (2 nm) to 0.05 m (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 m (3 nm) to 0.02 μm (20 nm), 0.005 μm (5 nm) to 0.02 μm (20 nm), 0.005 μm (5 nm) to 0.02 μm (20 nm), 0.003 μm (3 nm) to 0.01 μm (10 nm), 0.005 μm (5 nm) to 0.01 m (10 nm), 0.003 μm (3 nm) to 0.006 μm (6 nm), or 0.005 μm (5 nm). In a case where the temperature during baking is lower than the above range, crosslinking becomes insufficient. To the contrary, when the temperature during the baking is higher than the above range, the resist underlayer film may be decomposed by heat.

<Method for Manufacturing Patterned Substrate and Method for Manufacturing Semiconductor Device>

A method for manufacturing a patterned substrate includes the following steps. Usually, a photoresist layer is formed on a resist underlayer film. A photoresist formed by performing application and baking on the resist underlayer film by a method known per se is not particularly limited as long as it is sensitive to the light used for exposure. Either a negative photoresist or a positive photoresist may be used. Examples of the photoresist include a positive photoresist formed of a novolac resin and 1,2-naphthoquinonediazide sulfonic acid ester, a chemically amplified photoresist formed of a binder having a group degradable by an acid to increase an alkali dissolution rate and a photoacid generator, a chemically amplified photoresist formed of a low-molecular-weight compound degradable by an acid to increase an alkali dissolution rate of the photoresist, an alkali-soluble binder, and a photoacid generator, a chemically amplified photoresist formed of a binder having a group degradable by an acid to increase an alkali dissolution rate, a low-molecular-weight compound degradable by an acid to increase an alkali dissolution rate of the photoresist, and a photoacid generator, and a resist containing metal elements. Examples thereof include V146G (trade name) manufactured by JSR Corporation, APEX-E (trade name) manufactured by Shipley Company L.L.C, PAR710 (trade name) manufactured by Sumitomo Chemical Co., Ltd., and AR2772 and SEPR430 (trade name) manufactured by Shin-Etsu Chemical Co., Ltd. In addition, examples thereof include a fluorine-containing atomic polymer-based photoresist as described in Proc. SPIE, Vol. 3999, 330-334 (2000), Proc. SPIE, Vol. 3999, 357-364 (2000), and Proc. SPIE, Vol. 3999, 365-374 (2000).

In addition, the resist compositions described in WO 2019/188595 A, WO 2019/187881 A, WO 2019/187803 A, WO 2019/167737 A, WO 2019/167725 A, WO 2019/187445 A, WO 2019/167419 A, WO 2019/123842 A, WO 2019/054282 A, WO 2019/058945 A, WO 2019/058890 A, WO 2019/039290 A, WO 2019/044259 A, WO 2019/044231 A, WO 2019/026549 A, WO 2018/193954 A, WO 2019/172054 A, WO 2019/021975 A, WO 2018/230334 A, WO 2018/194123 A, JP 2018-180525 A, WO 2018/190088 A, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482 A, JP 2016-29498 A, JP 2011-253185 A, and the like, the so-called resist compositions such as a radiation-sensitive resin composition and a high-resolution patterning composition based on an organometallic solution, and a metal-containing resist composition may be used, but are not limited thereto.

Examples of the resist composition include the following compositions.

An active ray-sensitive or radiation-sensitive resin composition containing: a resin A having a repeating unit having an acid-decomposable group in which a polar group is protected by a protecting group that is removed by an action of an acid; and a compound represented by General Formula (21).

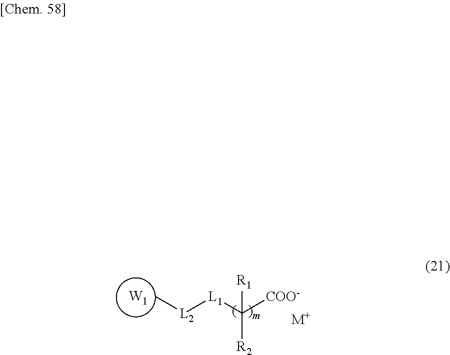

In General Formula (21), m represents an integer of 1 to 6.
R₁ and R₂ each independently represent a fluorine atom or a perfluoroalkyl group.
L₁ represents —O—, —S—, —COO—, —SO₂—, or —SO₃—.
L₂ represents an optionally substituted alkylene group or a single bond.
W₁ represents an optionally substituted cyclic organic group.
M⁺ represents a cation.

A metal-containing film-forming composition for extreme ultraviolet ray or electron beam lithography, containing: a solvent and a compound having a metal-oxygen covalent bond, in which the metal elements constituting the compound belong to the third to seventh periods of Groups 3 to 15 of the periodic table.

A radiation-sensitive resin composition containing: an acid generator and a polymer having a first structural unit represented by the following Formula (31) and a second structural unit having an acid-dissociable group represented by the following Formula (32).

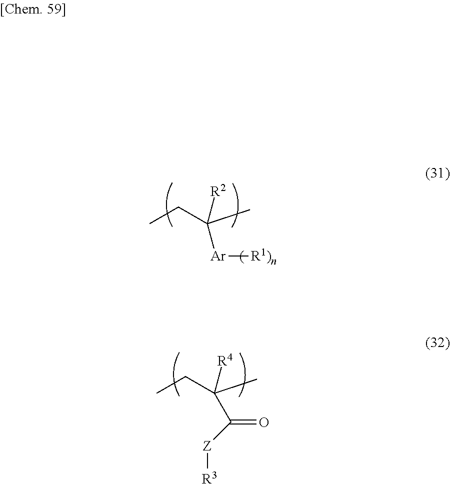

(In Formula (31), Ar is a group resulting from removing (n+1) hydrogen atoms from arene having 6 to 20 carbon atoms. R¹ is a hydroxy group, a sulfanyl group, or a monovalent organic group having 1 to 20 carbon atoms. n is an integer of 0 to 11. When n is 2 or more, a plurality of R¹'s are the same as or different from each other. R² is a hydrogen atom, a fluorine atom, a methyl group, or a trifluoromethyl group. In Formula (32), R³ is a monovalent group having 1 to 20 carbon atoms with the acid-dissociable group. Z is a single bond, an oxygen atom, or a sulfur atom. R⁴ is a hydrogen atom, a fluorine atom, a methyl group, or a trifluoromethyl group.)

A resist composition containing: an acid generator and a resin (A¹) having a structural unit having a cyclic carbonic acid ester structure, a structural unit represented by Formula (II), and a structural unit having an acid-unstable group.

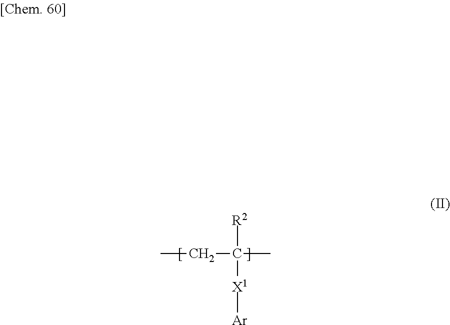

[In Formula (II),
R² represents an alkyl group having 1 to 6 carbon atoms which may have a halogen atom, a hydrogen atom, or a halogen atom; X¹ represents a single bond, —CO—O—*, or —CO—NR⁴—*; * represents a bond with Ar; R⁴ represents a hydrogen atom or an alkyl group having 1 to 4 carbon atoms; and Ar represents an aromatic hydrocarbon group having 6 to 20 carbon atoms which may have one or more groups selected from the group consisting of a hydroxy group and a carboxyl group.]

Examples of the resist film include the following.

A resist film containing a base resin having a repeating unit represented by the following Formula (a1) and/or a repeating unit represented by the following Formula (a2), and a repeating unit that generates an acid, which is bonded to a polymer main chain by exposure.

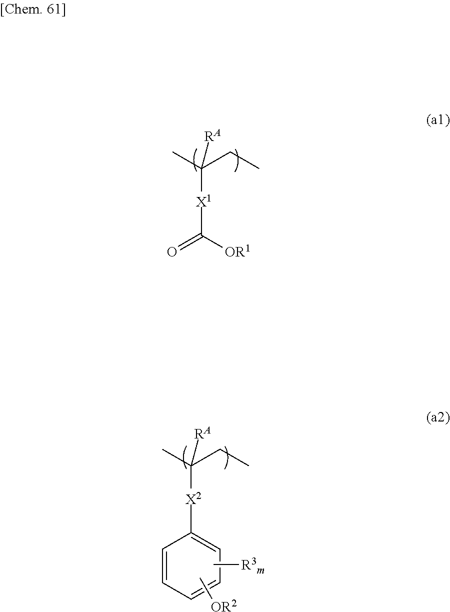

(In Formula (all and Formula (a2). R^{A}'s are each independently a hydrogen atom or a methyl group. R¹ and R² are each independently a tertiary alkyl group having 4 to 6 carbon atoms. R³'s each independently represent a fluorine atom or a methyl group. m is an integer of 0 to 4. X¹ is a single bond, a phenylene group or a naphthylene group, or a linking group having 1 to 12 carbon atoms containing at least one member selected from an ester bond, a lactone ring, a phenylene group, and a naphthylene group. X² is a single bond, an ester bond, or an amide bond.)

Examples of a resist material include the following.

A resist material containing a polymer having a repeating unit represented by the following Formula (b1) or Formula (b2).

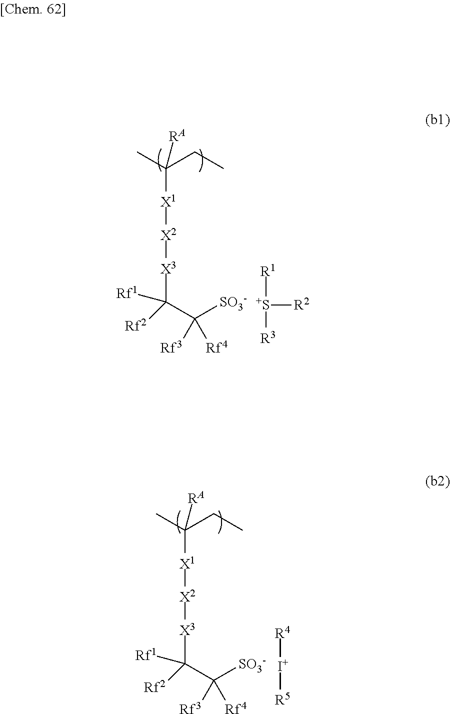

(In Formula (b1) and Formula (b2), R^{A} is a hydrogen atom or a methyl group. X is a single bond or an ester group. X² is a linear, branched, or cyclic alkylene group having 1 to 12 carbon atoms or an arylene group having 6 to 10 carbon atoms, a part of a methylene group constituting the alkylene group may be substituted with an ether group, an ester group, or a lactone ring-containing group, and at least one hydrogen atom contained in X² is substituted with a bromine atom. X³ is a single bond, an ether group, an ester group, or a linear, branched, or cyclic alkylene group having 1 to 12 carbon atoms, and a part of a methylene group constituting the alkylene group may be substituted with an ether group or an ester group. Rf¹ to Rf⁴ are each independently a hydrogen atom, a fluorine atom, or a trifluoromethyl group, and at least one of Rf¹ to Rf⁴ is a fluorine atom or a trifluoromethyl group. In addition, Rf¹ and Rf² may be combined to form a carbonyl group. R¹ to R⁵ each independently represent a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, some or all of the hydrogen atoms in these groups may be substituted with a hydroxy group, a carboxy group, a halogen atom, an oxo group, a cyano group, an amide group, a nitro group, a sultone group, a sulfone group, or a sulfonium salt-containing group, and a part of a methylene group constituting each of these groups may be substituted with an ether group, an ester group, a carbonyl group, a carbonate group, or a sulfonic acid ester group. In addition, R and R² may be bonded to form a ring together with a sulfur atom to which they are bonded.)

A resist material containing a base resin containing a polymer having a repeating unit represented by the following Formula (a).

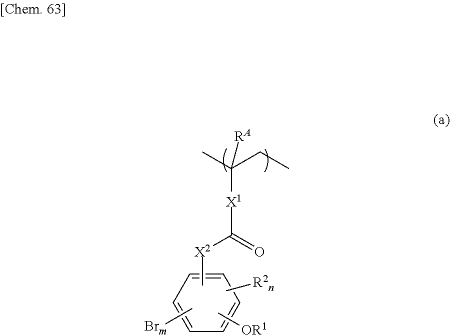

(In Formula (a), R^{A} is a hydrogen atom or a methyl group. R¹ is a hydrogen atom or an acid-unstable group. R² is a linear, branched, or cyclic alkyl group having 1 to 6 carbon atoms or a halogen atom other than bromine. X¹ is a single bond or a phenylene group, or a linear, branched, or cyclic alkylene group having 1 to 12 carbon atoms which may contain an ester group or a lactone ring. X² is —O—, —O—CH₂—, or —NH—. m is an integer of 1 to 4. n is an integer of 0 to 3.)

A resist composition which generates an acid by exposure and has solubility in a developer that is changed by an action of the acid, the resist composition containing:
a base component (A) having solubility to a developer, which is changed by an action of an acid; and a fluorine additive component (F) exhibiting decomposability to an alkaline developer,
in which the fluorine additive component (F) contains a fluororesin component (F1) having a structural unit (f1) containing a base-dissociable group and a structural unit (f2) containing a group represented by the following General Formula (f2-r-1).

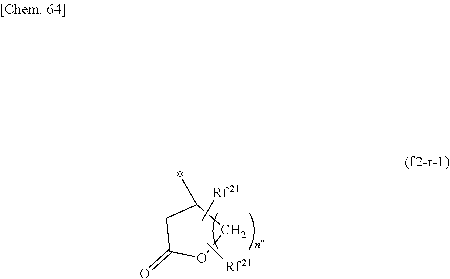

[In Formula (f2-r-1), Rf²¹'s each independently represent a hydrogen atom, an alkyl group, an alkoxy group, a hydroxyl group, a hydroxyalkyl group, or a cyano group. n″ is an integer of 0 to 2. * represents a bond.]

The structural unit (f1) includes a structural unit represented by the following General Formula (f1-1) or a structural unit represented by the following General Formula (f1-2).

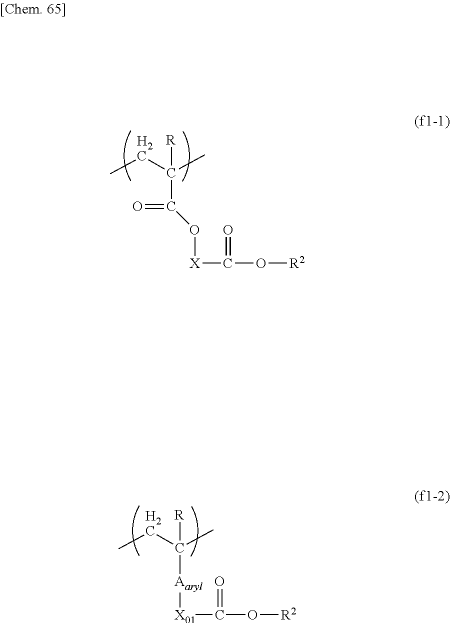

[In Formulas (f1-1) and (f1-2), R's are each independently a hydrogen atom, an alkyl group having 1 to 5 carbon atoms, or a halogenated alkyl group having 1 to 5 carbon atoms. X is a divalent linking group having no acid-dissociable site. A_{aryl} is an optionally substituted, divalent aromatic cyclic group. X₀₁ is a single bond or a divalent linking group. R²'s are each independently an organic group having a fluorine atom.]

Examples of the coating, the coating solution, and the coating composition include the following.

A coating containing a metal oxo-hydroxo network having an organic ligand by a metal carbon bond and/or a metal carboxylate bond.

Inorganic oxo/hydroxo-based composition.

A coating solution containing: an organic solvent; a first organometallic composition represented by Formula R_{z}SnO_{(2-(z/2)-(x2))}(OH)ₓ (where 0<z≤2 and 0<(z+x)≤4), Formula R′ₙSnX₄₋ₙ (where n=1 or 2), or a mixture thereof, where R and R′ are independently a hydrocarbyl group having 1 to 31 carbon atoms, and X is a ligand having a hydrolyzable bond to Sn or a combination thereof; and a hydrolyzable metal compound represented by MX′ᵥ (where M is a metal selected from Groups 2 to 16 of the periodic table of the elements, v=number of 2 to 6, and X′ is a ligand having a hydrolyzable M-X bond or a combination thereof).

A coating solution containing: an organic solvent; and a first organometallic composition represented by Formula RSnO_{(3/2-X/2)}(OH)ₓ (in the formula, 0<x<3), in which about 0.0025 M to about 1.5 M tin is contained in the solution, R is an alkyl group or cycloalkyl group having 3 to 31 carbon atoms, and the alkyl group or cycloalkyl group is bonded to tin at a secondary or tertiary carbon atom.

An inorganic pattern forming precursor aqueous solution containing a mixture of water, a metal suboxide cation, a polyatomic inorganic anion, and a radiation-sensitive ligand containing a peroxide group.

The exposure is performed through a mask (reticle) for forming a predetermined pattern, and for example, an i-line, a KrF energy laser, an ArF energy laser, an extreme ultraviolet ray (EUV), or an electron beam (EB) is used; however, the resist underlayer film-forming composition of the present application is preferably applied for electron beam (EB) or extreme ultraviolet ray (EUV) exposure, and more preferably for extreme ultraviolet ray (EUV) exposure. In the development, an alkaline developer is used, and a development temperature and a development time are appropriately selected from 5° C. to 50° C. and 10 seconds to 300 seconds, respectively. As the alkaline developer, for example, aqueous solutions of alkalis, for example, inorganic alkalis such as sodium hydroxide, potassium hydroxide, sodium carbonate, sodium silicate, sodium metasilicate, and ammonia water, primary amines such as ethylamine and n-propylamine, secondary amines such as diethylamine and di-n-butyl amine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, and cyclic amines such as pyrrole and piperidine, may be used. Furthermore, an appropriate amount of alcohols such as isopropyl alcohol and a surfactant such as a nonionic surfactant may be added to the aqueous solution of alkalis. Of these, a preferred developer is a quaternary ammonium salt and more preferably tetramethylammonium hydroxide and choline. Furthermore, a surfactant or the like may be added to the developer. Instead of the alkaline developer, a method of performing development with an organic solvent such as butyl acetate and developing a portion where an alkali dissolution rate of the photoresist is not increased may also be used. Through the above steps, a substrate on which the resist is patterned can be manufactured.

Next, the resist underlayer film is dry-etched using the formed resist pattern as a mask. At that time, when the inorganic film is formed on the surface of the used semiconductor substrate, the surface of the inorganic film is allowed to be exposed. When the inorganic film is not formed on the surface of the used semiconductor substrate, the surface of the semiconductor substrate is allowed to be exposed.

### EXAMPLES

Next, the present invention will be described in more detail with reference to Examples, but the present invention is not limited thereto.

The weight average molecular weight of the polymers in the following Synthesis Examples and Comparative Synthesis Examples of the present description is the result of the measurement by gel permeation chromatography (hereinafter, abbreviated as GPC). For the measurement, a GPC apparatus manufactured by Tosoh Corporation is used, and the measurement conditions and the like are as follows.
GPC column: TSKgel Super-Multipore HZ-N (two columns)
Column temperature: 40° C.
Solvent: tetrahydrofuran (THF)
Flow rate: 0.35 ml/min
Standard sample: polystyrene (manufactured by Tosoh Corporation)

### Synthesis Example A1

In a reaction vessel, 5.00 g of 1,3,5-tris(2,3-epoxypropyl)isocyanuric acid (trade name: TEPIC-SS, manufactured by Nissan Chemical Industries, Ltd.), 9.60 g of 4-nitrocinnamic acid (manufactured by Tokyo Chemical Industry Co., Ltd.), 0.63 g of tetrabutylphosphonium bromide (manufactured by Hokko Chemical Industry Co., Ltd.), and 0.14 g of hydroquinone (manufactured by Tokyo Chemical Industry Co., Ltd.) were added to 35.85 g of propylene glycol monomethyl ether and dissolved. The inside of the reaction vessel was replaced with nitrogen, and then a reaction was allowed to proceed at 140° C. for 24 hours, thereby obtaining a solution containing a polymer A1 (compound A1). GPC analysis showed that the obtained polymer A1 (compound A1) had a weight average molecular weight of 860 in terms of standard polystyrene, and a dispersity of 1.1. The structure present in the polymer A1 (compound A1) is shown by the following formula.

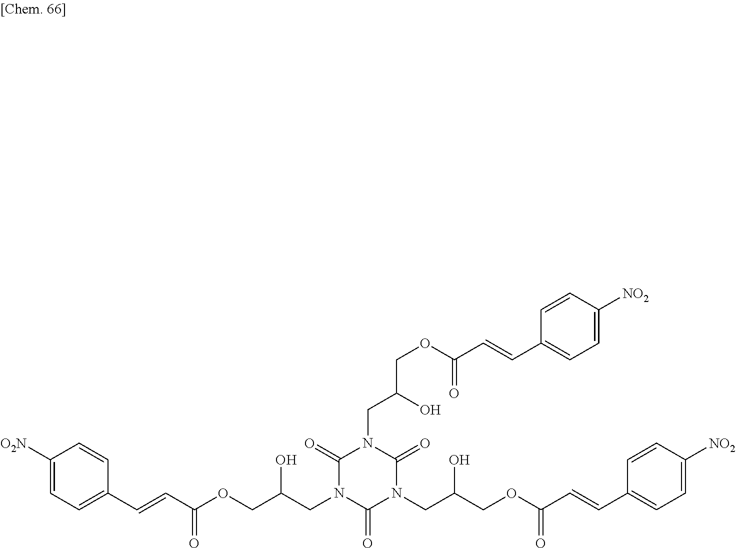 [SMILES: O=C(/C=C/c1ccc([N+](=O)[O-])cc1)OCC(O)Cn1c(=O)n(CC(O)COC(=O)/C=C/c2ccc([N+](=O)[O-])cc2)c(=O)n(CC(O)COC(=O)/C=C/c2ccc([N+](=O)[O-])cc2)c1=O]

### Synthesis Example A2

In a reaction vessel, 8.00 g of 1,3,5-tris(2,3-epoxypropyl)isocyanuric acid (trade name: TEPIC-SS, manufactured by Nissan Chemical Industries, Ltd.), 15.35 g of (E)-3-nitrocinnamic acid (manufactured by Tokyo Chemical Industry Co., Ltd.), and 1.01 g of tetrabutylphosphonium bromide (manufactured by Hokko Chemical Industry Co., Ltd.) were added to 56.85 g of propylene glycol monomethyl ether and dissolved. The inside of the reaction vessel was replaced with nitrogen, and then a reaction was allowed to proceed at 140° C. for 24 hours, thereby obtaining a solution containing a polymer A2 (compound A2). GPC analysis showed that the obtained polymer A2 (compound A2) had a weight average molecular weight of 1,140 in terms of standard polystyrene, and a dispersity of 1.0. The structure present in the polymer A2 (compound A2) is shown by the following formula.

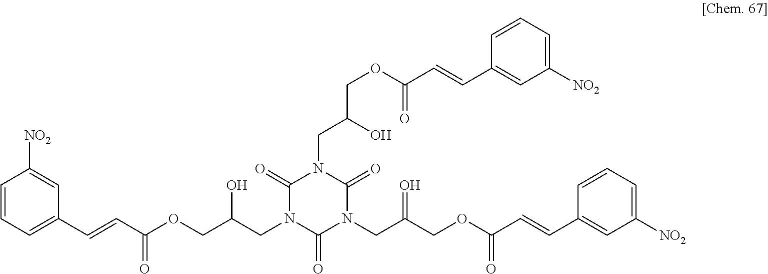 [SMILES: O=C(COC(=O)/C=C/c1cccc([N+](=O)[O-])c1)Cn1c(=O)n(CC(O)COC(=O)/C=C/c2cccc([N+](=O)[O-])c2)c(=O)n(CC(O)COC(=O)/C=C/c2cccc([N+](=O)[O-])c2)c1=O]

### Synthesis Example A3

In a reaction vessel, 6.00 g of monoallyl diglycidyl isocyanurate (manufactured by Shikoku Chemicals Corporation), 4.76 g of 5-nitroisophthalic acid (manufactured by Tokyo Chemical Industry Co., Ltd.), 0.55 g of tetrabutylphosphonium bromide (manufactured by Hokko Chemical Industry Co., Ltd.), and 0.12 g of hydroquinone (manufactured by Tokyo Chemical Industry Co., Ltd.) were added to 45.68 g of propylene glycol monomethyl ether and dissolved. The inside of the reaction vessel was replaced with nitrogen, and then a reaction was allowed to proceed at 140° C. for 24 hours, thereby obtaining a solution containing a polymer A3. GPC analysis showed that the obtained polymer A3 had a weight average molecular weight of 5,400 in terms of standard polystyrene, and a dispersity of 3.4. The structure present in the polymer A3 is shown by the following formula.

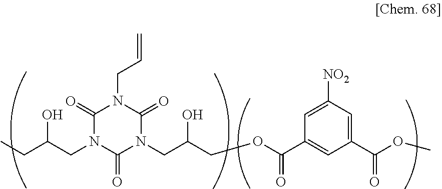

### Synthesis Example A4

In a reaction vessel, 6.00 g of monoallyl diglycidyl isocyanurate (manufactured by Shikoku Chemicals Corporation), 2.99 g of Trans-p-coumaric acid (manufactured by Tokyo Chemical Industry Co., Ltd.), 1.24 g of 4-nitrocinnamic acid (manufactured by Tokyo Chemical Industry Co., Ltd.), 0.55 g of tetrabutylphosphonium bromide (manufactured by Hokko Chemical Industry Co., Ltd.), and 0.12 g of hydroquinone (manufactured by Tokyo Chemical Industry Co., Ltd.) were added to 43.60 g of propylene glycol monomethyl ether and dissolved. The inside of the reaction vessel was replaced with nitrogen, and then a reaction was allowed to proceed at 140° C. for 24 hours, thereby obtaining a solution containing a polymer A4. GPC analysis showed that the obtained polymer A4 had a weight average molecular weight of 2,800 in terms of standard polystyrene, and a dispersity of 3.0. The structure present in the polymer A4 is shown by the following formula.

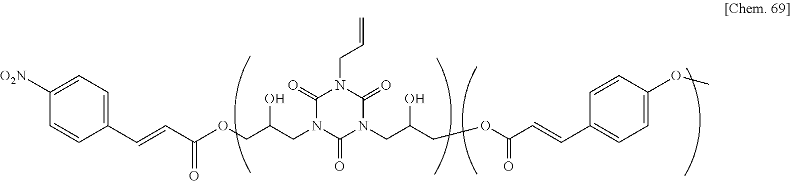

### Synthesis Example A5

In a reaction vessel, 8.00 g of monoallyl diglycidyl isocyanurate (manufactured by Shikoku Chemicals Corporation), 5.13 g of 5-nitroisophthalic acid (manufactured by Tokyo Chemical Industry Co., Ltd.), 1.66 g of 4-nitrocinnamic acid (manufactured by Tokyo Chemical Industry Co., Ltd.), 0.73 g of tetrabutylphosphonium bromide (manufactured by Hokko Chemical Industry Co., Ltd.), and 0.16 g of hydroquinone (manufactured by Tokyo Chemical Industry Co., Ltd.) were added to 62.70 g of propylene glycol monomethyl ether and dissolved. The inside of the reaction vessel was replaced with nitrogen, and then a reaction was allowed to proceed at 140° C. for 24 hours, thereby obtaining a solution containing a polymer A5. GPC analysis showed that the obtained polymer A5 had a weight average molecular weight of 2,900 in terms of standard polystyrene, and a dispersity of 2.4. The structure present in the polymer A5 is shown by the following formula.

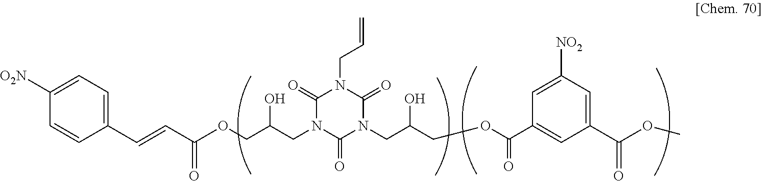

### Synthesis Example A6

In a reaction vessel, 10.00 g of monoallyl diglycidyl isocyanurate (manufactured by Shikoku Chemicals Corporation), 5.75 g of a-cyano-4-hydroxycinnamic acid (manufactured by Midori Kagaku Co., Ltd.), 2.07 g of 4-nitrocinnamic acid (manufactured by Tokyo Chemical Industry Co., Ltd.), 0.91 g of tetrabutylphosphonium bromide (manufactured by Hokko Chemical Industry Co., Ltd.), and 0.20 g of hydroquinone (manufactured by Tokyo Chemical Industry Co., Ltd.) were added to 28.39 g of propylene glycol monomethyl ether and dissolved. The inside of the reaction vessel was replaced with nitrogen, and then a reaction was allowed to proceed at 140° C. for 24 hours, thereby obtaining a solution containing a polymer A6. GPC analysis showed that the obtained polymer A6 had a weight average molecular weight of 2,700 in terms of standard polystyrene, and a dispersity of 2.3. The structure present in the polymer A6 is shown by the following formula.

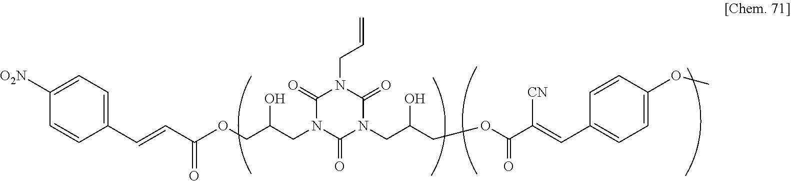

### Synthesis Example A7

In a reaction vessel, 9.00 g of monoallyl diglycidyl isocyanurate (manufactured by Shikoku Chemicals Corporation), 5.77 g of 5-nitroisophthalic acid (manufactured by Tokyo Chemical Industry Co., Ltd.), 1.45 g of terephthalaldehyde acid (manufactured by Tokyo Chemical Industry Co., Ltd.), and 0.82 g of tetrabutylphosphonium bromide (manufactured by Hokko Chemical Industry Co., Ltd.) were added to 39.76 g of propylene glycol monomethyl ether and dissolved. The inside of the reaction vessel was replaced with nitrogen, and then a reaction was allowed to proceed at 105° C. for 24 hours. Subsequently, a solution obtained by dissolving 0.64 g of malononitrile (manufactured by Junsei Chemical Co., Ltd.) in 1.50 g of propylene glycol monomethyl ether was added to the system, and a reaction was allowed to proceed for 4 hours, thereby obtaining a solution containing a polymer A7. GPC analysis showed that the obtained polymer A7 had a weight average molecular weight of 3,900 in terms of standard polystyrene, and a dispersity of 2.5. The structure present in the polymer A7 is shown by the following formula.

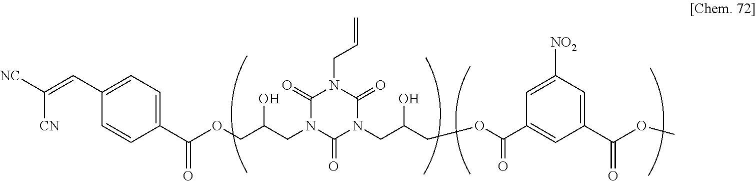

### Synthesis Example A8

In a reaction vessel, 6.00 g of diglycidyl terephthalate (manufactured by Nagase ChemteX Corporation, trade name: EX-711), 4.59 g of 5-nitroisophthalic acid (manufactured by Tokyo Chemical Industry Co., Ltd.), and 0.53 g of tetrabutylphosphonium bromide (manufactured by Hokko Chemical Industry Co., Ltd.) were added to 62.98 g of propylene glycol monomethyl ether and dissolved. The inside of the reaction vessel was replaced with nitrogen, and then a reaction was allowed to proceed at 140° C. for 24 hours, thereby obtaining a solution containing a polymer A8. GPC analysis showed that the obtained polymer A8 had a weight average molecular weight of 5,400 in terms of standard polystyrene, and a dispersity of 3.1. The structure present in the polymer A8 is shown by the following formula.

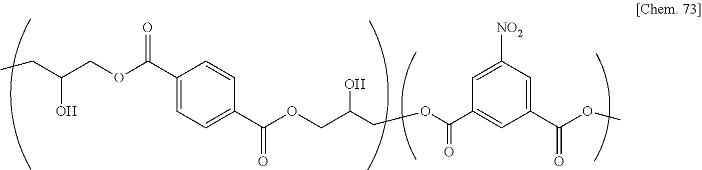

### Synthesis Example A9

In a reaction vessel, 4.00 g of resorcinol diglycidyl ether (manufactured by Nagase ChemteX Corporation, trade name: EX-201), 3.74 g of 5-nitroisophthalic acid (manufactured by Tokyo Chemical Industry Co., Ltd.), and 0.43 g of tetrabutylphosphonium bromide (manufactured by Hokko Chemical Industry Co., Ltd.) were added to 46.27 g of propylene glycol monomethyl ether and dissolved. The inside of the reaction vessel was replaced with nitrogen, and then a reaction was allowed to proceed at 140° C. for 24 hours, thereby obtaining a solution containing a polymer A9. GPC analysis showed that the obtained polymer A9 had a weight average molecular weight of 6,200 in terms of standard polystyrene, and a dispersity of 4.3. The structure present in the polymer A9 is shown by the following formula.

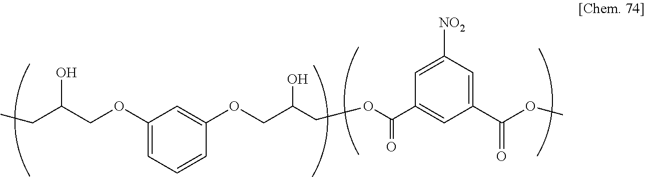

### Synthesis Example A10

In a reaction vessel, 9.00 g of 30% by weight PGME solution of N,N-diglycidyl-5,5-dimethylhydantoin (manufactured by Shikoku Chemicals Corporation), 3.20 g of monoallyl diglycidyl isocyanurate (manufactured by Shikoku Chemicals Corporation), 5.06 g of 5-nitroisophthalic acid (manufactured by Tokyo Chemical Industry Co., Ltd.), and 0.58 g of tetrabutylphosphonium bromide (manufactured by Hokko Chemical Industry Co., Ltd.) were added to 40.00 g of propylene glycol monomethyl ether and dissolved. The inside of the reaction vessel was replaced with nitrogen, and then a reaction was allowed to proceed at 140° C. for 24 hours, thereby obtaining a solution containing a polymer A10. GPC analysis showed that the obtained polymer A10 had a weight average molecular weight of 3,900 in terms of standard polystyrene, and a dispersity of 2.8. The structure present in the polymer A10 is shown by the following formula.

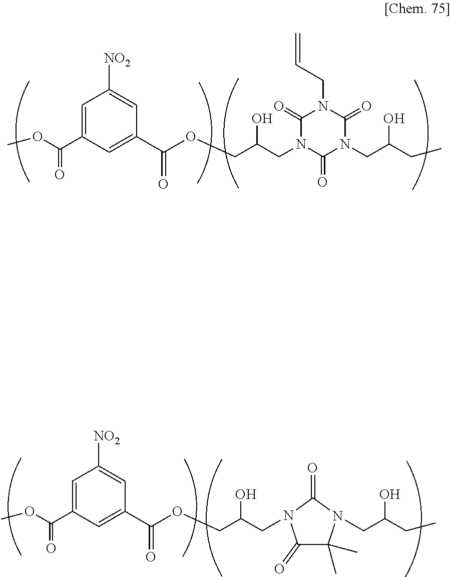

### Synthesis Example A11

In a reaction vessel, 15.00 g of 30% by weight PGME solution of N,N-diglycidyl-5,5-dimethylhydantoin (manufactured by Shikoku Chemicals Corporation), 4.21 g of 5-nitroisophthalic acid (manufactured by Tokyo Chemical Industry Co., Ltd.), and 0.48 g of tetrabutylphosphonium bromide (manufactured by Hokko Chemical Industry Co., Ltd.) were added to 26.48 g of propylene glycol monomethyl ether and dissolved. The inside of the reaction vessel was replaced with nitrogen, and then a reaction was allowed to proceed at 140° C. for 24 hours, thereby obtaining a solution containing a polymer A11. GPC analysis showed that the obtained polymer A11 had a weight average molecular weight of 3,200 in terms of standard polystyrene, and a dispersity of 2.3. The structure present in the polymer A11 is shown by the following formula.

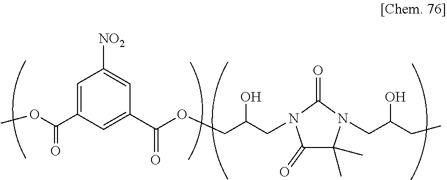

### Synthesis Example A12

In a reaction vessel, 15.00 g of 30% by weight PGME solution of monomethyldiglycidyl isocyanurate (manufactured by Shikoku Chemicals Corporation), 4.90 g of 5-nitroisophthalic acid (manufactured by Tokyo Chemical Industry Co., Ltd.), and 0.46 g of tetrabutylphosphonium bromide (manufactured by Hokko Chemical Industry Co., Ltd.) were added to 28.87 g of propylene glycol monomethyl ether and dissolved. The inside of the reaction vessel was replaced with nitrogen, and then a reaction was allowed to proceed at 140° C. for 24 hours, thereby obtaining a solution containing a polymer A12. GPC analysis showed that the obtained polymer A12 had a weight average molecular weight of 1,600 in terms of standard polystyrene, and a dispersity of 2.3. The structure present in the polymer A12 is shown by the following formula.

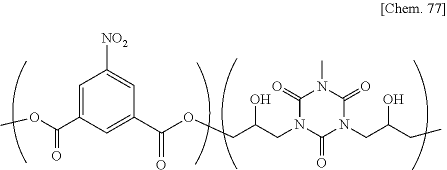

### Synthesis Example A13

In a reaction vessel, 15.00 g of 30% by weight PGME solution of N,N-diglycidyl-5,5-dimethylhydantoin (manufactured by Shikoku Chemicals Corporation), 3.40 g of 5-nitroisophthalic acid (manufactured by Tokyo Chemical Industry Co., Ltd.). 1.03 g of adamantane carboxylic acid (manufactured by Tokyo Chemical Industry Co., Ltd.), and 0.48 g of tetrabutylphosphonium bromide (manufactured by Hokko Chemical Industry Co., Ltd.) were added to 3.73 g of propylene glycol monomethyl ether and dissolved. The inside of the reaction vessel was replaced with nitrogen, and then a reaction was allowed to proceed at 140° C. for 24 hours, thereby obtaining a solution containing a polymer A13. GPC analysis showed that the obtained polymer A13 had a weight average molecular weight of 3,500 in terms of standard polystyrene, and a dispersity of 3.3. The structure present in the polymer A13 is shown by the following formula.

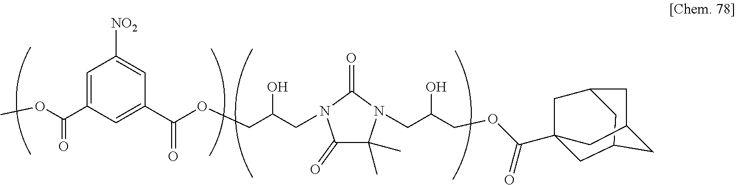

### Synthesis Example A14

In a reaction vessel, 15.00 g of 30% by weight PGME solution of N,N-diglycidyl-5,5-dimethylhydantoin (manufactured by Shikoku Chemicals Corporation), 3.40 g of 5-nitroisophthalic acid (manufactured by Tokyo Chemical Industry Co., Ltd.), 2.22 g of 3,5-diiodosalicylic acid (manufactured by Tokyo Chemical Industry Co., Ltd.), and 0.48 g of tetrabutylphosphonium bromide (manufactured by Hokko Chemical Industry Co., Ltd.) were added to 5.52 g of propylene glycol monomethyl ether and dissolved. The inside of the reaction vessel was replaced with nitrogen, and then a reaction was allowed to proceed at 140° C. for 24 hours, thereby obtaining a solution containing a polymer A13. GPC analysis showed that the obtained polymer A13 had a weight average molecular weight of 2,000 in terms of standard polystyrene, and a dispersity of 2.0. The structure present in the polymer A13 is shown by the following formula.

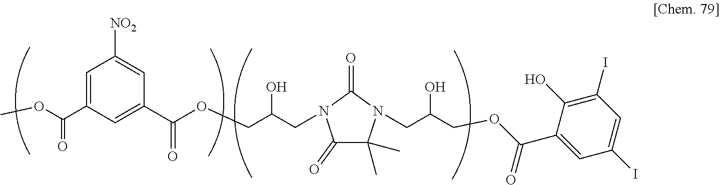

### Synthesis Example A15

In a reaction vessel, 15.00 g of 30% by weight PGME solution of N,N-diglycidyl-5,5-dimethylhydantoin (manufactured by Shikoku Chemicals Corporation), 3.40 g of 5-nitroisophthalic acid (manufactured by Tokyo Chemical Industry Co., Ltd.), 1.10 g of 4-nitrocinnamic acid (manufactured by Tokyo Chemical Industry Co., Ltd.), and 0.48 g of tetrabutylphosphonium bromide (manufactured by Hokko Chemical Industry Co., Ltd.) were added to 27.67 g of propylene glycol monomethyl ether and dissolved. The inside of the reaction vessel was replaced with nitrogen, and then a reaction was allowed to proceed at 140° C. for 24 hours, thereby obtaining a solution containing a polymer A15. GPC analysis showed that the obtained polymer A15 had a weight average molecular weight of 3,100 in terms of standard polystyrene, and a dispersity of 2.4. The structure present in the polymer A15 is shown by the following formula.

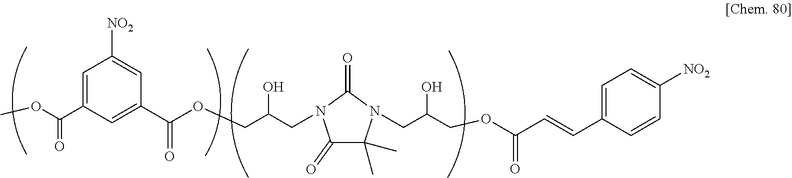

### Synthesis Example A16

In a reaction vessel, 15.00 g of 30% by weight PGME solution of N,N-diglycidyl-5,5-dimethylhydantoin (manufactured by Shikoku Chemicals Corporation), 3.40 g of 5-nitroisophthalic acid (manufactured by Tokyo Chemical Industry Co., Ltd.), 2.64 g of tetrabromophthalic anhydride (manufactured by Tokyo Chemical Industry Co., Ltd.), and 0.48 g of tetrabutylphosphonium bromide (manufactured by Hokko Chemical Industry Co., Ltd.) were added to 6.15 g of propylene glycol monomethyl ether and dissolved. The inside of the reaction vessel was replaced with nitrogen, and then a reaction was allowed to proceed at 140° C. for 24 hours, thereby obtaining a solution containing a polymer A16. GPC analysis showed that the obtained polymer A16 had a weight average molecular weight of 2,300 in terms of standard polystyrene, and a dispersity of 1.9. The structure present in the polymer A16 is shown by the following formula.

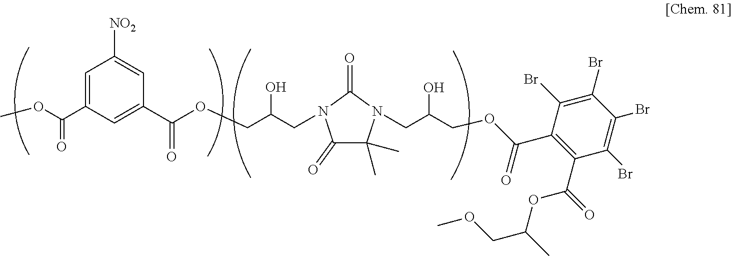

### Synthesis Example A17

In a reaction vessel, 15.00 g of 30% by weight PGME solution of monomethyldiglycidyl isocyanurate (manufactured by Shikoku Chemicals Corporation), 3.21 g of 5-nitroisophthalic acid (manufactured by Tokyo Chemical Industry Co., Ltd.), 0.97 g of adamantane carboxylic acid (manufactured by Tokyo Chemical Industry Co., Ltd.), and 0.46 g of tetrabutylphosphonium bromide (manufactured by Hokko Chemical Industry Co., Ltd.) were added to 25.94 g of propylene glycol monomethyl ether and dissolved. The inside of the reaction vessel was replaced with nitrogen, and then a reaction was allowed to proceed at 140° C. for 24 hours, thereby obtaining a solution containing a polymer A17. GPC analysis showed that the obtained polymer A17 had a weight average molecular weight of 1,300 in terms of standard polystyrene, and a dispersity of 2.3. The structure present in the polymer A17 is shown by the following formula.

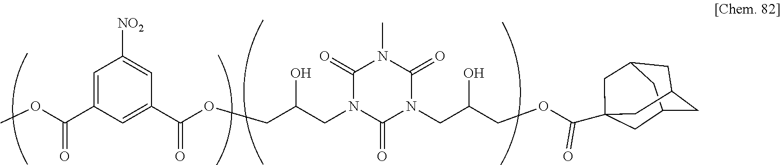

### Synthesis Example A18

In a reaction vessel, 12.00 g of 30% by weight PGME solution of monomethyldiglycidyl isocyanurate (manufactured by Shikoku Chemicals Corporation), 2.41 g of 5-nitroisophthalic acid (manufactured by Tokyo Chemical Industry Co., Ltd.), 2.23 g of 3,5-diiodosalicylic acid (manufactured by Tokyo Chemical Industry Co., Ltd.), and 0.36 g of tetrabutylphosphonium bromide (manufactured by Hokko Chemical Industry Co., Ltd.) were added to 25.97 g of propylene glycol monomethyl ether and dissolved. The inside of the reaction vessel was replaced with nitrogen, and then a reaction was allowed to proceed at 140° C. for 24 hours, thereby obtaining a solution containing a polymer A18. GPC analysis showed that the obtained polymer A18 had a weight average molecular weight of 1,600 in terms of standard polystyrene, and a dispersity of 2.2. The structure present in the polymer A18 is shown by the following formula.

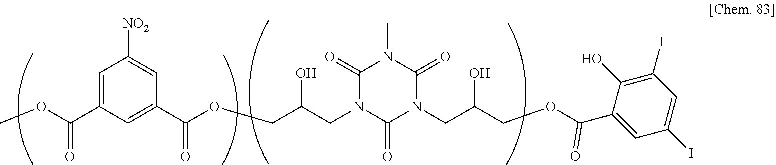

### Synthesis Example A19

In a reaction vessel, 15.00 g of 30% by weight PGME solution of monomethyldiglycidyl isocyanurate (manufactured by Shikoku Chemicals Corporation), 3.21 g of 5-nitroisophthalic acid (manufactured by Tokyo Chemical Industry Co., Ltd.), 2.49 g of tetrabromophthalic anhydride (manufactured by Tokyo Chemical Industry Co., Ltd.), and 0.46 g of tetrabutylphosphonium bromide (manufactured by Hokko Chemical Industry Co., Ltd.) were added to 32.02 g of propylene glycol monomethyl ether and dissolved. The inside of the reaction vessel was replaced with nitrogen, and then a reaction was allowed to proceed at 140° C. for 24 hours, thereby obtaining a solution containing a polymer A19. GPC analysis showed that the obtained polymer A19 had a weight average molecular weight of 2,000 in terms of standard polystyrene, and a dispersity of 2.1. The structure present in the polymer A19 is shown by the following formula.

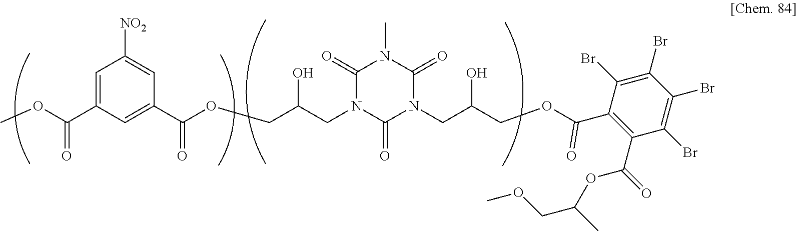

### Comparative Synthesis Example A1

In a reaction vessel, 100.00 g of monoallyl diglycidyl isocyanurate (manufactured by Shikoku Chemicals Corporation), 66.4 g of 5,5-diethylbarbituric acid, and 4.1 g of benzyltriethylammonium chloride were added to 682.00 g of propylene glycol monomethyl ether and dissolved. The inside of the reaction vessel was replaced with nitrogen, and then a reaction was allowed to proceed at 130° C. for 24 hours, thereby obtaining a solution containing a comparative polymer A1. GPC analysis showed that the obtained comparative polymer A1 had a weight average molecular weight of 6,800 in terms of standard polystyrene, and a dispersity of 4.8. The structure present in the comparative polymer A1 is shown by the following formula.

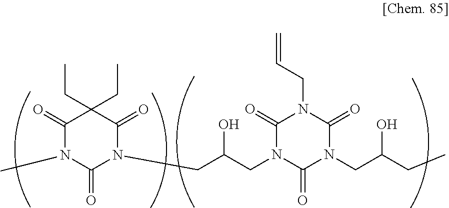

### Comparative Synthesis Example A2

In a reaction vessel, 6.00 g of monoallyl diglycidyl isocyanurate (manufactured by Shikoku Chemicals Corporation), 3.74 g of isophthalic acid (manufactured by Tokyo Chemical Industry Co., Ltd.), 0.55 g of tetrabutylphosphonium bromide (manufactured by Hokko Chemical Industry Co., Ltd.), and 0.12 g of hydroquinone (manufactured by Tokyo Chemical Industry Co., Ltd.) were added to 41.62 g of propylene glycol monomethyl ether and dissolved. The inside of the reaction vessel was replaced with nitrogen, and then a reaction was allowed to proceed at 140° C. for 24 hours, thereby obtaining a solution containing a comparative polymer A2. GPC analysis showed that the obtained comparative polymer A2 had a weight average molecular weight of 7,600 in terms of standard polystyrene, and a dispersity of 5.6. The structure present in the comparative polymer A2 is shown by the following formula.

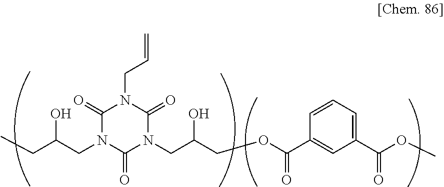

### Comparative Synthesis Example A3

In a reaction vessel, 6.00 g of monoallyl diglycidyl isocyanurate (manufactured by Shikoku Chemicals Corporation), 4.10 g of isophthalic acid (manufactured by Tokyo Chemical Industry Co., Ltd.), 0.55 g of tetrabutylphosphonium bromide (manufactured by Hokko Chemical Industry Co., Ltd.), and 0.12 g of hydroquinone (manufactured by Tokyo Chemical Industry Co., Ltd.) were added to 43.06 g of propylene glycol monomethyl ether and dissolved. The inside of the reaction vessel was replaced with nitrogen, and then a reaction was allowed to proceed at 140° C. for 24 hours, thereby obtaining a solution containing a comparative polymer A3. GPC analysis showed that the obtained comparative polymer A3 had a weight average molecular weight of 7,400 in terms of standard polystyrene, and a dispersity of 4.8. The structure present in the comparative polymer A3 is shown by the following formula.

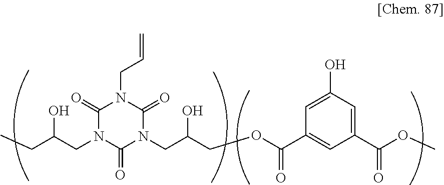

### Comparative Synthesis Example A4

In a reaction vessel, 5.00 g of monoallyl diglycidyl isocyanurate (manufactured by Shikoku Chemicals Corporation), 3.68 g of 5-methoxyisophthalic acid (manufactured by Tokyo Chemical Industry Co., Ltd.), 0.46 g of tetrabutylphosphonium bromide (manufactured by Hokko Chemical Industry Co., Ltd.), and 0.10 g of hydroquinone (manufactured by Tokyo Chemical Industry Co., Ltd.) were added to 36.94 g of propylene glycol monomethyl ether and dissolved. The inside of the reaction vessel was replaced with nitrogen, and then a reaction was allowed to proceed at 140° C. for 24 hours, thereby obtaining a solution containing a comparative polymer A4. GPC analysis showed that the obtained comparative polymer A4 had a weight average molecular weight of 7,300 in terms of standard polystyrene, and a dispersity of 5.2. The structure present in the comparative polymer A4 is shown by the following formula.

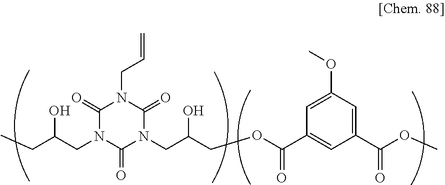

(Preparation of Resist Underlayer Film)

(Examples and Comparative Examples)

Each of the polymers (compounds) obtained in Synthesis Examples A1 to A19 and Comparative Synthesis Examples A1 to A4, a crosslinking agent, a curing catalyst (acid generator), and a solvent were mixed at proportions as shown in Tables A1 and A2, and the mixtures were filtered through a fluororesin filter having a pore size of 0.1 m, thereby preparing solutions of each of the resist underlayer film-forming compositions.

In Tables A1 and A2, tetramethoxymethyl glycoluril was abbreviated as PL-LI; imidazo[4,5-d]imidazole-2,5(1H,3H)-dione,tetrahydro-1,3,4,6-tetrakis[(2-methoxy-1-methylethoxy)methyl]- was abbreviated as PGME-PL; pyridinium p-hydroxybenzenesulfonic acid was abbreviated as PyPSA; a surfactant was abbreviated as R-30N; propylene glycol monomethyl ether acetate was abbreviated as PGMEA; and propylene glycol monomethyl ether was abbreviated as PGME. The amount of each of the components incorporated was shown in part(s) by mass.

TABLE 1
A1

| | | Crosslinking | Curing | | | |
|---|---|---|---|---|---|---|
| | Polymer | agent | catalyst | Surfactant | Solvent | |
| Example A1 | Synthesis | PL-LI | PyPSA | R-30N | PGME | PGMEA |
| | Example A1 | | | | | |
| (parts by mass) | 0.125 | 0.044 | 0.003 | — | 90 | 10 |
| Example A2 | Synthesis | PL-LI | PyPSA | R-30N | PGME | PGMEA |
| | Example A2 | | | | | |
| (parts by mass) | 0.125 | 0.044 | 0.003 | — | 90 | 10 |
| Example A3 | Synthesis | PGME-PL | PyPSA | R-30N | PGME | PGMEA |
| | Example A3 | | | | | |
| (parts by mass) | 0.146 | 0.040 | 0.004 | 0.001 | 90 | 10 |
| Example A4 | Synthesis | PL-LI | PyPSA | R-30N | PGME | PGMEA |
| | Example A4 | | | | | |
| (parts by mass) | 0.135 | 0.034 | 0.003 | — | 90 | 10 |
| Example A5 | Synthesis | PGME-PL | PyPSA | R-30N | PGME | PGMEA |
| | Example A5 | | | | | |
| (parts by mass) | 0.146 | 0.040 | 0.004 | — | 90 | 10 |
| Example A6 | Synthesis | PGME-PL | PyPSA | R-30N | PGME | PGMEA |
| | Example A6 | | | | | |
| (parts by mass) | 0.146 | 0.040 | 0.004 | — | 90 | 10 |
| Example A7 | Synthesis | PGME-PL | PyPSA | R-30N | PGME | PGMEA |
| | Example A7 | | | | | |
| (parts by mass) | 0.146 | 0.040 | 0.004 | — | 90 | 10 |
| Example A8 | Synthesis | PGME-PL | PyPSA | R-30N | PGME | PGMEA |
| | Example A8 | | | | | |
| (parts by mass) | 0.146 | 0.040 | 0.004 | — | 90 | 10 |
| Example A9 | Synthesis | PGME-PL | PyPSA | R-30N | PGME | PGMEA |
| | Example A9 | | | | | |
| (parts by mass) | 0.146 | 0.040 | 0.004 | — | 90 | 10 |
| Example A10 | Synthesis | PGME-PL | PyPSA | R-30N | PGME | PGMEA |
| | Example A10 | | | | | |
| (parts by mass) | 0.146 | 0.040 | 0.004 | — | 90 | 10 |
| Example A11 | Synthesis | PGME-PL | PyPSA | R-30N | PGME | PGMEA |
| | Example A11 | | | | | |
| (parts by mass) | 0.146 | 0.040 | 0.004 | — | 90 | 10 |
| Example A12 | Synthesis | PGME-PL | PyPSA | R-30N | PGME | PGMEA |
| | Example A12 | | | | | |
| (parts by mass) | 0.146 | 0.040 | 0.004 | — | 90 | 10 |
| Example A13 | Synthesis | PGME-PL | PyPSA | R-30N | PGME | PGMEA |
| | Example A13 | | | | | |
| (parts by mass) | 0.146 | 0.040 | 0.004 | — | 90 | 10 |
| Example A14 | Synthesis | PGME-PL | PyPSA | R-30N | PGME | PGMEA |
| | Example A14 | | | | | |
| (parts by mass) | 0.146 | 0.040 | 0.004 | — | 90 | 10 |
| Example A15 | Synthesis | PGME-PL | PyPSA | R-30N | PGME | PGMEA |
| | Example A15 | | | | | |
| (parts by mass) | 0.146 | 0.040 | 0.004 | — | 90 | 10 |
| Example A16 | Synthesis | PGME-PL | PyPSA | R-30N | PGME | PGMEA |
| | Example A16 | | | | | |
| (parts by mass) | 0.146 | 0.040 | 0.004 | — | 90 | 10 |
| Example A17 | Synthesis | PGME-PL | PyPSA | R-30N | PGME | PGMEA |
| | Example A17 | | | | | |
| (parts by mass) | 0.146 | 0.040 | 0.004 | — | 90 | 10 |
| Example A18 | Synthesis | PGME-PL | PyPSA | R-30N | PGME | PGMEA |
| | Example A18 | | | | | |
| (parts by mass) | 0.146 | 0.040 | 0.004 | — | 90 | 10 |
| Example A19 | Synthesis | PGME-PL | PyPSA | R-30N | PGME | PGMEA |
| | Example A19 | | | | | |
| (parts by mass) | 0.146 | 0.040 | 0.004 | — | 90 | 10 |

TABLE 2
A2

| | | Crosslinking | Curing | | | |
|---|---|---|---|---|---|---|
| | Polymer | agent | catalyst | Surfactant | Solvent | |
| Comparative | Comparative | PL-LI | PyPSA | R-30N | PGME | PGMEA |
| Example A1 | Synthesis | | | | | |
| | Example A1 | | | | | |
| (parts by mass) | 0.149 | 0.037 | 0.003 | 0.001 | 70 | 30 |
| Comparative | Comparative | PGME-PL | PyPSA | R-30N | PGME | PGMEA |
| Example A2 | Synthesis | | | | | |
| | Example A2 | | | | | |
| (parts by mass) | 0.146 | 0.040 | 0.004 | 0.001 | 90 | 10 |
| Comparative | Comparative | PGME-PL | PyPSA | R-30N | PGME | PGMEA |
| Example A3 | Synthesis | | | | | |
| | Example A3 | | | | | |
| (parts by mass) | 0.146 | 0.040 | 0.004 | 0.001 | 90 | 10 |
| Comparative | Comparative | PGME-PL | PyPSA | R-30N | PGME | PGMEA |
| Example A4 | Synthesis | | | | | |
| | Example A4 | | | | | |
| (parts by mass) | 0.146 | 0.040 | 0.004 | 0.001 | 90 | 10 |

(Test for Elution into Photoresist Solvent)

Each of the resist underlayer film-forming compositions of Examples A1 to A19 and Comparative Examples A1 to A4 was applied onto a silicon wafer using a spinner. The silicon wafer was baked on a hot plate at 205° C. for 60 seconds to obtain a film having a film thickness of 5 nm. These resist underlayer films were immersed in a mixed solution of propylene glycol monomethyl ether/propylene glycol monomethyl ether=70/30, which was a solvent used for the photoresist. The film that provided a film thickness change of less than 5 Å was evaluated as good, and the film that provided a film thickness change of 5 Å or more was evaluated as poor. The results thereof are shown in Table A3.

TABLE 3
A3

| | Elution test |
|---|---|
| Example A1 | Good |
| Example A2 | Good |
| Example A3 | Good |
| Example A4 | Good |
| Example A5 | Good |
| Example A6 | Good |
| Example A7 | Good |
| Example A8 | Good |
| Example A9 | Good |
| Example A10 | Good |
| Example A11 | Good |
| Example A12 | Good |
| Example A13 | Good |
| Example A14 | Good |
| Example A15 | Good |
| Example A16 | Good |
| Example A17 | Good |
| Example A18 | Good |
| Example A19 | Good |
| Comparative Example A1 | Good |
| Comparative Example A2 | Good |
| Comparative Example A3 | Good |
| Comparative Example A4 | Good |

(Evaluation of Resist Patterning)

[Test for Forming Resist Pattern by Electron Beam Drawing Apparatus]

Each of the resist underlayer film-forming compositions was applied onto a silicon wafer using a spinner. The silicon wafer was baked on a hot plate at 205° C. for 60 seconds to obtain a resist underlayer film having a thickness of 5 nm. A positive resist solution for EUV was spin-coated on the resist underlayer film, and heating was performed at 130° C. for 60 seconds, thereby forming an EUV resist film. The resist film was exposed under the predetermined conditions using an electron beam drawing apparatus (ELS-G130). After the exposure, the film was baked (PEB) at 90° C. for 60 seconds, the baked film was cooled on a cooling plate to room temperature. The cooled film was subjected to paddle development for 30 seconds using a 2.38% tetramethylammonium hydroxide aqueous solution (manufactured by TOKYO OHKA KOGYO CO., LTD., trade name: NMD-3) as a photoresist developer. A resist pattern having a line size of 16 nm to 28 nm was formed. A scanning electron microscope (manufactured by Hitachi High-Technologies Corporation, CG4100) was used for measuring a length of the resist pattern.

The photoresist pattern thus obtained was evaluated for determining whether or not a 22 nm line-and-space (L/S) was formed. The formation of the 22 nm L/S pattern was confirmed in all cases of Examples A1 to A19. In Comparative Example A3, the 22 nm L/S pattern formation was not confirmed. In addition, the amount of charge for forming the 22 nm line/44 nm pitch (line-and-space (L/S=1/1)) was defined as the optimal irradiation energy, and the irradiation energy (μC/cm²) at that time, together with the minimum CD size and LWR at which no collapse was observed in the shot of the resist pattern are shown in Table A4. In Examples A1 to A19, it was confirmed that the LWR and the minimum CD size were improved as compared with Comparative Examples A1 to A4.

TABLE 4
A4

| | Irradiation | Minimum | |
|---|---|---|---|
| | energy | CD size | LWR |
| | (uC/cm²) | (nm) | (nm) |
| Example A1 | 495 | <17.6 | 3.33 |
| Example A2 | 479 | <16.9 | 3.13 |
| Example A3 | 477 | 17.1 | 3.31 |
| Example A4 | 476 | 17.5 | 3.07 |
| Example A5 | 475 | 16.8 | 3.53 |
| Example A6 | 450 | 18.0 | 3.61 |
| Example A7 | 456 | 16.1 | 3.65 |
| Example A8 | 462 | 16.2 | 3.44 |
| Example A9 | 464 | 16.4 | 3.44 |
| Example A10 | 442 | 16.1 | 3.87 |
| Example A11 | 474 | 16.2 | 3.39 |
| Example A12 | 465 | 16.0 | 3.50 |
| Example A13 | 488 | <16.2 | 3.33 |
| Example A14 | 470 | 15.7 | 3.35 |
| Example A15 | 462 | 16.2 | 3.39 |
| Example A16 | 450 | 16.4 | 3.85 |
| Example A17 | 465 | 17.0 | 3.45 |
| Example A18 | 472 | 16.3 | 3.45 |
| Example A19 | 477 | 16.4 | 3.43 |
| Comparative Example A1 | 433 | 18.5 | 3.54 |
| Comparative Example A2 | 454 | 18.3 | 3.56 |
| Comparative Example A3 | Pattern was not obtained | | |
| Comparative Example A4 | 437 | 18.3 | 3.65 |

### Synthesis Example B1

In a reaction vessel, 6.00 g of monoallyl diglycidyl isocyanurate (manufactured by Shikoku Chemicals Corporation), 2.99 g of Trans-p-coumaric acid (manufactured by Tokyo Chemical Industry Co., Ltd.), 0.95 g of Trans-cinnamic acid (manufactured by Tokyo Chemical Industry Co., Ltd.), 0.55 g of tetrabutylphosphonium bromide (manufactured by Hokko Chemical Industry Co., Ltd.), and 0.12 g of hydroquinone (manufactured by Tokyo Chemical Industry Co., Ltd.) were added to 42.44 g of propylene glycol monomethyl ether and dissolved. The inside of the reaction vessel was replaced with nitrogen, and then a reaction was allowed to proceed at 140° C. for 24 hours, thereby obtaining a solution containing a polymer B1. GPC analysis showed that the obtained polymer B1 had a weight average molecular weight of 2,900 in terms of standard polystyrene, and a dispersity of 2.3. The structure present in the polymer B1 is shown by the following formula.

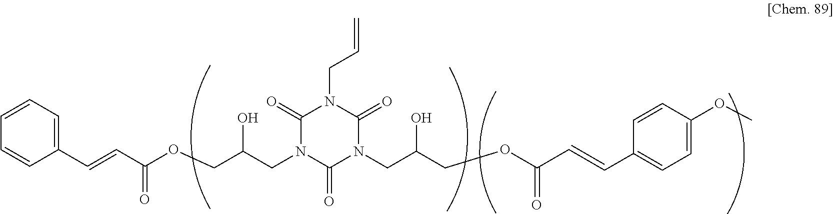

### Synthesis Example B2

In a reaction vessel, 6.00 g of monoallyl diglycidyl isocyanurate (manufactured by Shikoku Chemicals Corporation), 2.99 g of Trans-p-coumaric acid (manufactured by Tokyo Chemical Industry Co., Ltd.), 1.04 g of 4-methylcinnamic acid (manufactured by Tokyo Chemical Industry Co., Ltd.), 0.55 g of tetrabutylphosphonium bromide (manufactured by Hokko Chemical Industry Co., Ltd.), and 0.12 g of hydroquinone (manufactured by Tokyo Chemical Industry Co., Ltd.) were added to 42.44 g of propylene glycol monomethyl ether and dissolved. The inside of the reaction vessel was replaced with nitrogen, and then a reaction was allowed to proceed at 140° C. for 24 hours, thereby obtaining a solution containing a polymer B2. GPC analysis showed that the obtained polymer B2 had a weight average molecular weight of 3,000 in terms of standard polystyrene, and a dispersity of 2.2. The structure present in the polymer B2 is shown by the following formula.

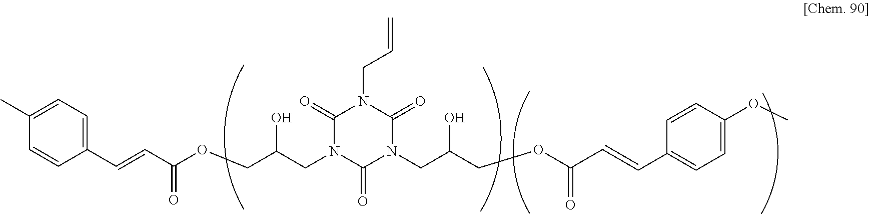

### Synthesis Example B3

In a reaction vessel, 35.00 g of a propylene glycol monomethyl ether solution of 1,6-bis(2,3-epoxypropan-1-yloxy)naphthalene (manufactured by DIC Corporation, trade name: WR-400), 1.99 g of 5,5-diethylbarbituric acid (manufactured by Tateyama Kasei Co., Ltd.), 0.57 g of Trans-cinnamic acid (manufactured by Tokyo Chemical Industry Co., Ltd.), and 0.32 g of tetrabutylphosphonium bromide (manufactured by Hokko Chemical Industry Co., Ltd.) were added to 5.10 g of propylene glycol monomethyl ether and dissolved. The inside of the reaction vessel was replaced with nitrogen, and then a reaction was allowed to proceed at 140° C. for 24 hours, thereby obtaining a solution containing a polymer B3. GPC analysis showed that the obtained polymer B3 had a weight average molecular weight of 3,700 in terms of standard polystyrene, and a dispersity of 2.1. The structure present in the polymer B3 is shown by the following formula.

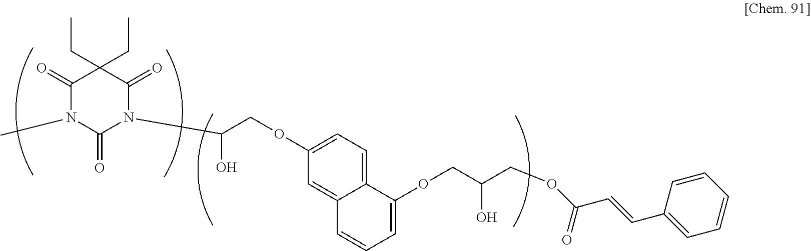

### Synthesis Example B4

In a reaction vessel, 6.00 g of 1,3,5-tris(2,3-epoxypropyl)isocyanuric acid (trade name: TEPIC-SS, manufactured by Nissan Chemical Industries, Ltd.), 8.71 g of Trans-cinnamic acid (manufactured by Tokyo Chemical Industry Co., Ltd.), 0.76 g of tetrabutylphosphonium bromide (manufactured by Hokko Chemical Industry Co., Ltd.), and 0.16 g of hydroquinone (manufactured by Tokyo Chemical Industry Co., Ltd.) were added to 36.48 g of propylene glycol monomethyl ether and dissolved. The inside of the reaction vessel was replaced with nitrogen, and then a reaction was allowed to proceed at 140° C. for 24 hours, thereby obtaining a solution containing a polymer B4 (compound B4). GPC analysis showed that the obtained polymer B4 (compound B4) had a weight average molecular weight of 680 in terms of standard polystyrene, and a dispersity of 1.1. The structure present in the polymer B4 (compound B4) is shown by the following formula.

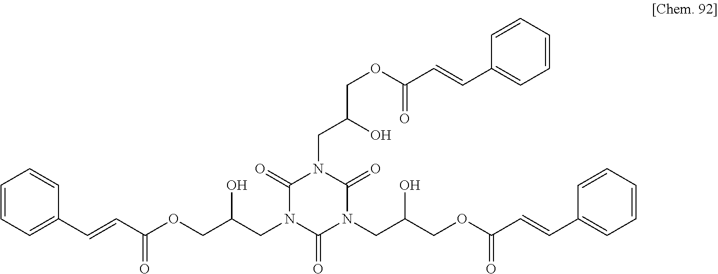 [SMILES: O=C(/C=C/c1ccccc1)OCC(O)Cn1c(=O)n(CC(O)COC(=O)/C=C/c2ccccc2)c(=O)n(CC(O)COC(=O)/C=C/c2ccccc2)c1=O]

### Synthesis Example B5

In a reaction vessel, 5.00 g of 1,3,5-tris(2,3-epoxypropyl)isocyanuric acid (trade name: TEPIC-SS, manufactured by Nissan Chemical Industries, Ltd.), 8.06 g of 4-methylcinnamic acid (manufactured by Tokyo Chemical Industry Co., Ltd.), 0.63 g of tetrabutylphosphonium bromide (manufactured by Hokko Chemical Industry Co., Ltd.), and 0.14 g of hydroquinone (manufactured by Tokyo Chemical Industry Co., Ltd.) were added to 32.26 g of propylene glycol monomethyl ether and dissolved. The inside of the reaction vessel was replaced with nitrogen, and then a reaction was allowed to proceed at 140° C. for 24 hours, thereby obtaining a solution containing a polymer B5 (compound B5). GPC analysis showed that the obtained polymer B5 (compound B5) had a weight average molecular weight of 760 in terms of standard polystyrene, and a dispersity of 1.1. The structure present in the polymer B5 (compound B5) is shown by the following formula.

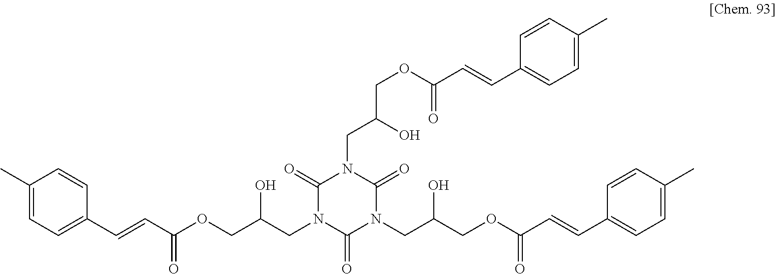

### Synthesis Example B6

In a reaction vessel, 5.00 g of 1,3,5-tris(2,3-epoxypropyl)isocyanuric acid (trade name: TEPIC-SS, manufactured by Nissan Chemical Industries, Ltd.), 8.90 g of trans-4-methylcinnamic acid (manufactured by Tokyo Chemical Industry Co., Ltd.), 0.63 g of tetrabutylphosphonium bromide (manufactured by Hokko Chemical Industry Co., Ltd.), and 0.14 g of hydroquinone (manufactured by Tokyo Chemical Industry Co., Ltd.) were added to 34.23 g of propylene glycol monomethyl ether and dissolved. The inside of the reaction vessel was replaced with nitrogen, and then a reaction was allowed to proceed at 140° C. for 24 hours, thereby obtaining a solution containing a polymer B6 (compound B6). GPC analysis showed that the obtained polymer B6 (compound B6) had a weight average molecular weight of 760 in terms of standard polystyrene, and a dispersity of 1.0. The structure present in the polymer B6 (compound B6) is shown by the following formula.

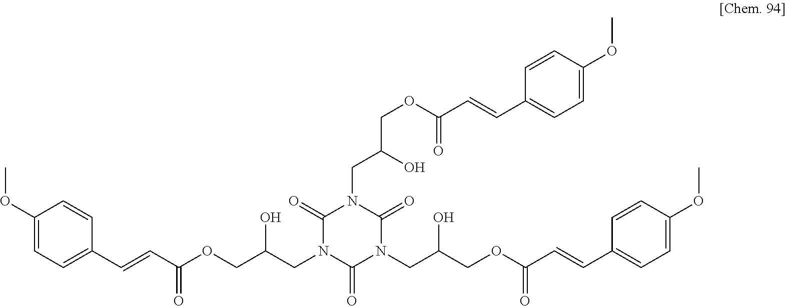 [SMILES: COc1ccc(/C=C/C(=O)OCC(O)Cn2c(=O)n(CC(O)COC(=O)/C=C/c3ccc(OC)cc3)c(=O)n(CC(O)COC(=O)/C=C/c3ccc(OC)cc3)c2=O)cc1]

### Synthesis Example B7

In a reaction vessel, 5.00 g of 1,3,5-tris(2,3-epoxypropyl)isocyanuric acid (trade name: TEPIC-SS, manufactured by Nissan Chemical Industries, Ltd.), 8.25 g of 4-fluorocinnamic acid (manufactured by Tokyo Chemical Industry Co., Ltd.), 0.63 g of tetrabutylphosphonium bromide (manufactured by Hokko Chemical Industry Co., Ltd.), and 0.14 g of hydroquinone (manufactured by Tokyo Chemical Industry Co., Ltd.) were added to 32.72 g of propylene glycol monomethyl ether and dissolved. The inside of the reaction vessel was replaced with nitrogen, and then a reaction was allowed to proceed at 140° C. for 24 hours, thereby obtaining a solution containing a polymer B7 (compound B7). GPC analysis showed that the obtained polymer B7 (compound B7) had a weight average molecular weight of 810 in terms of standard polystyrene, and a dispersity of 1.0. The structure present in the polymer B7 (compound B7) is shown by the following formula.

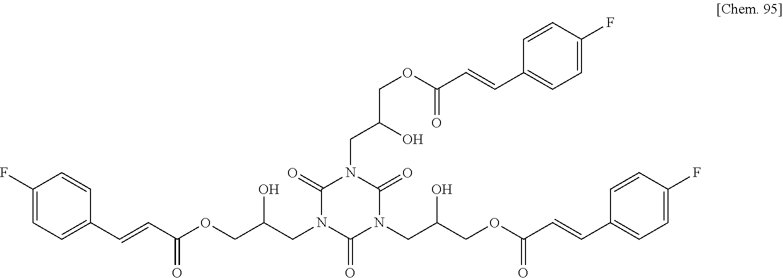 [SMILES: O=C(/C=C/c1ccc(F)cc1)OCC(O)Cn1c(=O)n(CC(O)COC(=O)/C=C/c2ccc(F)cc2)c(=O)n(CC(O)COC(=O)/C=C/c2ccc(F)cc2)c1=O]

### Comparative Synthesis Example B1

In a reaction vessel, 100.00 g of monoallyl diglycidyl isocyanurate (manufactured by Shikoku Chemicals Corporation), 66.4 g of 5,5-diethylbarbituric acid (manufactured by Tateyama Kasei Co., Ltd.), and 4.1 g of benzyltriethylammonium chloride were added to 682.00 g of propylene glycol monomethyl ether and dissolved. The inside of the reaction vessel was replaced with nitrogen, and then a reaction was allowed to proceed at 130° C. for 24 hours, thereby obtaining a solution containing a comparative polymer B1. GPC analysis showed that the obtained comparative polymer B1 had a weight average molecular weight of 6,800 in terms of standard polystyrene, and a dispersity of 4.8. The structure present in the comparative polymer B1 is shown by the following formula.

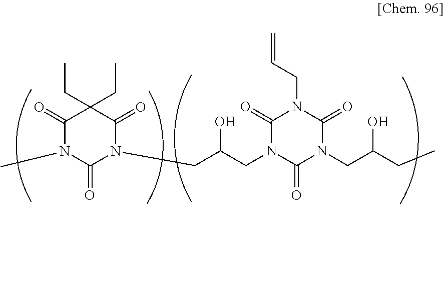

### Comparative Synthesis Example B2

In a reaction vessel, 40.00 g of a propylene glycol monomethyl ether solution of 1,6-bis(2,3-epoxypropan-1-yloxy)naphthalene (manufactured by DIC Corporation, trade name: WR-400), 2.87 g of Trans-p-coumaric acid (manufactured by Tokyo Chemical Industry Co., Ltd.), 0.37 g of tetrabutylphosphonium bromide (manufactured by Hokko Chemical Industry Co., Ltd.), and 0.08 g of hydroquinone (manufactured by Tokyo Chemical Industry Co., Ltd.) were added to 5.95 g of propylene glycol monomethyl ether and dissolved. The inside of the reaction vessel was replaced with nitrogen, and then a reaction was allowed to proceed at 140° C. for 24 hours, thereby obtaining a solution containing a comparative polymer B2. GPC analysis showed that the obtained comparative polymer B2 had a weight average molecular weight of 6,200 in terms of standard polystyrene, and a dispersity of 3.0. The structure present in the comparative polymer B2 is shown by the following formula.

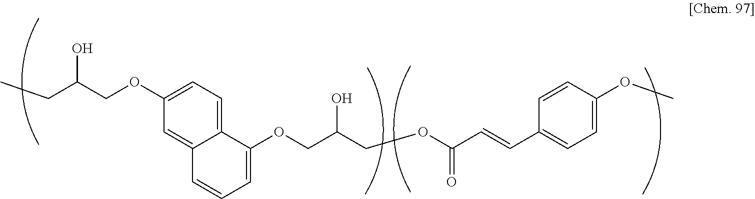

(Preparation of Resist Underlayer Film)

### Examples and Comparative Examples

Each of the polymers (compounds) obtained in Synthesis Examples B1 to B7 and Comparative Synthesis Examples B1 and B2, a crosslinking agent, a curing catalyst, and a solvent were mixed at proportions as shown in Tables B1 and B2, and the mixtures were filtered through a fluororesin filter having a pore size of 0.1 m, thereby preparing solutions of each of the resist underlayer film-forming compositions.

In Tables B1 and B2, tetramethoxymethyl glycoluril was abbreviated as PL-LI; imidazo[4,5-d]imidazole-2,5(1H,3H)-dione,tetrahydro-1,3,4,6-tetrakis[(2-methoxy-1-m ethylethoxy)methyl]- was abbreviated as PGME-PL; pyridinium p-hydroxybenzenesulfonic acid was abbreviated as PyPSA; a surfactant was abbreviated as R-30N; propylene glycol monomethyl ether acetate was abbreviated as PGMEA; and propylene glycol monomethyl ether was abbreviated as PGME. The amount of each of the components incorporated was shown in part(s) by mass.

TABLE 5
B1

| | | Crosslinking | Curing | | |
|---|---|---|---|---|---|
| | Polymer | agent | catalyst | Solvent | |
| Example B1 | Synthesis | PL-LI | PyPSA | PGME | PGMEA |
| | Example B1 | | | | |
| (parts by mass) | 0.141 | 0.035 | 0.004 | 90 | 10 |
| Example B2 | Synthesis | PL-LI | PyPSA | PGME | PGMEA |
| | Example B2 | | | | |
| (parts by mass) | 0.141 | 0.035 | 0.004 | 90 | 10 |
| Example B3 | Synthesis | PGME-PL | PyPSA | PGME | PGMEA |
| | Example B3 | | | | |
| (parts by mass) | 0.146 | 0.040 | 0.004 | 70 | 30 |
| Example B4 | Synthesis | PL-LI | PyPSA | PGME | PGMEA |
| | Example B4 | | | | |
| (parts by mass) | 0.125 | 0.044 | 0.003 | 90 | 10 |
| Example B5 | Synthesis | PL-LI | PyPSA | PGME | PGMEA |
| | Example B5 | | | | |
| (parts by mass) | 0.125 | 0.044 | 0.003 | 90 | 10 |
| Example B6 | Synthesis | PL-LI | PyPSA | PGME | PGMEA |
| | Example B6 | | | | |
| (parts by mass) | 0.125 | 0.044 | 0.003 | 90 | 10 |
| Example B7 | Synthesis | PL-LI | PyPSA | PGME | PGMEA |
| | Example B7 | | | | |
| (parts by mass) | 0.125 | 0.044 | 0.003 | 90 | 10 |

TABLE 6
B2

| | | Crosslinking | Curing | | | |
|---|---|---|---|---|---|---|
| | Polymer | agent | catalyst | Surfactant | Solvent | |
| Comparative | Comparative | PL-LI | PyPSA | R-30N | PGME | PGMEA |
| Example B1 | Synthesis | | | | | |
| | Example B1 | | | | | |
| (parts by mass) | 0.149 | 0.037 | 0.003 | 0.001 | 70 | 30 |
| Comparative | Comparative | PL-LI | PyPSA | — | PGME | PGMEA |
| Example B2 | Synthesis | | | | | |
| | Example B2 | | | | | |
| (parts by mass) | 0.141 | 0.035 | 0.004 | — | 90 | 10 |

(Test for Elution into Photoresist Solvent)

Each of the resist underlayer film-forming compositions of Examples B1 to B7 and Comparative Examples B1 and B2 was applied onto a silicon wafer using a spinner. The silicon wafer was baked on a hot plate at 205° C. for 60 seconds to obtain a film having a film thickness of 5 nm. These resist underlayer films were immersed in a mixed solution of propylene glycol monomethyl ether/propylene glycol monomethyl ether=70/30, which was a solvent used for the photoresist. The film that provided a film thickness change of less than 5 Å was evaluated as good, and the film that provided a film thickness change of 5 Å or more was evaluated as poor. The results thereof are shown in Table B3.

TABLE 7
B3

| | Elution test |
|---|---|
| Example B1 | Good |
| Example B2 | Good |
| Example B3 | Good |
| Example B4 | Good |
| Example B5 | Good |
| Example B6 | Good |
| Example B7 | Good |
| Comparative Example B1 | Good |
| Comparative Example B2 | Good |

(Evaluation of Resist Patterning)

[Test for Forming Resist Pattern by Electron Beam Drawing Apparatus]

Each of the resist underlayer film-forming compositions was applied onto a silicon wafer using a spinner. The silicon wafer was baked on a hot plate at 205° C. for 60 seconds to obtain a resist underlayer film having a thickness of 5 nm. A positive resist solution for EUV was spin-coated on the resist underlayer film, and heating was performed at 130° C. for 60 seconds, thereby forming an EUV resist film. The resist film was exposed under the predetermined conditions using an electron beam drawing apparatus (ELS-G130). After the exposure, the film was baked (PEB) at 90° C. for 60 seconds, the baked film was cooled on a cooling plate to room temperature. The cooled film was subjected to paddle development for 30 seconds using a 2.38% tetramethylammonium hydroxide aqueous solution (manufactured by TOKYO OHKA KOGYO CO., LTD., trade name: NMD-3) as a photoresist developer. A resist pattern having a line size of 16 nm to 28 nm was formed. A scanning electron microscope (manufactured by Hitachi High-Technologies Corporation, CG4100) was used for measuring a length of the resist pattern.

The photoresist pattern thus obtained was evaluated for determining whether or not a 22 nm line-and-space (L/S) was formed. The formation of the 22 nm L/S pattern was confirmed in all cases of Examples B1 to B7. In addition, the amount of charge for forming the 22 nm line/44 nm pitch (line-and-space (L/S=1/1)) was defined as the optimal irradiation energy, and the irradiation energy (μC/cm²) at that time, together with the minimum CD size and LWR are shown in Table B4. In all of Examples B1 to B7, it was confirmed that the LWR was improved as compared with Comparative Examples B1 and B2.

TABLE 8
B4

| | Irradiation energy | LWR |
|---|---|---|
| | (uC/cm²) | (nm) |
| Example B1 | 428 | 3.15 |
| Example B2 | 444 | 3.08 |
| Example B3 | 453 | 3.14 |
| Example B4 | 468 | 3.13 |
| Example B5 | 479 | 3.11 |
| Example B6 | 461 | 3.13 |
| Example B7 | 473 | 3.16 |
| Comparative Example B1 | 433 | 3.54 |
| Comparative Example B2 | 437 | 3.38 |

### Synthesis Example C1

In a reaction vessel, 9.00 g of monoallyl diglycidyl isocyanurate (manufactured by Shikoku Chemicals Corporation), 5.77 g of 5-nitroisophthalic acid (manufactured by Tokyo Chemical Industry Co., Ltd.), 1.45 g of terephthalaldehyde acid (manufactured by Tokyo Chemical Industry Co., Ltd.), and 0.82 g of tetrabutylphosphonium bromide (manufactured by Hokko Chemical Industry Co., Ltd.) were added to 39.76 g of propylene glycol monomethyl ether and dissolved. The inside of the reaction vessel was replaced with nitrogen, and then a reaction was allowed to proceed at 105° C. for 24 hours. Subsequently, a solution obtained by dissolving 0.64 g of malononitrile (manufactured by Junsei Chemical Co., Ltd.) in 1.50 g of propylene glycol monomethyl ether was added to the system, and a reaction was allowed to proceed for 4 hours, thereby obtaining a solution containing a polymer C1. GPC analysis showed that the obtained polymer C1 had a weight average molecular weight of 3,900 in terms of standard polystyrene, and a dispersity of 2.5. The structure present in the polymer C1 is shown by the following formula.

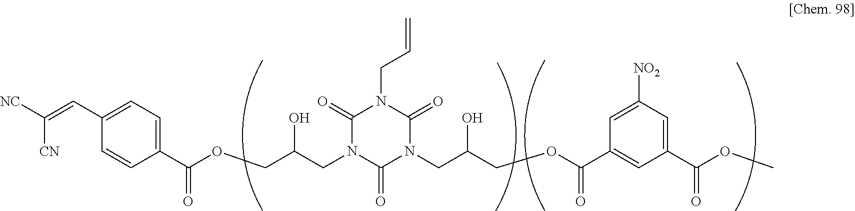

### Synthesis Example C2

In a reaction vessel, 5.00 g of monoallyl diglycidyl isocyanurate (manufactured by Shikoku Chemicals Corporation), 3.21 g of 5-nitroisophthalic acid (manufactured by Tokyo Chemical Industry Co., Ltd.), 0.79 g of 3-cyanobenzoic acid (manufactured by Tokyo Chemical Industry Co., Ltd.), and 0.46 g of tetrabutylphosphonium bromide (manufactured by Hokko Chemical Industry Co., Ltd.) were added to 37.81 g of propylene glycol monomethyl ether and dissolved. The inside of the reaction vessel was replaced with nitrogen, and then a reaction was allowed to proceed at 140° C. for 24 hours, thereby obtaining a solution containing a polymer C2. GPC analysis showed that the obtained polymer C2 had a weight average molecular weight of 3,300 in terms of standard polystyrene, and a dispersity of 2.4. The structure present in the polymer C2 is shown by the following formula.

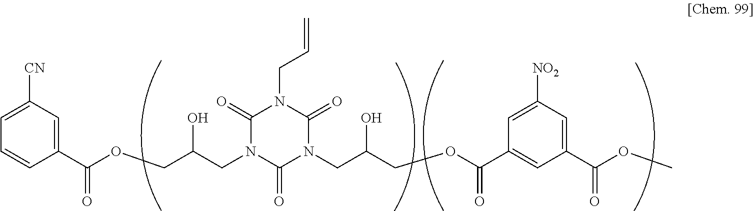

### Synthesis Example C3

In a reaction vessel, 5.00 g of monoallyl diglycidyl isocyanurate (manufactured by Shikoku Chemicals Corporation), 3.21 g of 5-nitroisophthalic acid (manufactured by Tokyo Chemical Industry Co., Ltd.), 0.93 g of a-cyanocinnamic acid (manufactured by Tokyo Chemical Industry Co., Ltd.), 0.46 g of tetrabutylphosphonium bromide (manufactured by Hokko Chemical Industry Co., Ltd.), and 0.10 g of hydroquinone (manufactured by Tokyo Chemical Industry Co., Ltd.) were added to 38.76 g of propylene glycol monomethyl ether and dissolved. The inside of the reaction vessel was replaced with nitrogen, and then a reaction was allowed to proceed at 140° C. for 24 hours, thereby obtaining a solution containing a polymer C3. GPC analysis showed that the obtained polymer C3 had a weight average molecular weight of 2,900 in terms of standard polystyrene, and a dispersity of 2.3. The structure present in the polymer C3 is shown by the following formula.

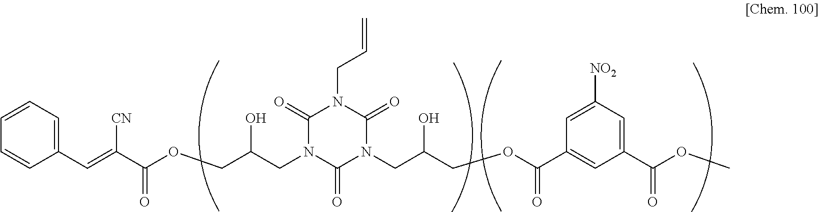

### Comparative Synthesis Example C1

In a reaction vessel, 100.00 g of monoallyl diglycidyl isocyanurate (manufactured by Shikoku Chemicals Corporation), 66.4 g of 5,5-diethylbarbituric acid (manufactured by Tateyama Kasei Co., Ltd.), and 4.1 g of benzyltriethylammonium chloride were added to 682.00 g of propylene glycol monomethyl ether and dissolved. The inside of the reaction vessel was replaced with nitrogen, and then a reaction was allowed to proceed at 130° C. for 24 hours, thereby obtaining a solution containing a comparative polymer C1. GPC analysis showed that the obtained comparative polymer C1 had a weight average molecular weight of 6,800 in terms of standard polystyrene, and a dispersity of 4.8. The structure present in the comparative polymer C1 is shown by the following formula.

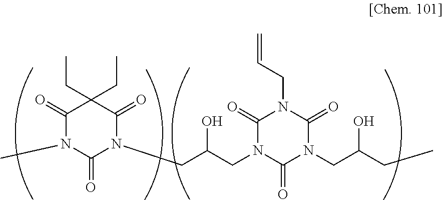

### Comparative Synthesis Example C2

In a reaction vessel, 12.86 g of 1,3,5-tris(2,3-epoxypropyl)isocyanuric acid (trade name: TEPIC-SS, manufactured by Nissan Chemical Industries, Ltd.), 9.67 g of terephthalaldehyde acid (manufactured by Tokyo Chemical Industry Co., Ltd.), 7.87 g of 4-hydroxybenzaldehyde (manufactured by Junsei Chemical Co., Ltd.), and 1.09 g of tetrabutylphosphonium bromide (manufactured by Hokko Chemical Industry Co., Ltd.) were added to 125.96 g of propylene glycol monomethyl ether and dissolved. The inside of the reaction vessel was replaced with nitrogen, and then a reaction was allowed to proceed at 135° C. for 6 hours. Subsequently, a solution obtained by dissolving 8.51 g of malononitrile (manufactured by Junsei Chemical Co., Ltd.) in 34.04 g of propylene glycol monomethyl ether was added to the system, and a reaction was allowed to proceed for 2 hours, thereby obtaining a solution containing a comparative polymer C2 (comparative compound C2). GPC analysis showed that the obtained comparative polymer C2 (comparative compound C2) had a weight average molecular weight of 980 in terms of standard polystyrene, and a dispersity of 1.3. The structure present in the comparative polymer C2 (comparative compound C2) is shown by the following formula.

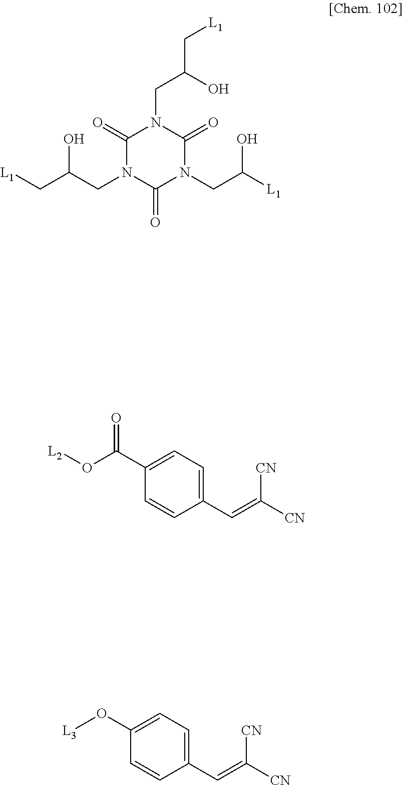

(L¹ represents a binding site with L₂ and L₃)

(Preparation of Resist Underlayer Film)

### Examples and Comparative Examples

Each of the polymers (compounds) obtained in Synthesis Examples C1 to C3 and Comparative Synthesis Examples C1 and C2, a crosslinking agent, a curing catalyst, and a solvent were mixed at proportions as shown in Tables C1 and C2, and the mixtures were filtered through a fluororesin filter having a pore size of 0.1 m, thereby preparing solutions of each of the resist underlayer film-forming compositions.

In Tables C1 and C2, tetramethoxymethyl glycoluril was abbreviated as PL-LI; imidazo[4,5-d]imidazole-2,5(1H,3H)-dione,tetrahydro-1,3,4,6-tetrakis[(2-methoxy-1-m ethylethoxy)methyl]- was abbreviated as PGME-PL; pyridinium p-hydroxybenzenesulfonic acid was abbreviated as PyPSA; a surfactant was abbreviated as R-30N; propylene glycol monomethyl ether acetate was abbreviated as PGMEA; and propylene glycol monomethyl ether was abbreviated as PGME. The amount of each of the components incorporated was shown in part(s) by mass.

TABLE 9
C1

| | | Crosslinking | Curing | | |
|---|---|---|---|---|---|
| | Polymer | agent | catalyst | Solvent | |
| Example C1 | Synthesis Example C1 | PGME-PL | PyPSA | PGME | PGMEA |
| (parts by mass) | 0.146 | 0.040 | 0.004 | 90 | 10 |
| Example C2 | Synthesis Example C2 | PGME-PL | PyPSA | PGME | PGMEA |
| (parts by mass) | 0.146 | 0.040 | 0.004 | 90 | 10 |
| Example C3 | Synthesis Example C3 | PGME-PL | PyPSA | PGME | PGMEA |
| (parts by mass) | 0.146 | 0.040 | 0.004 | 90 | 10 |

TABLE 10
C2

| | | Crosslinking | Curing | | | |
|---|---|---|---|---|---|---|
| | Polymer | agent | catalyst | Surfactant | Solvent | |
| Comparative | Comparative | PL-LI | PyPSA | R-30N | PGME | PGMEA |
| Example C1 | Synthesis | | | | | |
| | Example C1 | | | | | |
| (parts by mass) | 0.149 | 0.037 | 0.003 | 0.001 | 70 | 30 |
| Comparative | Comparative | PL-LI | PyPSA | R-30N | PGME | PGMEA |
| Example C2 | Synthesis | | | | | |
| | Example C2 | | | | | |
| (parts by mass) | 0.125 | 0.044 | 0.003 | — | 90 | 10 |

(Test for Elution into Photoresist Solvent)

Each of the resist underlayer film-forming compositions of Examples C1 to C3 and Comparative Examples C1 and C2 was applied onto a silicon wafer using a spinner. The silicon wafer was baked on a hot plate at 205° C. for 60 seconds to obtain a film having a film thickness of 5 nm. These resist underlayer films were immersed in a mixed solution of propylene glycol monomethyl ether/propylene glycol monomethyl ether=70/30, which was a solvent used for the photoresist. The film that provided a film thickness change of less than 1 Å was evaluated as good, and the film that provided a film thickness change of 1 Å or more was evaluated as poor. The results thereof are shown in Table C3.

TABLE 11
C3

| | Elution test |
|---|---|
| Example C1 | Good |
| Example C2 | Good |
| Example C3 | Good |
| Comparative Example C1 | Good |
| Comparative Example C2 | Poor |

(Evaluation of Resist Patterning)

[Test for Forming Resist Pattern by Electron Beam Drawing Apparatus]

Each of the resist underlayer film-forming compositions was applied onto a silicon wafer using a spinner. The silicon wafer was baked on a hot plate at 205° C. for 60 seconds to obtain a resist underlayer film having a thickness of 5 nm. A positive resist solution for EUV was spin-coated on the resist underlayer film, and heating was performed at 130° C. for 60 seconds, thereby forming an EUV resist film. The resist film was exposed under the predetermined conditions using an electron beam drawing apparatus (ELS-G130). After the exposure, the film was baked (PEB) at 90° C. for 60 seconds, the baked film was cooled on a cooling plate to room temperature. The cooled film was subjected to paddle development for 30 seconds using a 2.38% tetramethylammonium hydroxide aqueous solution (manufactured by TOKYO OHKA KOGYO CO., LTD., trade name: NMD-3) as a photoresist developer. A resist pattern having a line size of 16 nm to 28 nm was formed. A scanning electron microscope (manufactured by Hitachi High-Technologies Corporation, CG4100) was used for measuring a length of the resist pattern.

The photoresist pattern thus obtained was evaluated for determining whether or not a 22 nm line-and-space (L/S) was formed. The formation of the 22 nm L/S pattern was confirmed in all cases of Examples C1 to C3. In addition, the amount of charge forming the 22 nm line/44 nm pitch (line-and-space (L/S=1/1)) was defined as the optimal irradiation energy, and the irradiation energy (μC/cm²) at that time, together with the minimum CD size and LWR at which no collapse was observed in the shot of the resist pattern are shown in Table C4. In Examples C1 to C3, it was confirmed that the LWR and the minimum CD size were improved as compared with Comparative Example C1.

TABLE 12
C4

| | Irradiation | Minimum | |
|---|---|---|---|
| | energy | CD size | LWR |
| | (uC/cm2) | (nm) | (nm) |
| Example C1 | 450 | 16.5 | 3.43 |
| Example C2 | 452 | 17.0 | 3.30 |
| Example C3 | 457 | 16.7 | 3.53 |
| Comparative Example C1 | 433 | 18.5 | 3.54 |

### INDUSTRIAL APPLICABILITY

The resist underlayer film-forming composition according to the present invention can provide a composition for forming a resist underlayer film that can form a desired resist pattern, a method for manufacturing a substrate with a resist pattern using the resist underlayer film-forming composition, and a method for manufacturing a semiconductor device.

1. A resist underlayer film-forming composition comprising a solvent and a polymer or compound having a structure represented by the following Formula (100): 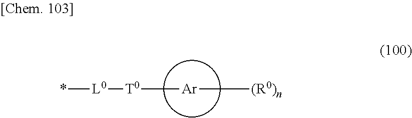
(in Formula (100),
Ar represents an optionally substituted aromatic ring group having 6 to 40 carbon atoms,
L⁰ represents a single bond, an ester bond, an ether bond, an optionally substituted alkylene group having 1 to 10 carbon atoms, or an optionally substituted alkenylene group having 2 to 10 carbon atoms,
T⁰ represents a single bond, an ester bond, an ether bond, an optionally substituted alkylene group having 1 to 10 carbon atoms, or an optionally substituted alkenylene group having 2 to 10 carbon atoms,
provided that L⁰ and T⁰ are different from each other,
n quantity of R⁰ each independently represent a hydroxy group, a halogen atom, a nitro group, a cyano group, an amino group, or a monovalent organic group,
n represents an integer of 0 to 5, and
* represents a binding site to a residue of the polymer or compound).

2. The resist underlayer film-forming composition according to claim 1, which comprises a solvent and a compound having a partial structure represented by Formula (100),
wherein in Formula (100),
Ar represents an optionally substituted aromatic ring having 6 to 40 carbon atoms,
L⁰ represents a single bond, an ester bond, an ether bond, an alkylene group having 1 to 10 carbon atoms, or an alkenylene group having 2 to 10 carbon atoms,
T⁰ represents a single bond,
n quantity of R⁰ each independently represent a hydroxy group, a halogen atom, a nitro group, a cyano group, an amino group, or a monovalent organic group, and
n represents an integer of 1 to 3.

3. The resist underlayer film-forming composition according to claim 2, wherein the compound is a reaction product of an epoxy group-containing compound and a compound represented by the following Formula (101): 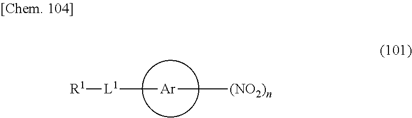
(in Formula (101), R represents a group having reactivity with an epoxy group, and
Ar, L¹, and n have the same meaning as Ar, L⁰, and n in claim 2, respectively).

4. A resist underlayer film-forming composition comprising a solvent and a polymer,
wherein the polymer has at a terminal thereof a structure represented by the following Formula (103): 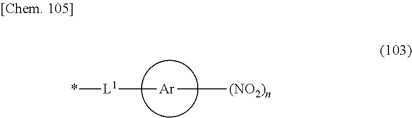
(in Formula (103), Ar represents an optionally substituted aromatic ring having 6 to 40 carbon atoms; L represents a single bond, an ester bond, an ether bond, an alkylene group having 1 to 10 carbon atoms, or an alkenylene group having 2 to 10 carbon atoms; and n represents an integer of 1 to 3).

5. A resist underlayer film-forming composition comprising a solvent and a polymer, which is a reaction product of a compound containing two or more epoxy groups with a compound represented by the following Formula (102): 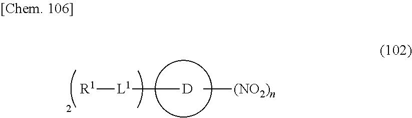
(in Formula (102), R represents a group having reactivity with an epoxy group; D represents an aromatic ring having 6 to 40 carbon atoms or a heterocyclic ring; and L¹ and n have the same meaning as L⁰ and n in claim 2, respectively).

6. The resist underlayer film-forming composition according to claim 5, wherein the polymer has at a terminal thereof a structure represented by Formula (103).

7. A resist underlayer film-forming composition comprising a solvent and a polymer represented by the following Formula (P1): 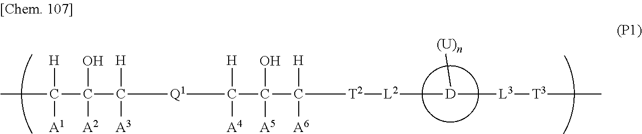
(in Formula (P1), A¹, A², A³, A⁴, A⁵, and A⁶ each independently represent a hydrogen atom, a methyl group, or an ethyl group; Q¹ represents a divalent organic group; T² and T³ each independently represent a single bond, an ester bond, or an ether bond; L² and L³ each independently represent a single bond, an optionally substituted alkylene group having 1 to 10 carbon atoms, or an optionally substituted alkenylene group having 2 to 10 carbon atoms; U represents a nitro group; D represents an aromatic ring having 6 to 40 carbon atoms or a heterocyclic ring; and n represents an integer of 0 to 3).

8. The resist underlayer film-forming composition according to claim 3, wherein the epoxy group-containing compound, the compound containing two or more epoxy groups, or Q¹ has a heterocyclic structure.

9. The resist underlayer film-forming composition according to claim 2, wherein at least one of L to L³ is an alkenylene group having 2 to 10 carbon atoms.

10. A resist underlayer film-forming composition comprising a solvent and a polymer or compound having at a terminal thereof a structure represented by the following Formula (200): 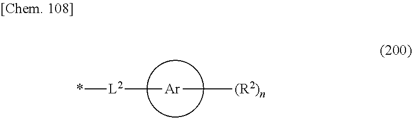
(in Formula (200), Ar represents an optionally substituted aromatic ring having 6 to 40 carbon atoms; L² represents an optionally substituted alkenylene group having 2 to 10 carbon atoms; n quantity of R² each independently represent a group selected from the group consisting of a hydroxy group, a halogen atom, a carboxy group, a nitro group, a cyano group, a methylenedioxy group, an acetoxy group, a methylthio group, an amino group, an optionally substituted alkyl group having 1 to 10 carbon atoms, and an optionally substituted alkoxy group having 1 to 10 carbon atoms; n represents an integer of 0 to 5; and * represents a binding site to a residue of the polymer or compound).

11. The resist underlayer film-forming composition according to claim 10, wherein the polymer is a reaction product of a compound (A) containing two or more epoxy groups and a compound (B) containing two or more groups having reactivity with the epoxy group, and
the compounds (A) and (B) have a heterocyclic structure or an aromatic ring structure having 6 to 40 carbon atoms.

12. The resist underlayer film-forming composition according to claim 10, wherein the polymer has a unit structure represented by the following Formula (P2): 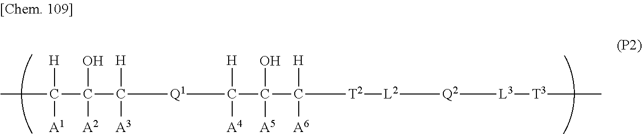
(in Formula (P2), A¹, A², A³, A⁴, A⁵, and A⁶ each independently represent a hydrogen atom, a methyl group, or an ethyl group; Q¹ and Q² each independently represent a divalent organic group having a heterocyclic structure or an aromatic ring structure having 6 to 40 carbon atoms; T² and T³ each independently represent a single bond, an ester bond, or an ether bond; and L² and L³ each independently represent a single bond, an optionally substituted alkylene group having 1 to 10 carbon atoms, or an optionally substituted alkenylene group having 2 to 10 carbon atoms).

13. A resist underlayer film-forming composition comprising a solvent and a polymer having at a terminal thereof a structure represented by the following Formula (300): 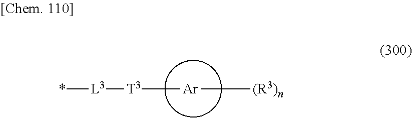
(in Formula (300), Ar represents an optionally substituted aryl group having 6 to 40 carbon atoms; L³ represents a single bond, an ester bond, or an ether bond; T³ represents a single bond, an optionally substituted alkylene group having 1 to 10 carbon atoms, or an optionally substituted alkenylene group having 2 to 10 carbon atoms; n quantity of R³ each independently represent a monovalent organic group; n represents an integer of 0 to 5; and * represents a binding site to a residue of the polymer; and at least one cyano group is present in Formula (300)).

14. The resist underlayer film-forming composition according to claim 13, wherein the polymer is represented by the following Formula (P3): 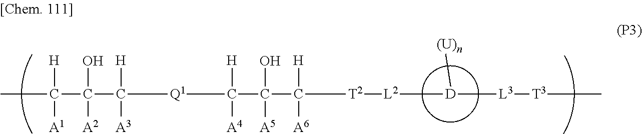
(in Formula (P3), A¹, A², A³, A⁴, A⁵, and A⁶ each independently represent a hydrogen atom, a methyl group, or an ethyl group; Q¹ represents a divalent organic group; T² and T³ each independently represent a single bond, an ester bond, or an ether bond; L² and L³ each independently represent a single bond, an optionally substituted alkylene group having 1 to 10 carbon atoms, or an optionally substituted alkenylene group having 2 to 10 carbon atoms; D represents an arylene group having 6 to 40 carbon atoms or a heterocylic ring; U represents a group selected from the group consisting of a halogen atom, a carboxy group, a nitro group, a cyano group, a methylenedioxy group, an acetoxy group, a methylthio group, an amino group, an optionally substituted alkyl group having 1 to 10 carbon atoms, an optionally substituted alkenyl group having 2 to 10 carbon atoms, and an optionally substituted alkoxy group having 1 to 10 carbon atoms; and m represents an integer of 0 to 5).

15. The resist underlayer film-forming composition according to claim 1, further comprising an acid generator.

16. The resist underlayer film-forming composition according to claim 1, further comprising a crosslinking agent.

17. A resist underlayer film, which is a baked product of a coating film of the resist underlayer film-forming composition according to claim 1.

18. A method for manufacturing a patterned substrate, comprising:
applying the resist underlayer film-forming composition according to claim 1 onto a semiconductor substrate and baking the resist underlayer film-forming composition to form a resist underlayer film;
applying a resist onto the resist underlayer film and baking the resist to form a resist film;
exposing the semiconductor substrate coated with the resist underlayer film and the resist; and
developing the exposed resist film and performing patterning.

19. A method for manufacturing a semiconductor device, comprising:
forming a resist underlayer film of the resist underlayer film-forming composition according to claim 1 on a semiconductor substrate;
forming a resist film on the resist underlayer film;
forming a resist pattern by irradiating the resist film with a light or electron beam and then developing the resist film;
forming a patterned resist underlayer film by etching the resist underlayer film through the formed resist pattern; and
processing the semiconductor substrate by the patterned resist underlayer film.
